(19) United States
(12) Patent Application Publication
(10) Pub. No.: US 2025/0127048 A1
(43) Pub. Date: Apr. 17, 2025

(54) COMPOSITION, OPTOELECTRONIC DEVICE INCLUDING THE SAME, AND ELECTRONIC APPARATUS INCLUDING THE OPTOELECTRONIC DEVICE

(71) Applicant: Samsung Display Co., Ltd., Yongin-si (KR)

(72) Inventors: Junyong Shin, Yongin-si (KR); Soungwook Kim, Yongin-si (KR); Hwasook Ryu, Yongin-si (KR); Seokgyu Yoon, Yongin-si (KR)

(21) Appl. No.: 18/777,178

(22) Filed: Jul. 18, 2024

(30) Foreign Application Priority Data
Oct. 17, 2023 (KR) 10-2023-0138922

(51) Int. Cl. H10K 85/60; H10K 71/16; H10K 101/30

(52) U.S. Cl. CPC H10K 85/6572; H10K 71/16; H10K 85/615; H10K 85/654; H10K 85/6576; H10K 2101/30

(57) ABSTRACT

An optoelectronic device including a first electrode, a second electrode facing the first electrode, and an optical activation layer arranged between the first electrode and the second electrode is provided. The optical activation layer includes a first compound represented by Formula 1, a second compound represented by Formula 2, and a third compound represented by Formula 3, and descriptions of Formulae 1 to 3 are provided.

### CROSS-REFERENCE TO RELATED APPLICATION

This application claims priority to and the benefit of Korean Patent Application No. 10-2023-0138922, filed on Oct. 17, 2023, in the Korean Intellectual Property Office, the entire content of which is incorporated by reference herein.

### BACKGROUND

### 1. Field

One or more aspects of embodiments of the present disclosure relate to a composition, an optoelectronic device including the same, and an electronic apparatus including the optoelectronic device.

### 2. Description of the Related Art

Optoelectronic devices are devices that convert optical energy and/or optical signals into electrical energy and/or electrical signals, respectively. Examples of an optoelectronic device are an optical or solar cell, which converts optical energy into electrical energy, an optical detector or sensor, which detects and converts optical energy into electrical signals, and/or the like.

Electronic apparatuses including optoelectronic devices and light-emitting devices have been developed. Light emitted from a light-emitting device may be reflected from an object (e.g., a finger of a user) in contact with an electronic apparatus, and then be incident (e.g., be incident light) onto an optoelectronic device. As the optoelectronic device detects incident light energy and converts it into electrical signals, the contact and/or approach of the object to the electronic apparatus may be recognized.

### SUMMARY

One or more aspects of embodiments of the present disclosure are directed toward an optoelectronic device, which simply and accurately recognizes information (e.g., fingerprints and/or blood pressure) of a user by utilizing a material depositable at a relatively low temperature, and an electronic apparatus including the optoelectronic device.

Additional aspects will be set forth in part in the description which follows and, in part, will be apparent from the description, or may be learned by practice of the presented embodiments of the disclosure.

According to one or more embodiments, a composition includes a first compound represented by Formula 1, a second compound represented by Formula 2, and a third compound represented by Formula 3:

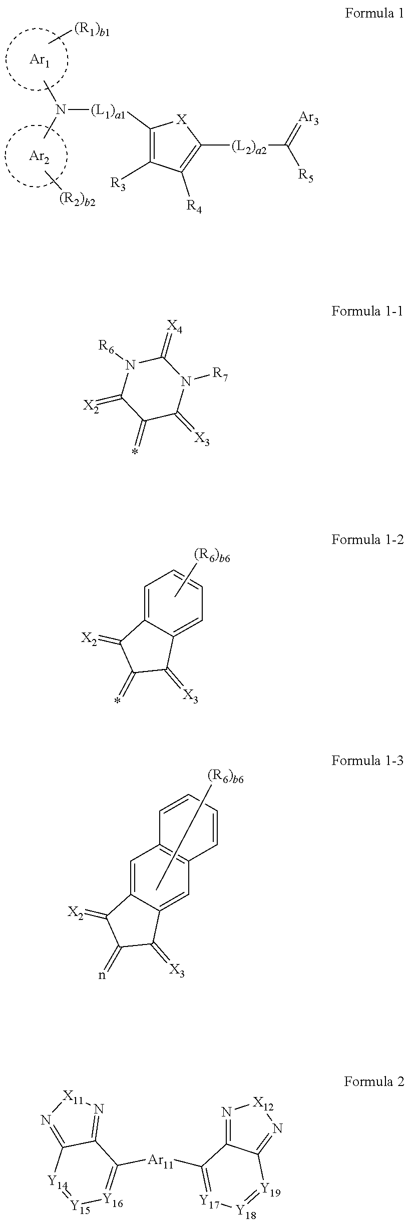

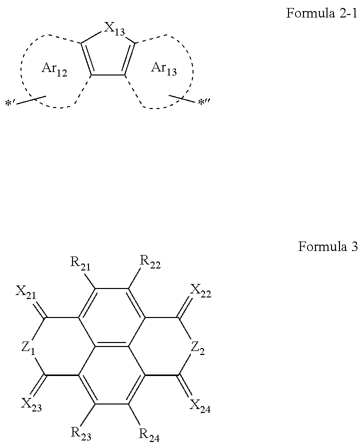

wherein, in Formula 1, Formula 1-1 to Formula 1-3, Formula 2, Formula 2-1, and Formula 3,
Ar₁, Ar₂, Ar₁₂, and Ar₁₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
Ar₁ and Ar₂ may optionally be linked to each other via a single bond, *—O—*′, *—S—*′, *—C(T₁)(T₂)-*′, *—Si(T₁)(T₂)-*′, or *—N(T₁)-*′, e.g., Ar₁ and Ar₂ may not be connected, or Ar₁ and Ar₂ may be connected by one selected from among a single bond, *—O—*′, *—S—*′, *—C(T₁)(T₂)-*′, *—Si(T₁)(T₂)-*′, and *—N(T₁)-*′,
Ar₂ and an X₁-containing 5-membered ring may optionally be linked to each other via a single bond, *—O—*′, *—S—*′, *—C(T₃)(T₄)-*′, *—Si(T₃)(T₄)-*′, or *—N(T₃)-*′, e.g., Ar₂ may not be connected to the X₁-containing 5-membered ring, or Ar₂ may be connected to the X₁-containing 5-membered ring by one selected from among a single bond, *—O—*′, *—S—*′, *—C(T₃)(T₄)-*′, *—Si(T₃)(T₄)-*′, and *—N(T₃)-*′,
T₁ to T₄ may each independently be hydrogen, deuterium, —F, —Cl, a cyano group, a C₁-C₆₀ alkyl group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
Ar₃ may be a group represented by one of (e.g., one selected from among) Formula 1-1 to Formula 1-3,
Ar₁₁ may be a group represented by Formula 2-1,
X₁ may be O, S, Se, Te, SO, SO₂, C(R₁ₐ)(R_{1b}), Si(R₁ₐ)(R_{1b}), or N(R₁ₐ),
X₂ may be O, S, Se, Te, SO, SO₂, C(R_{1c})(R₁ₐ), Si(R_{1c})(R₁ₐ), or N(R_{1c}),
X₃ may be O, S, Se, Te, SO, SO₂, C(R₁ₑ)(R_{1f}), Si(R₁ₑ)(R_{1f}), or N(R₁ₑ),
X₄ may be O, S, Se, Te, SO, SO₂, C(R_{1g})(R₁ₕ), Si(R_{1g})(R₁ₕ), or N(R_{1g}),
X₁₁ may be N(R₁₁), O, S, or Se, and X₁₂ may be N(R₁₂), O, S, or Se,
X₁₃ may be C(R₁₃ₐ)(R_{13b}), N(R₁₃), O, S, or Se,
Y₁₄ may be N or C(R₁₄), Y₁₅ may be N or C(R₁₅), Y₁₆ may be N or C(R₁₆), Y₁₇ may be N or C(R₁₇), Y₁₈ may be N or C(R₁₈), and Y₁ may be N or C(R₁₉),
X₂₁ to X₂₄ may each independently be O, S, or Se,
Z₁ may be O or N(R₂₅), and Z₂ may be O or N(R₂₆),
L₁ and L₂ may each independently be a single bond, a C₁-C₂₀ alkylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
each of a1 and a2 may be an integer from 1 to 3,
each of b1 and b2 may be an integer from 1 to 10, and b6 may be an integer from 1 to 6,
R₁ₐ to R₁ₕ, R₁ to R₇, R₁₃ₐ, R_{13b}, R₁₁ to R₁₉, and R₂₁ to R₂₆ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ may be
deuterium, —F, —Cl, —Br, —I, a hydroxyl group, a cyano group, or a nitro group,
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof, or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group, or
a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, cyano group, a C₁-C₆₀ alkyl group, a C₁-C₆₀ alkoxy group, a phenyl group, a biphenyl group, or any combination thereof, and
*, *′, and *″ each indicate a binding site to a neighboring atom.

According to one or more embodiments, an optoelectronic device includes a first electrode, a second electrode facing the first electrode, and an optical activation layer arranged between the first electrode and the second electrode, wherein the optical activation layer may include the first compound represented by Formula 1, the second compound represented by Formula 2, and the third compound represented by Formula 3.

In one or more embodiments, the optical activation layer may be a single layer.

In one or more embodiments, the optical activation layer may include a first layer including the first compound, and a second layer including the second compound.

In one or more embodiments, each of the first layer and the second layer may include the third compound.

In one or more embodiments, the second layer may be arranged between the first layer and the second electrode, the optical activation layer may further include a third layer between the second layer and the second electrode, and the third layer may include the third compound.

In one or more embodiments, the optoelectronic device may further include a charge generation layer between the first electrode and the second electrode, and the optical activation layer may include a first optical activation layer between the first electrode and the charge generation layer and a second optical activation layer between the charge generation layer and the second electrode.

In one or more embodiments, the optical activation layer may include the first compound and the third compound, and the second optical activation layer may include the second compound and the third compound.

In one or more embodiments, an absolute value of a highest occupied molecular orbital energy level of the first compound may be in range of about 5.0 electron volt (eV) to about 5.5 eV.

In one or more embodiments, an absolute value of a highest occupied molecular orbital energy level of the second compound may be in range of about 5.0 eV to about 6.5 eV.

In one or more embodiments, an absolute value of a lowest unoccupied molecular orbital energy level of the third compound may be about 3.5 eV or less.

In one or more embodiments, the optical activation layer may not include (e.g., may exclude) (e.g., each of) a fullerene-based compound and a subphthalocyanine-based compound.

In one or more embodiments, the optical activation layer may be provided by vacuum deposition.

According to one or more embodiments, an electronic apparatus includes a first electrode, a second electrode facing the first electrode, an optical activation layer between the first electrode and the second electrode, and an emission layer not overlapping the optical activation layer between the first electrode and the second electrode, wherein the optical activation layer includes the first compound represented by Formula 1, the second compound represented by Formula 2, and the third compound represented by Formula 3.

According to one or more embodiments, the electronic equipment includes the electronic apparatus,
wherein the electronic equipment may be at least one selected from among a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, and a signboard or a combination thereof.

### BRIEF DESCRIPTION OF THE DRAWINGS

The accompanying drawings are included to provide a further understanding of the preceding and other aspects, features, and advantages of certain embodiments of the disclosure are incorporated in and constitute a part of this specification. The drawings illustrate example embodiments and, together with the following description taken in conjunction with the accompanying drawings. In the drawings:

FIG. 1 is a cross-sectional view schematically illustrating a portion of an electronic apparatus according to one or more embodiments;

FIG. 2 is a diagram illustrating an example of an enlarged view of a region of a light-emitting device included in the electronic apparatus of FIG. 1;

FIG. 3 is a diagram illustrating an example of an enlarged view of a region of an optoelectronic device included in the electronic apparatus of FIG. 1;

FIG. 4 is a diagram illustrating an optoelectronic device according to one or more embodiments;

FIG. 5 is a diagram illustrating an optoelectronic device according to one or more embodiments;

FIG. 6 is a diagram illustrating an optoelectronic device according to one or more embodiments;

FIG. 7 is a diagram illustrating an optoelectronic device according to one or more embodiments;

FIG. 8 is a diagram illustrating an optoelectronic device according to one or more embodiments;

FIG. 9 is a perspective view schematically illustrating electronic equipment including an optoelectronic device according to one or more embodiments;

FIG. 10 is a diagram schematically illustrating the exterior of a vehicle as electronic equipment including an optoelectronic device according to one or more embodiments; and

FIGS. 11A to 11C are each a diagram schematically illustrating the interior of a vehicle according to one or more embodiments.

### DETAILED DESCRIPTION

Reference will now be made in more detail to embodiments, examples of which are illustrated in the accompanying drawings, wherein like reference numerals refer to like elements throughout the specification, and duplicative descriptions thereof may not be provided. In this regard, the present embodiments may have different forms and should not be construed as being limited to the descriptions set forth herein. Accordingly, the embodiments are merely described, by referring to the drawings, to explain aspects of the present description. As utilized herein, the term “and/or” includes any and all combinations of one or more of the associated listed items. Expressions such as “at least one of,” “one of,” “selected from,” and “selected from among,” when preceding a list of elements, modify the entire list of elements and do not modify the individual elements of the list. For example, throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

Unless otherwise defined, all chemical names, technical and scientific terms, and terms defined in common dictionaries should be interpreted as having meanings consistent with the context of the related art, and should not be interpreted in an ideal or overly formal sense. It will be understood that, although the terms first, second, and/or the like may be used herein to describe various elements, these elements should not be limited by these terms. These terms are only used to distinguish one element from another element. Thus, a first element could be termed a second element without departing from the teachings of the present disclosure. Similarly, a second element could be termed a first element.

As used herein, singular forms such as “a,” “an,” and “the” are intended to include the plural forms as well, unless the context clearly indicates otherwise.

It will be further understood that the terms “comprise,” “comprises,” “comprising,” “has,” “have,” “having,” “include,” “includes,” and/or “including,” when used in this specification, specify the presence of stated features, steps, operations, elements, and/or components, but do not preclude the presence or addition of one or more other features, steps, operations, elements, components, and/or groups thereof.

As used herein, the terms “use,” “using,” and “used” may be considered synonymous with the terms “utilize,” “utilizing,” and “utilized,” respectively.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

It will be understood that when an element is referred to as being “on,” “connected to,” or “on” another element, it may be directly on, connected, or coupled to the other element or one or more intervening elements may also be present. When an element is referred to as being “directly on,” “directly connected to,” or “directly coupled to” another element, there are no intervening elements present.

Spatially relative terms, such as “beneath,” “below,” “lower,” “above,” “upper,” “bottom,” “top,” and the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

In this context, “consisting essentially of” means that any additional components will not materially affect the chemical, physical, optical or electrical properties of the semiconductor film.

In present disclosure, “not include (or not including) a or any ‘component’”, “exclude (or excluding) a or any ‘component’”, “‘component’-free”, and/or the like refers to that the “component” not being added, selected or utilized as a component in the structure/composition, but the “component” of less than a suitable amount may still be included due to other impurities and/or external factors.

Further, in this specification, the phrase “on a plane,” or “plan view,” means viewing a target portion from the top, and the phrase “on a cross-section” means viewing a cross-section formed by vertically cutting a target portion from the side.

The expression “composition and/or optical activation layer includes a first compound represented by Formula 1” as utilized herein may be understood as “composition and/or optical activation layer includes one kind of first compound represented by Formula 1” or “composition and/or optical activation layer includes two or more different kinds of first compounds, each represented by Formula 1.”

The expression “composition and/or optical activation layer includes a second compound represented by Formula 2” as utilized herein may be understood as “composition and/or optical activation layer includes one kind of second compound represented by Formula 2” or “composition and/or optical activation layer includes two or more different kinds of second compounds, each represented by Formula 2.”

The expression “composition and/or optical activation layer includes a third compound represented by Formula 3” as utilized herein may be understood as “composition and/or optical activation layer includes one kind of third compound represented by Formula 3” or “composition and/or optical activation layer includes two or more different kinds of third compounds, each represented by Formula 3.”

### Composition

An aspect of the present disclosure provides a composition including: a first compound represented by Formula 1; a second compound represented by Formula 2; and a third compound represented by Formula 3:

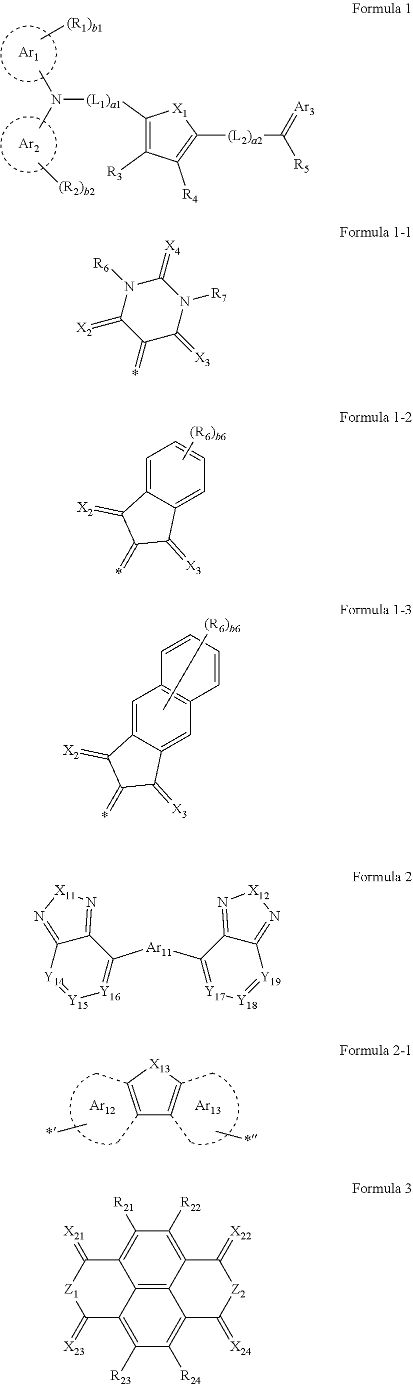

wherein, in Formula 1, Formula 1-1 to Formula 1-3, Formula 2, Formula 2-1, and Formula 3,
Ar₁, Ar₂, Ar₁₂, and Ar₁₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
Ar₁ and Ar₂ may optionally be linked to each other via a single bond, *—O—*, *—S—*′, *—C(T₁)(T₂)-*′, *—Si(T₁)(T₂)-*′, or *—N(T₁)-*′, e.g., Ar₁ and Ar₂ may not be connected, or Ar₁ and Ar₂ may be connected by one selected from among a single bond, *—O—*′, *—S—*′, *—C(T₁)(T₂)-*′, *—Si(T₁)(T₂)-*′, and *—N(T₁)-*′,
Ar₂ and an X₁-containing 5-membered ring may optionally be linked to each other via a single bond, *—O—*′, *—S—*′, *—C(T₃)(T₄)-*′, *—Si(T₃)(T₄)-*′, or *—N(T₃)-*′, e.g., Ar₂ may not be connected to the X₁-containing 5-membered ring, or Ar₂ may be connected to the X₁-containing 5-membered ring by one selected from among a single bond, *—O—*′, *—S—*′, *—C(T₃)(T₄)-*′, *—Si(T₃)(T₄)-*′, and *—N(T₃)-*′,
T₁ to T₄ may each independently be hydrogen, deuterium, —F, —Cl, a cyano group, a C₁-C₆₀ alkyl group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
Ar₃ may be a group represented by one of Formula 1-1 to Formula 1-3,
Ar₁₁ may be a group represented by Formula 2-1,
X₁ may be O, S, Se, Te, SO, SO₂, C(R₁ₐ)(R_{1b}), Si(R₁ₐ)(R_{1b}), or N(R₁ₐ),
X₂ may be O, S, Se, Te, SO, SO₂, C(R_{1c})(R₁ₐ), Si(R_{1c})(R₁ₐ), or N(R_{1c}),
X₃ may be O, S, Se, Te, SO, SO₂, C(R₁ₑ)(R_{1f}), Si(R₁ₑ)(R_{1f}), or N(R₁ₑ),
X₄ may be O, S, Se, Te, SO, SO₂, C(R_{1g})(R₁ₕ), Si(R_{1g})(R₁ₕ), or N(R_{1g}),
X₁₁ may be N(R₁₁), O, S, or Se, and X₁₂ may be N(R₁₂), O, S, or Se,
X₁₃ may be C(R₁₃ₐ)(R_{13b}), N(R₁₃), O, S, or Se,
Y₁₄ may be N or C(R₁₄), Y₁₅ may be N or C(R₁₅), Y₁₆ may be N or C(R₁₆), Y₁₇ may be N or C(R₁₇), Y₁₈ may be N or C(R₁₈), and Y₁₉ may be N or C(R₁₉),
X₂₁ to X₂₄ may each independently be O, S, or Se,
Z₁ may be O or N(R₂₅), and Z₂ may be O or N(R₂₆),
L₁ and L₂ may each independently be a single bond, a C₁-C₂₀ alkylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
each of a1 and a2 may be an integer from 1 to 3,
each of b1 and b2 may be an integer from 1 to 10, and b6 may be an integer from 1 to 6,
R₁ₐ to R₁ₕ, R₁ to R₇, R₁₃ₐ, R_{13b}, R₁₁ to R₁₉, and R₂₁ to R₂₆ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(021), —S(═O)₂(Q₂₁), —P(═O)(Q₂₁)(Q₂₂), or any combination thereof; or
Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be:
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or
a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, cyano group, a C₁-C₆₀ alkyl group, a C₁-C₆₀ alkoxy group, a phenyl group, a biphenyl group, or any combination thereof, and
*, *′, and *″ each indicate a binding site to a neighboring atom.

The composition includes all of the first to third compounds, and thus is clearly (and/or should be apparent to one skilled in the art to be) different from a composition including one or two of the first compound to the third compound. Hereinafter, each of the first to third compounds included in the composition will be described.

### First Compound

The first compound may be represented by Formula 1. The first compound may be to absorb light having a wavelength in a range of about 400 nanometer (nm) to about 1,000 nm. The first compound may be to absorb blue light, green light, red light, near-infrared light, and/or any combination thereof. For example, the first compound may be to absorb green light having a maximum absorption wavelength in a range of about 450 nm to about 600 nm.

In Formula 1, Ar₁ and Ar₂ may each independently be a C₃-C₁ cycloalkyl group unsubstituted or substituted with at least one R₁₀ₐ, a C₁-C₁₀ heterocycloalkyl group unsubstituted or substituted with at least one R₁₀ₐ, a C₃-C₁₀ cycloalkenyl group unsubstituted or substituted with at least one R₁₀ₐ, a C₁-C₁₀ heterocycloalkenyl group unsubstituted or substituted with at least one R₁₀ₐ, a C₆-C₆₀ aryl group unsubstituted or substituted with at least one R₁₀ₐ, a C₁-C₆₀ heteroaryl group unsubstituted or substituted with at least one R₁₀ₐ, a monovalent non-aromatic condensed polycyclic group unsubstituted or substituted with at least one R₁₀ₐ, or a monovalent non-aromatic condensed heteropolycyclic group unsubstituted or substituted with at least one R₁₀ₐ.

For example, Ar₁ and Ar₂ may each independently be benzene a benzene group unsubstituted or substituted with at least one R₁₀ₐ, a naphthalene group unsubstituted or substituted with at least one R₁₀ₐ, a pyridine group unsubstituted or substituted with at least one R₁₀ₐ, a pyrimidine group unsubstituted or substituted with at least one R₁₀ₐ, or a triazine group unsubstituted or substituted with at least one R₁₀ₐ.

The expression “Ar₁ and Ar₂ are optionally linked to each other” in Formula 1 refers to Ar₁ and Ar₂ being linked or not linked to each other. For example, the expression “Ar₁ and Ar₂ are linked to each other via a single bond” may be understood by referring to Compound A1 and/or the like, and the expression “Ar₁ and Ar₂ are linked to each other via *—C(T₁)(T₂)-*′” may be understood by referring to Compound A65 and/or the like:

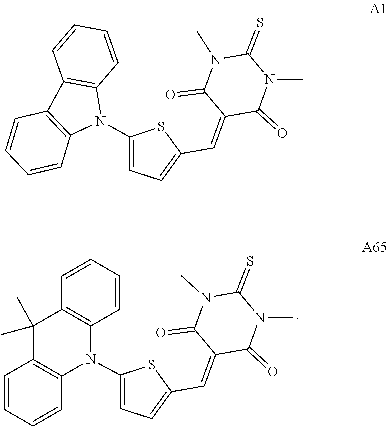

In one or more embodiments, Ar₁ and Ar₂ may be linked to each other (e.g., connected) via a single bond, *—O—*′, *—S—*′, *—C(T₁)(T₂)-*′, *—Si(T₁)(T₂)-*′, or *—N(T₁)*′.

In one or more embodiments, T₁ and T₂ may each independently be selected from:
hydrogen, deuterium, —F, —Cl, and a cyano group; and
a C₁-C₁₀ alkyl group unsubstituted or substituted with deuterium, —F, —Cl, a cyano group, or any combination thereof.

The expression “Ar₂ and X₁-containing 5-membered ring are optionally linked to each other” in Formula 1 refers to Ar₂ and the X₁-containing 5-membered ring being linked or not linked to each other. Ar₂ and the X₁-containing 5-membered ring may be linked to each other at the position of R₃ in Formula 1. For example, the expression “Ar₂ and X₁-containing 5-membered ring are not linked to each other” may be understood by referring to Compounds A1 and A65, and the expression “Ar₂ and X₁-containing 5-membered ring are linked to each other via *—C(T₁)(T₂)-*′38 may be understood by referring to Compound A9 and/or the like:

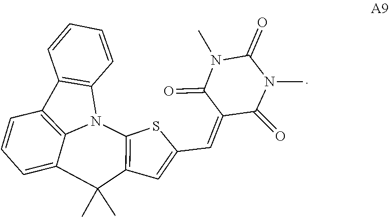 [SMILES: CN1C(=O)C(=Cc2cc3c(s2)-n2c4ccccc4c4cccc(c42)C3(C)C)C(=O)N(C)C1=O]

In one or more embodiments, Ar₂ and the X₁-containing 5-membered ring may optionally be linked to each other (e.g., connected) via a single bond or *—C(T₃)(T₄)-*′.

In one or more embodiments, T₃ and T₄ may each independently be selected from:
hydrogen, deuterium, —F, —Cl, and a cyano group; and
a C₁-C₁₀ alkyl group unsubstituted or substituted with deuterium, —F, —Cl, a cyano group, or any combination thereof.

In one or more embodiments, in Formula 1, a moiety represented by

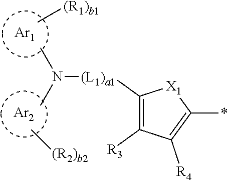

may be a moiety represented by one of Formulae 1A to 1E:

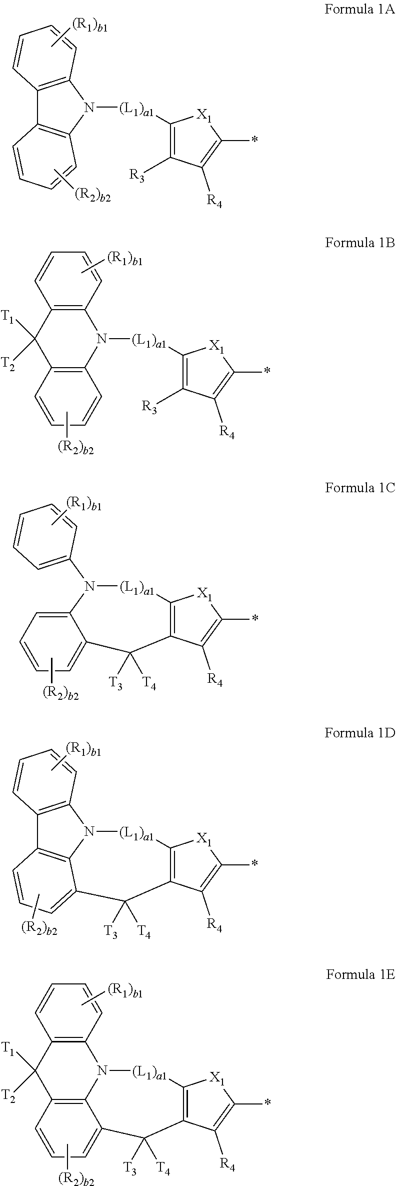

wherein, in Formulae 1A to 1E,
X₁, L₁, a1, T₁ to T₄, and R₁ to R₄ are each as described herein,
b1 may be an integer from 1 to 5,
b2 may be an integer from 1 to 4, and
* indicates a binding site to (L₂)ₐ₂ in Formula 1.

In Formula 1, Ar₃ may be a group represented by one selected from among Formula 1-1, Formula 1-2, and Formula 1-3.

In Formula 1-1 to Formula 1-3, X₂ to X₄ may each independently be O, S, or Se. At least one of X₂ and X₃ may be O. X₄ may be O or S.

In Formula 1-1 to Formula 1-3, R₆ and R₇ may each independently be hydrogen, deuterium, —F, a cyano group, a C₁-C₆₀ alkyl group unsubstituted or substituted with at least one R₁₀ₐ, a C₁-C₆₀ alkoxy group unsubstituted or substituted with at least one R₁₀ₐ, a C₆-C₆₀ aryl group unsubstituted or substituted with at least one R₁₀ₐ, or a C₁-C₆₀ heteroaryl group unsubstituted or substituted with at least one R₁₀ₐ.

In Formula 1-2, when b6 is 2 to 4, a plurality of Re may be identical to or different from each other. In Formula 1-3, when b6 is 2 to 6, a plurality of Re may be identical to or different from each other.

In one or more embodiments, in Formula 1, at least one selected from among L₁ and L₂ may be a single bond. In one or more embodiments, in Formula 1, a1 may be 1, L₁ may be a single bond. In one or more embodiments, in Formula 1, a2 may be 1, and L₂ may be a single bond.

In one or more embodiments, a highest occupied molecular orbital (HOMO) energy level of the first compound may be in a range of about −5.5 electron volt (eV) to about −5.0 eV. For example, an absolute value of the HOMO energy level of the first compound may be in a range of about 5.0 eV to about 5.5 eV.

In one or more embodiments, a lowest unoccupied molecular orbital (LUMO) energy level of the first compound may be in a range of about −4.0 eV to about −3.0 eV. For example, an absolute value of the LUMO energy level of the first compound may be in a range of about 3.0 eV to about 4.0 eV.

In one or more embodiments, the first compound may be at least one selected from among Compounds A1 to A108:

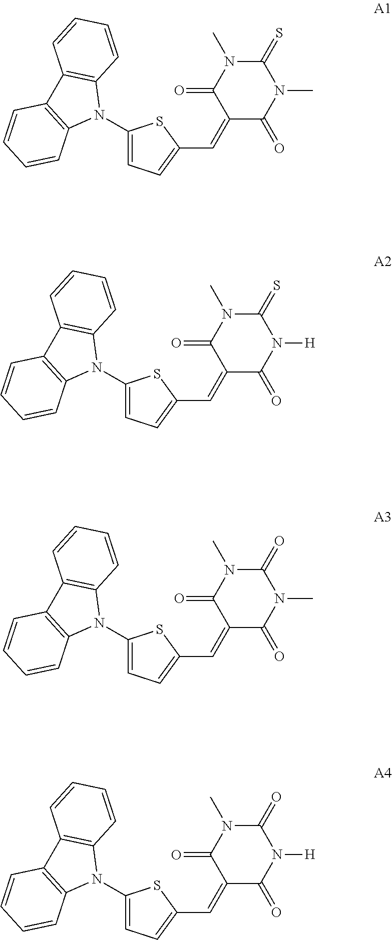 [SMILES: CN1C(=O)C(=Cc2ccc(-n3c4ccccc4c4ccccc43)s2)C(=O)N(C)C1=S ; CN1C(=O)/C(=C\c2ccc(-n3c4ccccc4c4ccccc43)s2)C(=O)NC1=S ; CN1C(=O)C(=Cc2ccc(-n3c4ccccc4c4ccccc43)s2)C(=O)N(C)C1=O ; CN1C(=O)NC(=O)/C(=C/c2ccc(-n3c4ccccc4c4ccccc43)s2)C1=O]

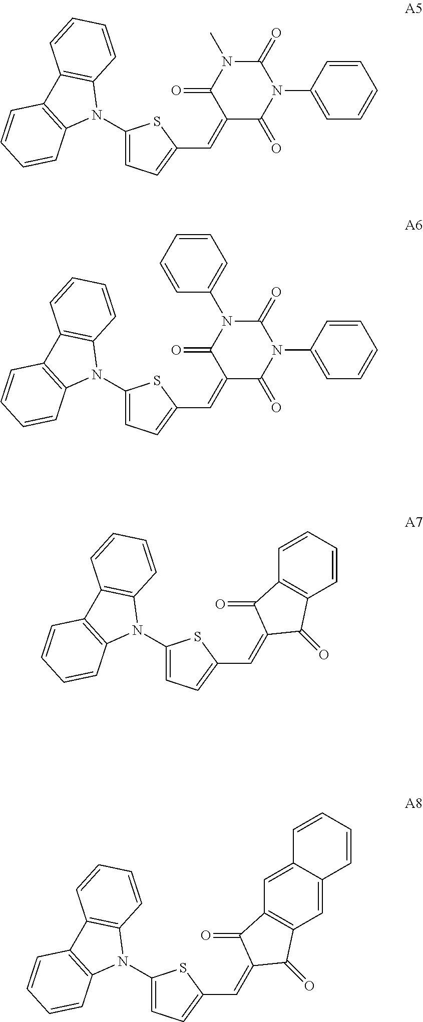 [SMILES: CN1C(=O)/C(=C\c2ccc(-n3c4ccccc4c4ccccc43)s2)C(=O)N(c2ccccc2)C1=O ; O=C1C(=Cc2ccc(-n3c4ccccc4c4ccccc43)s2)C(=O)N(c2ccccc2)C(=O)N1c1ccccc1 ; O=C1C(=Cc2ccc(-n3c4ccccc4c4ccccc43)s2)C(=O)c2ccccc21 ; O=C1C(=Cc2ccc(-n3c4ccccc4c4ccccc43)s2)C(=O)c2cc3ccccc3cc21]

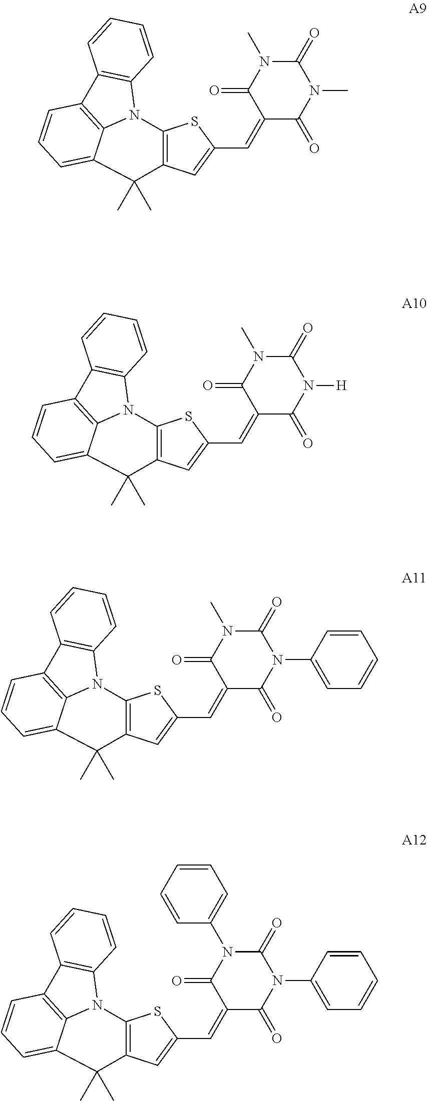 [SMILES: CN1C(=O)C(=Cc2cc3c(s2)-n2c4ccccc4c4cccc(c42)C3(C)C)C(=O)N(C)C1=O ; CN1C(=O)NC(=O)/C(=C/c2cc3c(s2)-n2c4ccccc4c4cccc(c42)C3(C)C)C1=O ; CN1C(=O)/C(=C\c2cc3c(s2)-n2c4ccccc4c4cccc(c42)C3(C)C)C(=O)N(c2ccccc2)C1=O ; CC1(C)c2cc(C=C3C(=O)N(c4ccccc4)C(=O)N(c4ccccc4)C3=O)sc2-n2c3ccccc3c3cccc1c32]

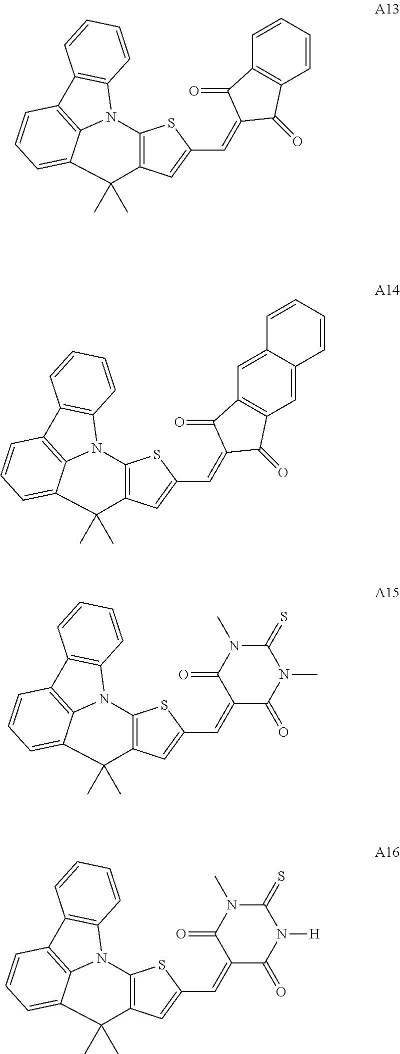 [SMILES: CC1(C)c2cc(C=C3C(=O)c4ccccc4C3=O)sc2-n2c3ccccc3c3cccc1c32 ; CC1(C)c2cc(C=C3C(=O)c4cc5ccccc5cc4C3=O)sc2-n2c3ccccc3c3cccc1c32 ; CN1C(=O)C(=Cc2cc3c(s2)-n2c4ccccc4c4cccc(c42)C3(C)C)C(=O)N(C)C1=S ; CN1C(=O)/C(=C\c2cc3c(s2)-n2c4ccccc4c4cccc(c42)C3(C)C)C(=O)NC1=S]

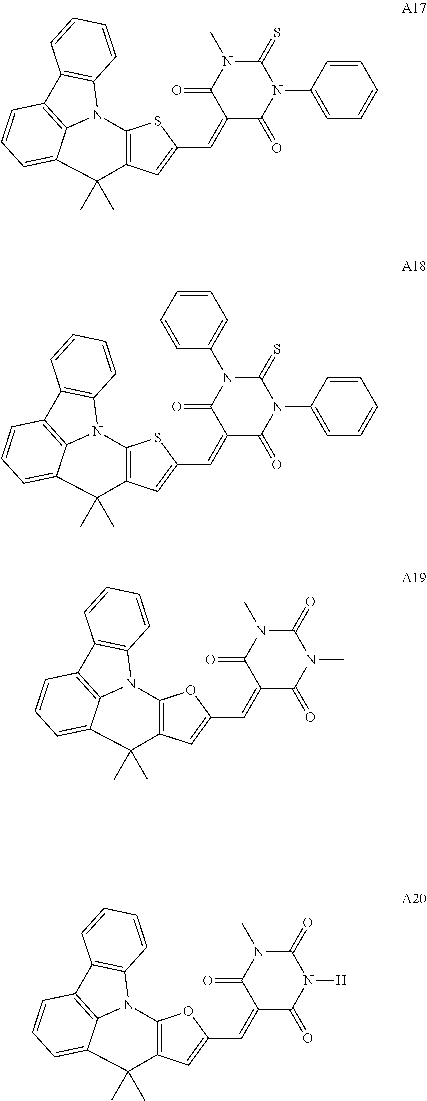 [SMILES: CN1C(=O)/C(=C\c2cc3c(s2)-n2c4ccccc4c4cccc(c42)C3(C)C)C(=O)N(c2ccccc2)C1=S ; CC1(C)c2cc(C=C3C(=O)N(c4ccccc4)C(=S)N(c4ccccc4)C3=O)sc2-n2c3ccccc3c3cccc1c32 ; CN1C(=O)C(=Cc2cc3c(o2)-n2c4ccccc4c4cccc(c42)C3(C)C)C(=O)N(C)C1=O ; CN1C(=O)NC(=O)/C(=C/c2cc3c(o2)-n2c4ccccc4c4cccc(c42)C3(C)C)C1=O]

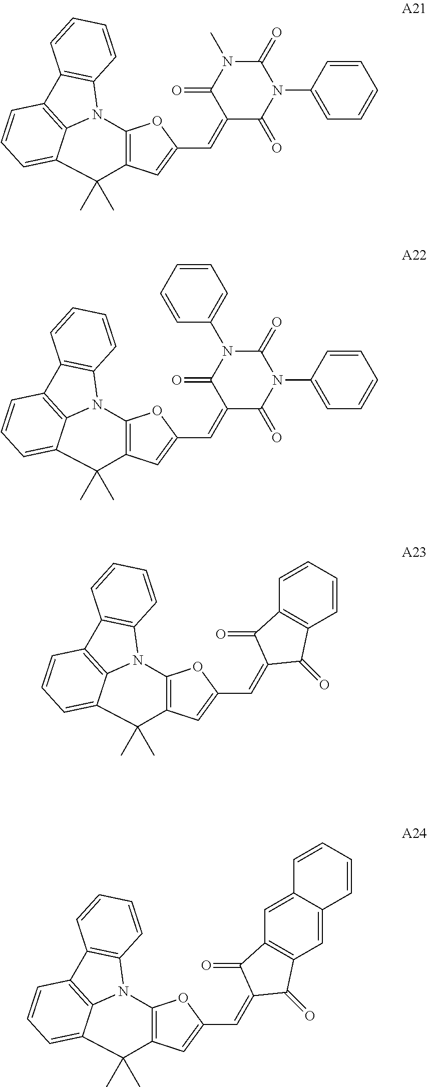 [SMILES: CN1C(=O)/C(=C\c2cc3c(o2)-n2c4ccccc4c4cccc(c42)C3(C)C)C(=O)N(c2ccccc2)C1=O ; CC1(C)c2cc(C=C3C(=O)N(c4ccccc4)C(=O)N(c4ccccc4)C3=O)oc2-n2c3ccccc3c3cccc1c32 ; CC1(C)c2cc(C=C3C(=O)c4ccccc4C3=O)oc2-n2c3ccccc3c3cccc1c32 ; CC1(C)c2cc(C=C3C(=O)c4cc5ccccc5cc4C3=O)oc2-n2c3ccccc3c3cccc1c32]

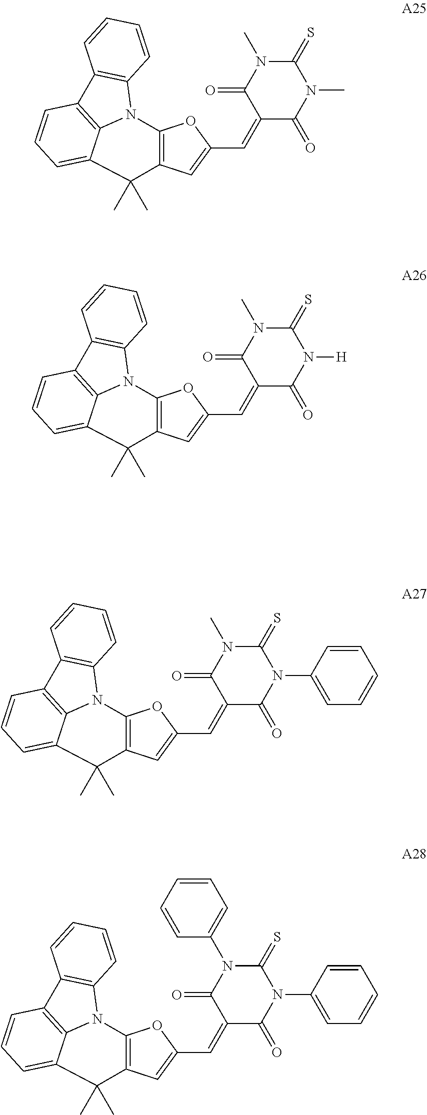 [SMILES: CN1C(=O)C(=Cc2cc3c(o2)-n2c4ccccc4c4cccc(c42)C3(C)C)C(=O)N(C)C1=S ; CN1C(=O)/C(=C\c2cc3c(o2)-n2c4ccccc4c4cccc(c42)C3(C)C)C(=O)NC1=S ; CN1C(=O)/C(=C\c2cc3c(o2)-n2c4ccccc4c4cccc(c42)C3(C)C)C(=O)N(c2ccccc2)C1=S ; CC1(C)c2cc(C=C3C(=O)N(c4ccccc4)C(=S)N(c4ccccc4)C3=O)oc2-n2c3ccccc3c3cccc1c32]

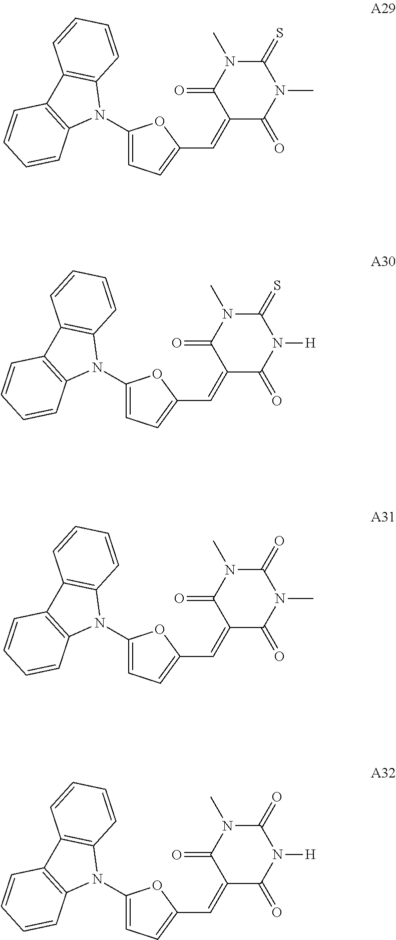 [SMILES: CN1C(=O)C(=Cc2ccc(-n3c4ccccc4c4ccccc43)o2)C(=O)N(C)C1=S ; CN1C(=O)/C(=C\c2ccc(-n3c4ccccc4c4ccccc43)o2)C(=O)NC1=S ; CN1C(=O)C(=Cc2ccc(-n3c4ccccc4c4ccccc43)o2)C(=O)N(C)C1=O ; CN1C(=O)NC(=O)/C(=C/c2ccc(-n3c4ccccc4c4ccccc43)o2)C1=O]

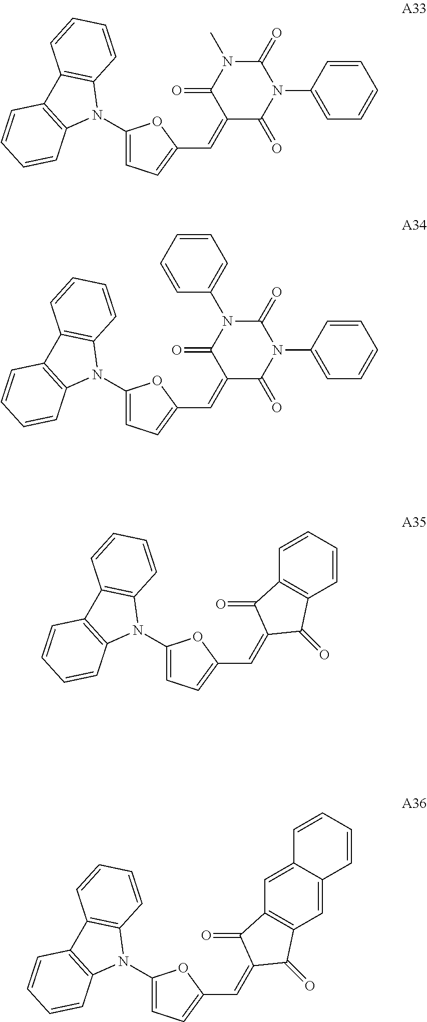 [SMILES: CN1C(=O)/C(=C\c2ccc(-n3c4ccccc4c4ccccc43)o2)C(=O)N(c2ccccc2)C1=O ; O=C1C(=Cc2ccc(-n3c4ccccc4c4ccccc43)o2)C(=O)N(c2ccccc2)C(=O)N1c1ccccc1 ; O=C1C(=Cc2ccc(-n3c4ccccc4c4ccccc43)o2)C(=O)c2ccccc21 ; O=C1C(=Cc2ccc(-n3c4ccccc4c4ccccc43)o2)C(=O)c2cc3ccccc3cc21]

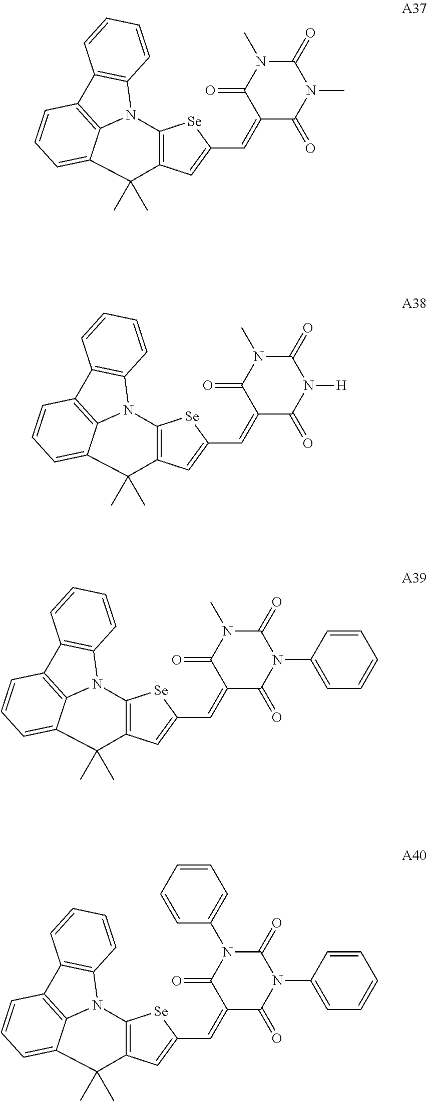 [SMILES: CN1C(=O)C(=Cc2cc3c([se]2)-n2c4ccccc4c4cccc(c42)C3(C)C)C(=O)N(C)C1=O ; CN1C(=O)NC(=O)/C(=C/c2cc3c([se]2)-n2c4ccccc4c4cccc(c42)C3(C)C)C1=O ; CN1C(=O)/C(=C\c2cc3c([se]2)-n2c4ccccc4c4cccc(c42)C3(C)C)C(=O)N(c2ccccc2)C1=O ; CC1(C)c2cc(C=C3C(=O)N(c4ccccc4)C(=O)N(c4ccccc4)C3=O)[se]c2-n2c3ccccc3c3cccc1c32]

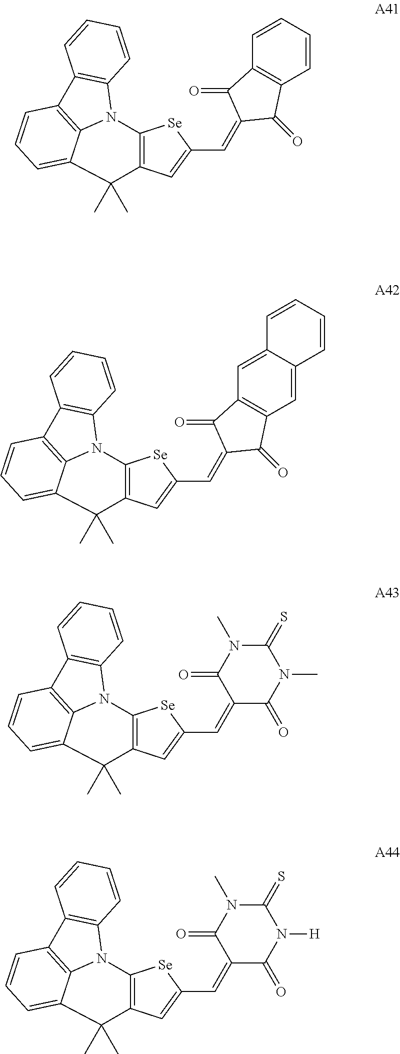 [SMILES: CC1(C)c2cc(C=C3C(=O)c4ccccc4C3=O)[se]c2-n2c3ccccc3c3cccc1c32 ; CC1(C)c2cc(C=C3C(=O)c4cc5ccccc5cc4C3=O)[se]c2-n2c3ccccc3c3cccc1c32 ; CN1C(=O)C(=Cc2cc3c([se]2)-n2c4ccccc4c4cccc(c42)C3(C)C)C(=O)N(C)C1=S ; CN1C(=O)/C(=C\c2cc3c([se]2)-n2c4ccccc4c4cccc(c42)C3(C)C)C(=O)NC1=S]

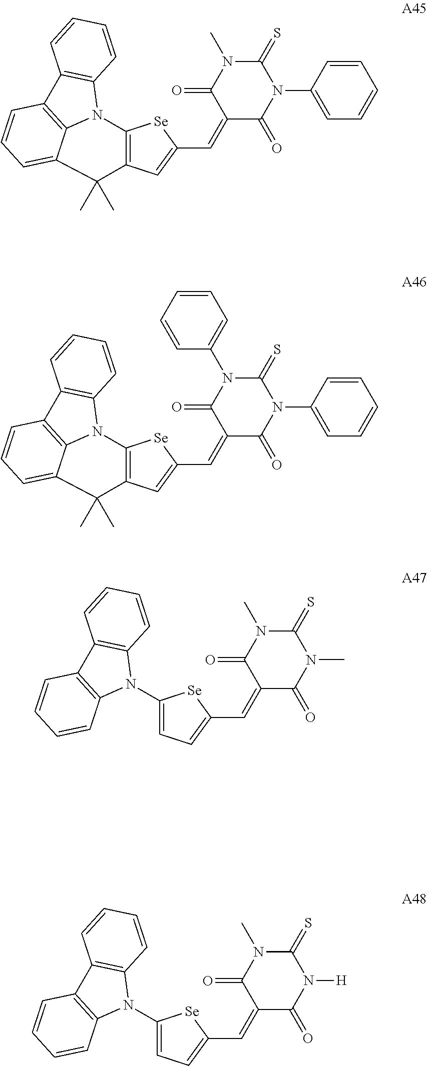 [SMILES: CN1C(=O)/C(=C\c2cc3c([se]2)-n2c4ccccc4c4cccc(c42)C3(C)C)C(=O)N(c2ccccc2)C1=S ; CC1(C)c2cc(C=C3C(=O)N(c4ccccc4)C(=S)N(c4ccccc4)C3=O)[se]c2-n2c3ccccc3c3cccc1c32 ; CN1C(=O)C(=Cc2ccc(-n3c4ccccc4c4ccccc43)[se]2)C(=O)N(C)C1=S ; CN1C(=O)/C(=C\c2ccc(-n3c4ccccc4c4ccccc43)[se]2)C(=O)NC1=S]

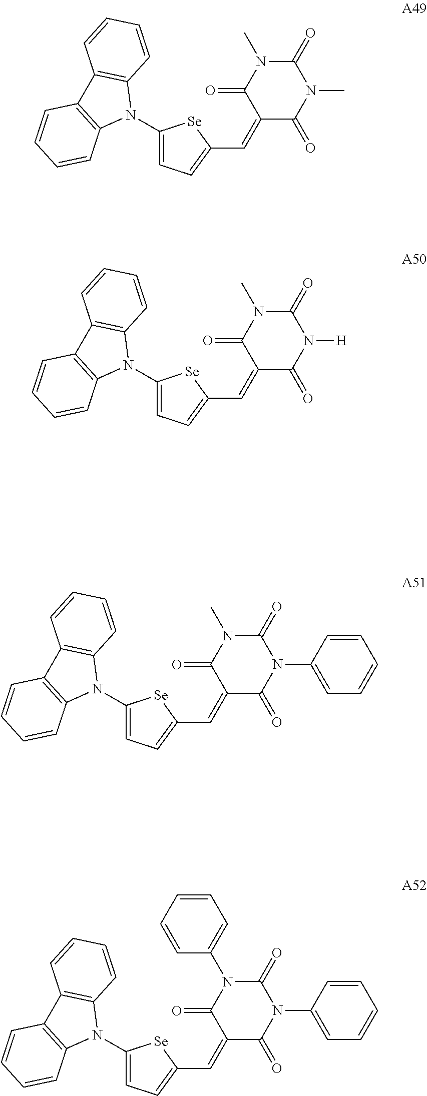 [SMILES: CN1C(=O)C(=Cc2ccc(-n3c4ccccc4c4ccccc43)[se]2)C(=O)N(C)C1=O ; CN1C(=O)NC(=O)/C(=C/c2ccc(-n3c4ccccc4c4ccccc43)[se]2)C1=O ; CN1C(=O)/C(=C\c2ccc(-n3c4ccccc4c4ccccc43)[se]2)C(=O)N(c2ccccc2)C1=O ; O=C1C(=Cc2ccc(-n3c4ccccc4c4ccccc43)[se]2)C(=O)N(c2ccccc2)C(=O)N1c1ccccc1]

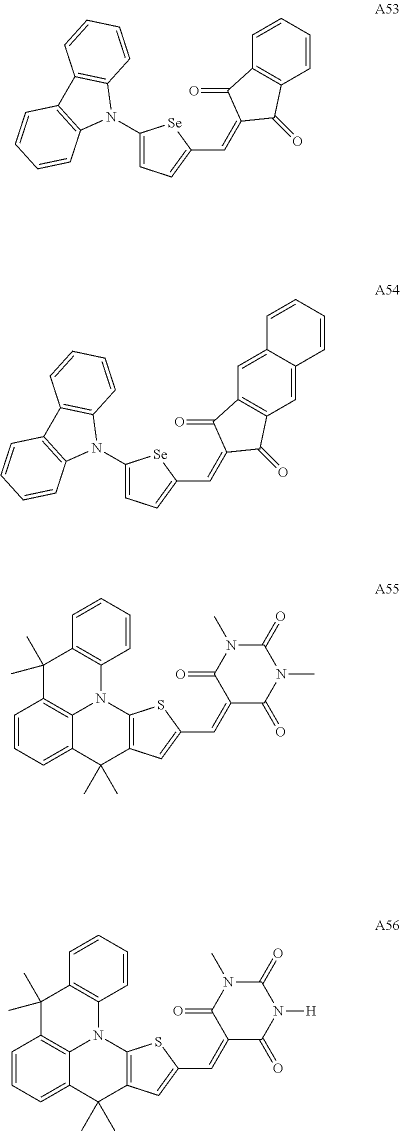

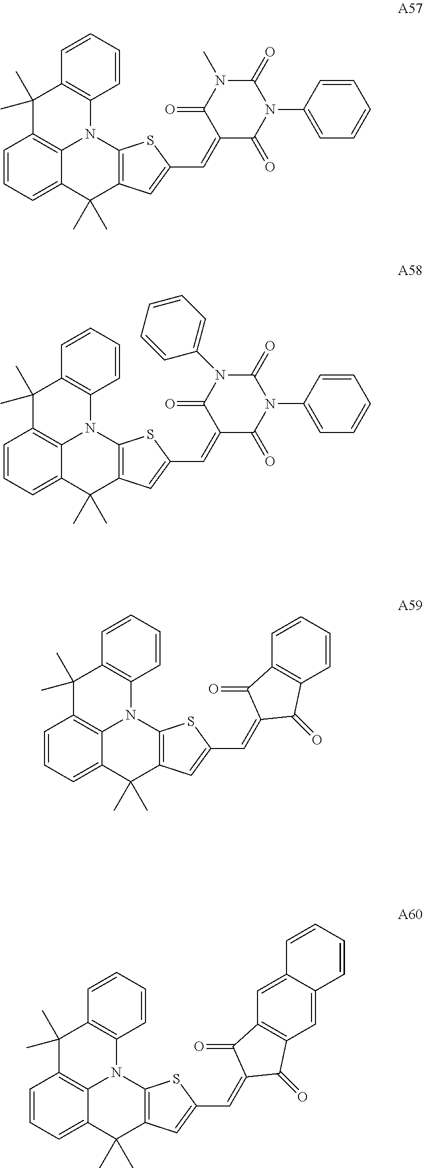 [SMILES: CN1C(=O)/C(=C\c2cc3c(s2)N2c4ccccc4C(C)(C)c4cccc(c42)C3(C)C)C(=O)N(c2ccccc2)C1=O ; CC1(C)c2ccccc2N2c3sc(C=C4C(=O)N(c5ccccc5)C(=O)N(c5ccccc5)C4=O)cc3C(C)(C)c3cccc1c32 ; CC1(C)c2ccccc2N2c3sc(C=C4C(=O)c5ccccc5C4=O)cc3C(C)(C)c3cccc1c32 ; CC1(C)c2ccccc2N2c3sc(C=C4C(=O)c5cc6ccccc6cc5C4=O)cc3C(C)(C)c3cccc1c32]

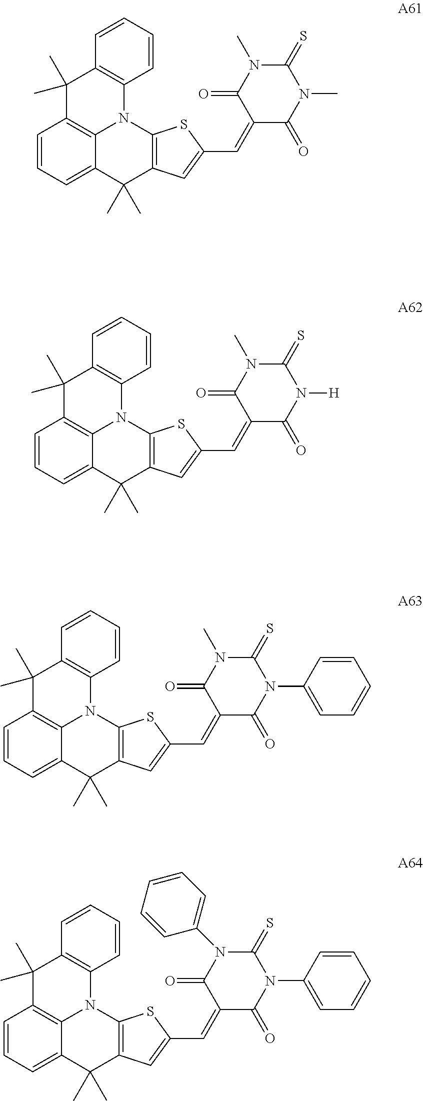

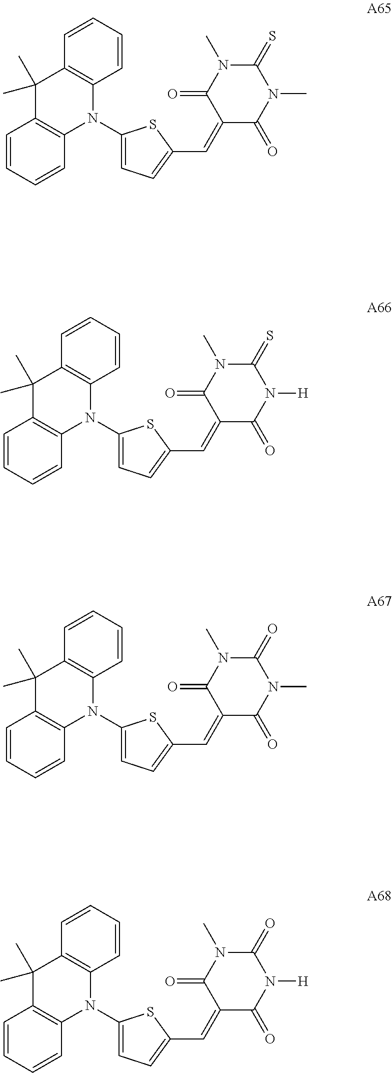

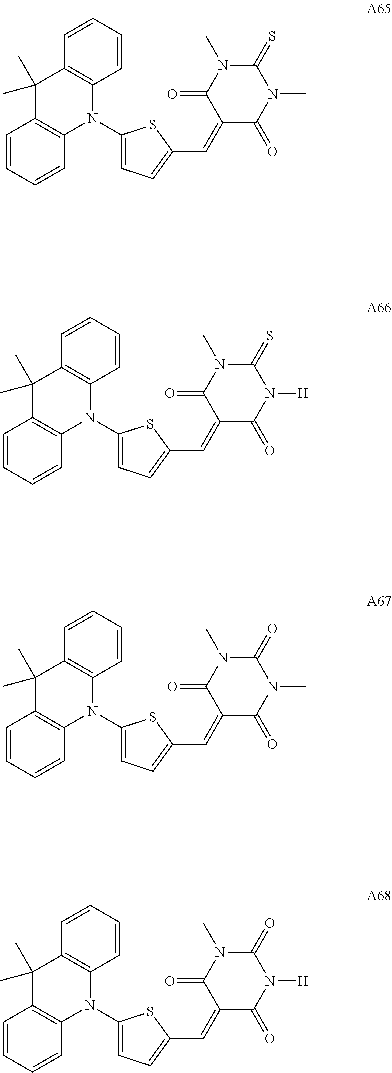

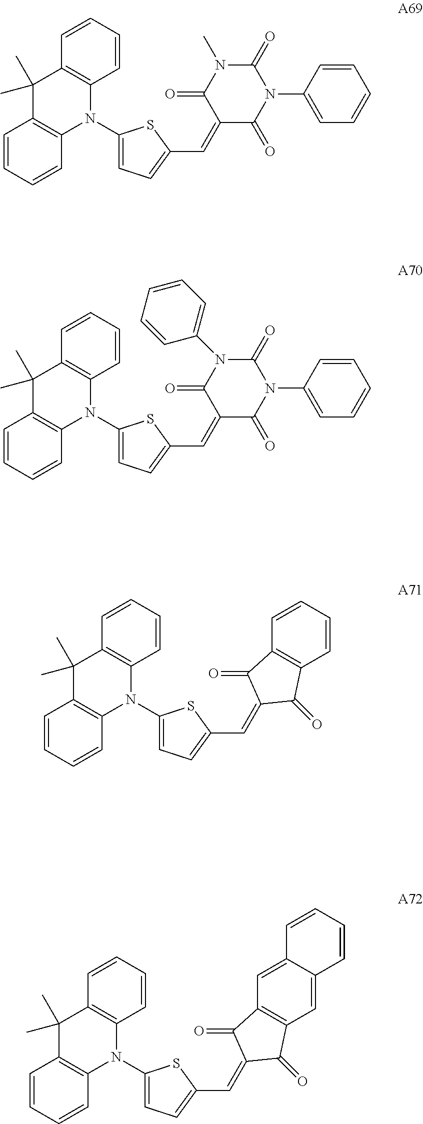 [SMILES: CN1C(=O)/C(=C\c2ccc(N3c4ccccc4C(C)(C)c4ccccc43)s2)C(=O)N(c2ccccc2)C1=O ; CC1(C)c2ccccc2N(c2ccc(C=C3C(=O)N(c4ccccc4)C(=O)N(c4ccccc4)C3=O)s2)c2ccccc21 ; CC1(C)c2ccccc2N(c2ccc(C=C3C(=O)c4ccccc4C3=O)s2)c2ccccc21 ; CC1(C)c2ccccc2N(c2ccc(C=C3C(=O)c4cc5ccccc5cc4C3=O)s2)c2ccccc21]

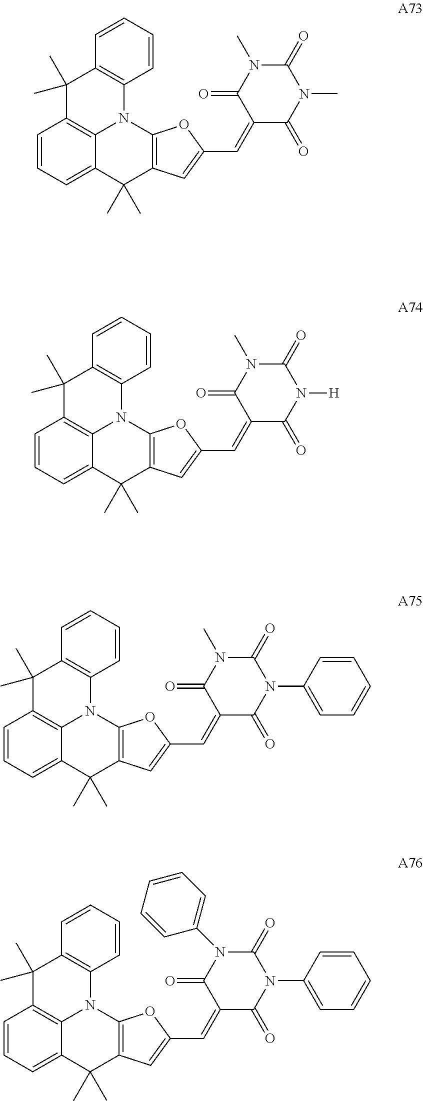

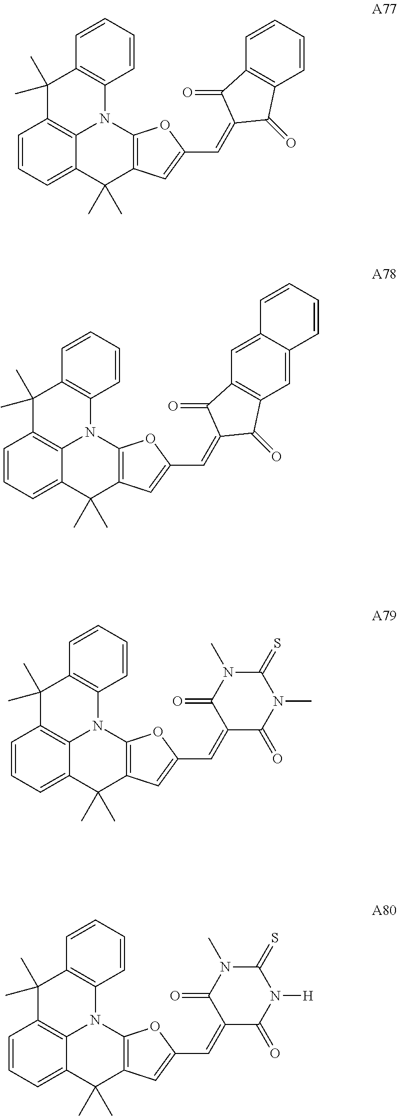

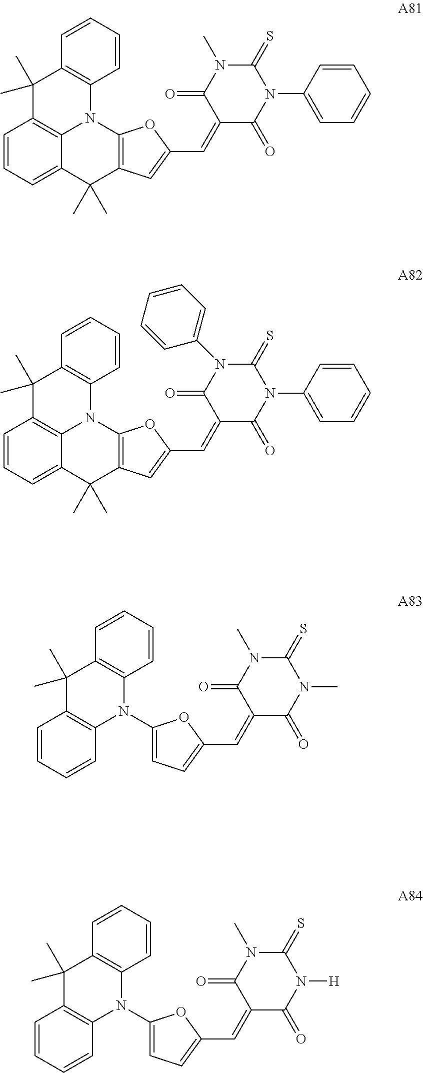

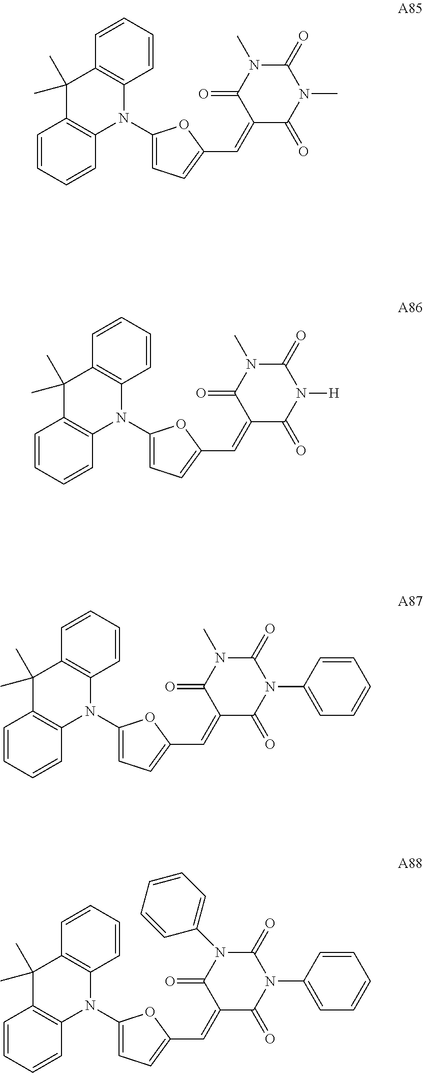

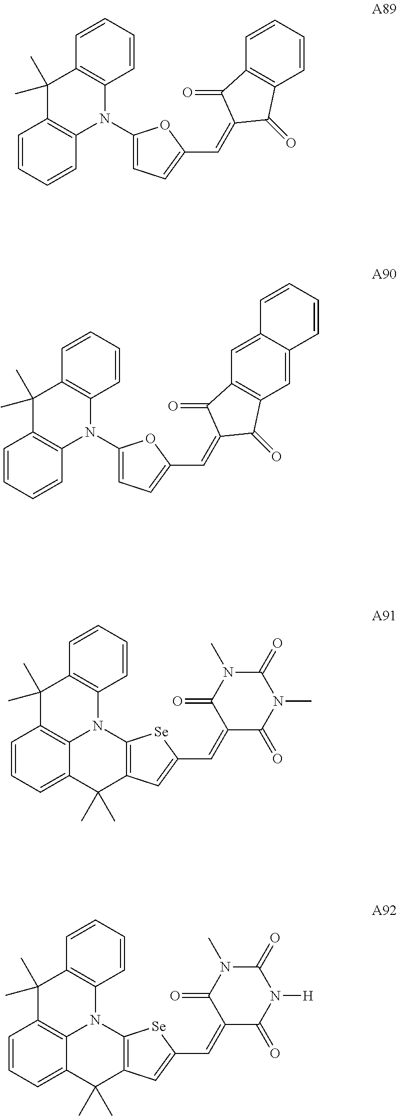

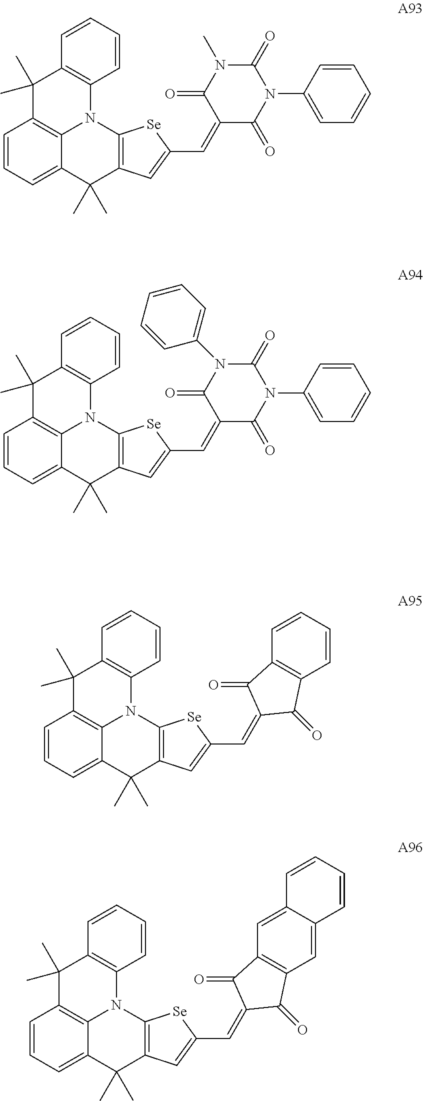 [SMILES: CN1C(=O)/C(=C\c2cc3c([se]2)N2c4ccccc4C(C)(C)c4cccc(c42)C3(C)C)C(=O)N(c2ccccc2)C1=O ; CC1(C)c2ccccc2N2c3[se]c(C=C4C(=O)N(c5ccccc5)C(=O)N(c5ccccc5)C4=O)cc3C(C)(C)c3cccc1c32 ; CC1(C)c2ccccc2N2c3[se]c(C=C4C(=O)c5ccccc5C4=O)cc3C(C)(C)c3cccc1c32 ; CC1(C)c2ccccc2N2c3[se]c(C=C4C(=O)c5cc6ccccc6cc5C4=O)cc3C(C)(C)c3cccc1c32]

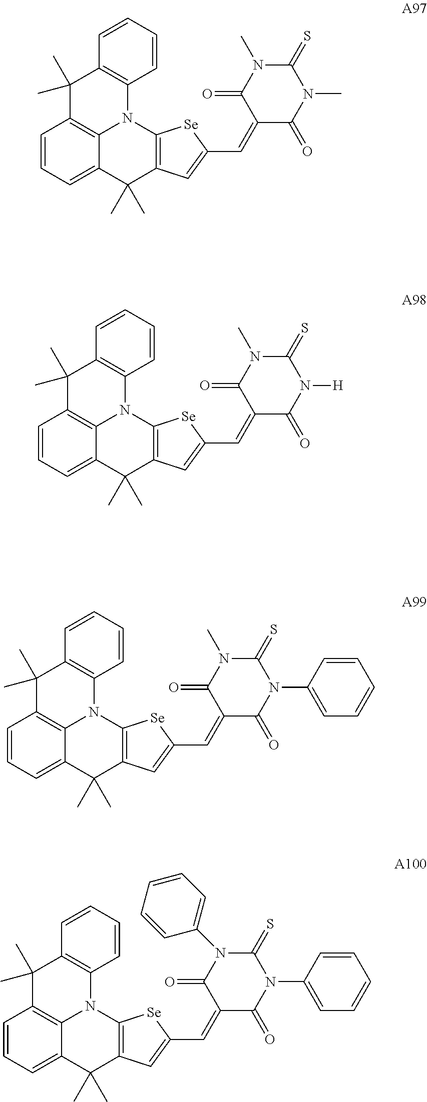

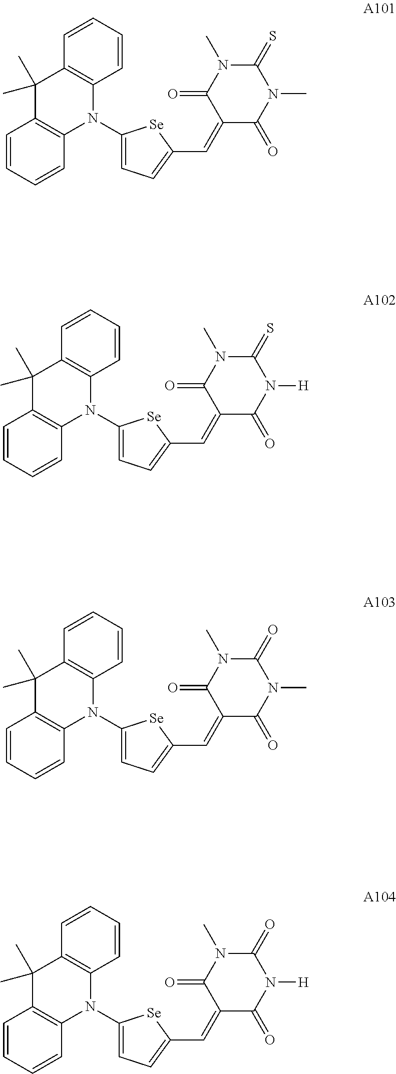

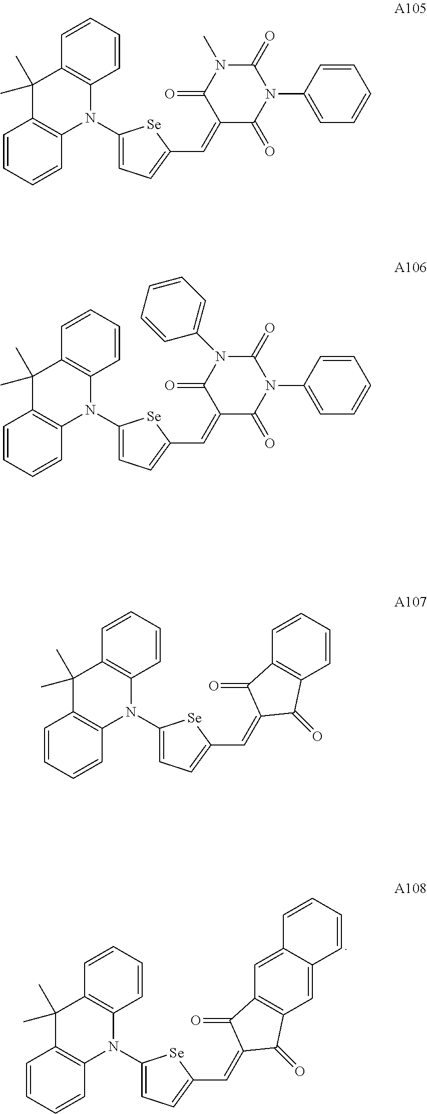 [SMILES: CN1C(=O)/C(=C\c2ccc(N3c4ccccc4C(C)(C)c4ccccc43)[se]2)C(=O)N(c2ccccc2)C1=O ; CC1(C)c2ccccc2N(c2ccc(C=C3C(=O)N(c4ccccc4)C(=O)N(c4ccccc4)C3=O)[se]2)c2ccccc21 ; CC1(C)c2ccccc2N(c2ccc(C=C3C(=O)c4ccccc4C3=O)[se]2)c2ccccc21 ; CC1(C)c2ccccc2N(c2ccc(C=C3C(=O)c4cc5ccccc5cc4C3=O)[se]2)c2ccccc21]

The first compound included in the composition described herein may be the same as a first compound included in an optoelectronic device, an electronic apparatus, or electronic equipment described herein, and thus, a description of the first compound will not be provided in the description of the optoelectronic device, the electronic apparatus, or the electronic equipment.

### Second Compound

The second compound may be represented by Formula 2. The second compound may be to absorb light having a wavelength in a range of about 400 nm to about 1,000 nm. The second compound may be to absorb blue light, green light, red light, near-infrared light, and/or any combination thereof. For example, the second compound may be to absorb red light having a maximum absorption wavelength in a range of about 600 nm to about 750 nm.

In Formula 2, Ar₁₁ may be a group represented by Formula 2-1. In Formula 2-1, Ar₁₂ and Ar₁₃ may each independently be a C₃-C₁ cycloalkyl group unsubstituted or substituted with at least one R₁₀ₐ, a C₁-C₁₀ heterocycloalkyl group unsubstituted or substituted with at least one R₁₀ₐ, a C₃-C₁ cycloalkenyl group unsubstituted or substituted with at least one R₁₀ₐ, a C₁-C₁₀ heterocycloalkenyl group unsubstituted or substituted with at least one R₁₀ₐ, a C₆-C₆₀ aryl group unsubstituted or substituted with at least one R₁₀ₐ, or a C₁-C₆₀ heteroaryl group unsubstituted or substituted with at least one R₁₀ₐ. For example, the moiety represented by Formula 2-1 may be a condensed ring in which three monocyclic rings are condensed. Accordingly, the moiety represented by Formula 2-1 is clearly (and/or should be apparent to one skilled in the art to be) different from a condensed ring in which two, four, or five monocyclic rings are condensed.

In one or more embodiments, in Formula 2-1, Ar₁₂ and Ar₁₃ may each independently be a cyclopentadiene group unsubstituted or substituted with at least one R₁₀ₐ, a benzene group unsubstituted or substituted with at least one R₁₀ₐ, a pyrimidine group unsubstituted or substituted with at least one R₁₀ₐ, a thiophene group unsubstituted or substituted with at least one R₁₀ₐ, a pyrrole group unsubstituted or substituted with at least one R₁₀ₐ, or a furan group unsubstituted or substituted with at least one R₁₀ₐ.

In one or more embodiments, the moiety represented by Formula 2-1 may be a moiety represented by at least one of Formulae 2-1A to 2-11:

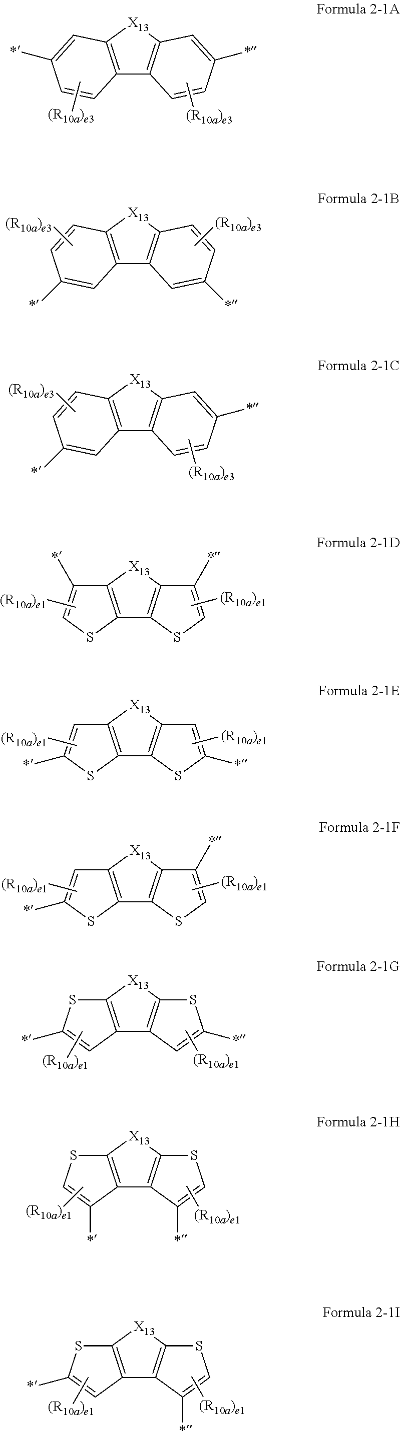

wherein, in Formulae 2-1A to 2-11,
X₁₃, R₁₀ₐ, *′, and *″ are each as described herein, and
e1 may be an integer from 0 or 1.
e3 may be an integer from 0 to 3.
In one or more embodiments, in Formulae 2-1 and 2-1A to 2-11,
X₁₃ may be C(R₁₃ₐ)(R_{13b}) or N(R₁₃), and
R₁₃, R₁₃ₐ, and R_{13b} may each independently be selected from:
hydrogen, deuterium, —F, —Cl, and a cyano group; and
a C₁-C₁ alkyl group, a C₆-C₆₀ aryl group, or a C₁-C₆₀ heteroaryl group, each unsubstituted or substituted with deuterium, —F, —Cl, a cyano group, or any combination thereof.

In one or more embodiments, in Formula 2, X₁₁ may be N(R₁₁) or S, and X₁₂ may be N(R₁₂) or S, and
R₁₁ and R₁₂ may each independently be selected from:
hydrogen, deuterium, —F, —Cl, and a cyano group; and
a C₁-C₁ alkyl group, a C₆-C₆₀ aryl group, or a C₁-C₆₀ heteroaryl group, each unsubstituted or substituted with deuterium, —F, —Cl, a cyano group, or any combination thereof.

In one or more embodiments, in Formula 2, at least two of (e.g., at least two selected from among) Y₁₄ to Y₁₆ may each be N, and at least two of (e.g., at least two selected from among) Y₁₇ to Y₁₉ may each be N.

In one or more embodiments, in Formula 2, Y₁₄ may be C(R₁₄), Y₁₅ may be N or C(R₁₅), Y₁₆ may be N or C(R₁₆), Y₁₇ may be N or C(R₁₇), Y₁₈ may be N or C(R₁₈), and Y₁₉ may be C(R₁₉),
R₁₄ to R₁₉ may each independently be selected from:
hydrogen, deuterium, —F, —Cl, —Br, —I, and a cyano group;
a C₁-C₁ alkyl group unsubstituted or substituted with deuterium, —F, —Cl, —Br, —I, a cyano group, or any combination thereof; and
a C₆-C₁ aryl group unsubstituted or substituted with deuterium, —F, —Cl, —Br, —I, a cyano group, or any combination thereof.

In one or more embodiments, at least one of R₁₄ to R₁₉ may be selected from:
hydrogen, deuterium, —F, and a cyano group;
a C₁-C₁ alkyl group unsubstituted or substituted with deuterium, —F, a cyano group, or any combination thereof; and
a C₆-C₁a aryl group unsubstituted or substituted with deuterium, —F, a cyano group, or any combination thereof.

In one or more embodiments, a HOMO energy level of the second compound may be in a range of about −6.5 eV to about −5.0 eV. For example, an absolute value of the HOMO energy level of the second compound may be in a range of about 5.0 eV to about 6.5 eV. For example, the HOMO energy level of the second compound may be in a range of about −6.0 eV to about −5.5 eV, and the absolute value of the HOMO energy level of the second compound may be in a range of about 5.5 eV to about 6.0 eV.

In one or more embodiments, a LUMO energy level of the second compound may be in a range of about −4.5 eV to about −3.0 eV. For example, an absolute value of the LUMO energy level of the second compound may be in a range of about 3.0 eV to about 4.5 eV.

In one or more embodiments, the second compound may be at least one selected from among Compounds B1 to B50:

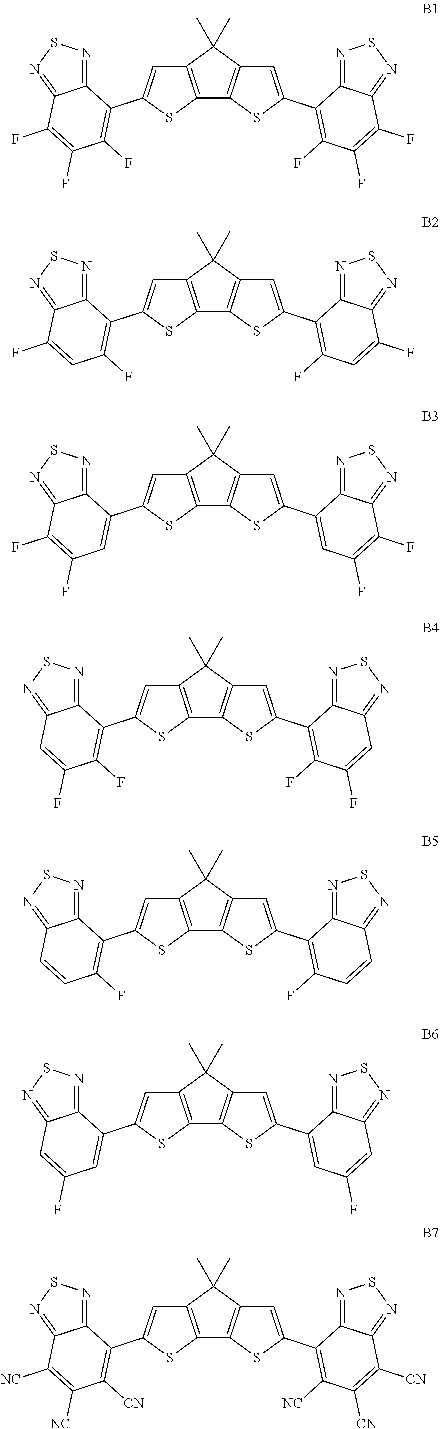

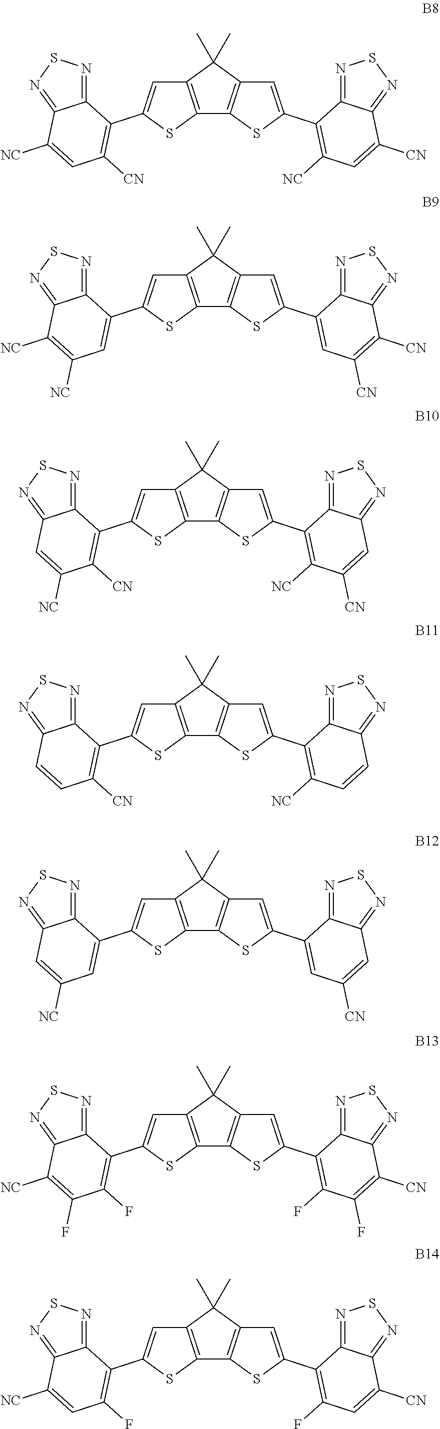

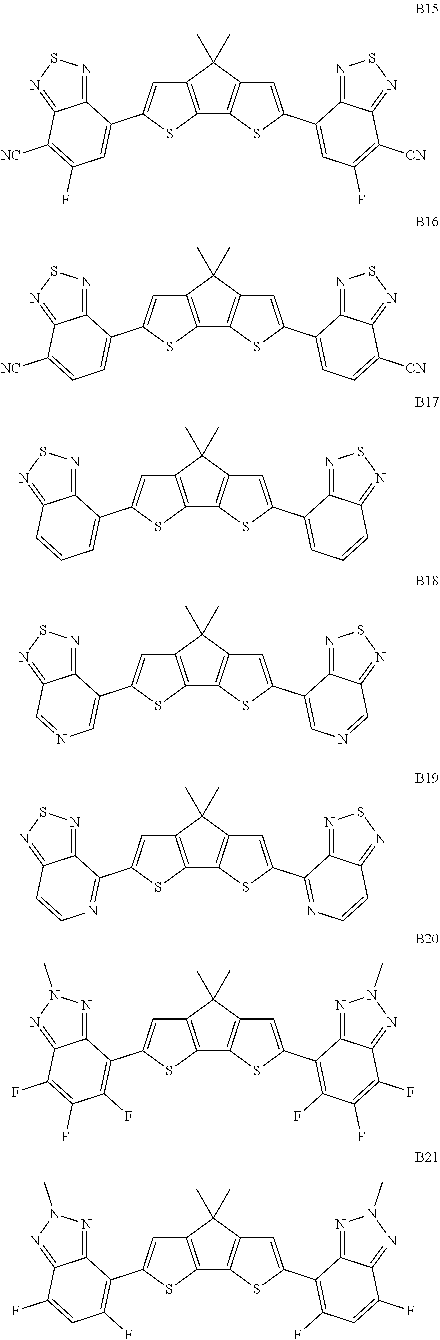

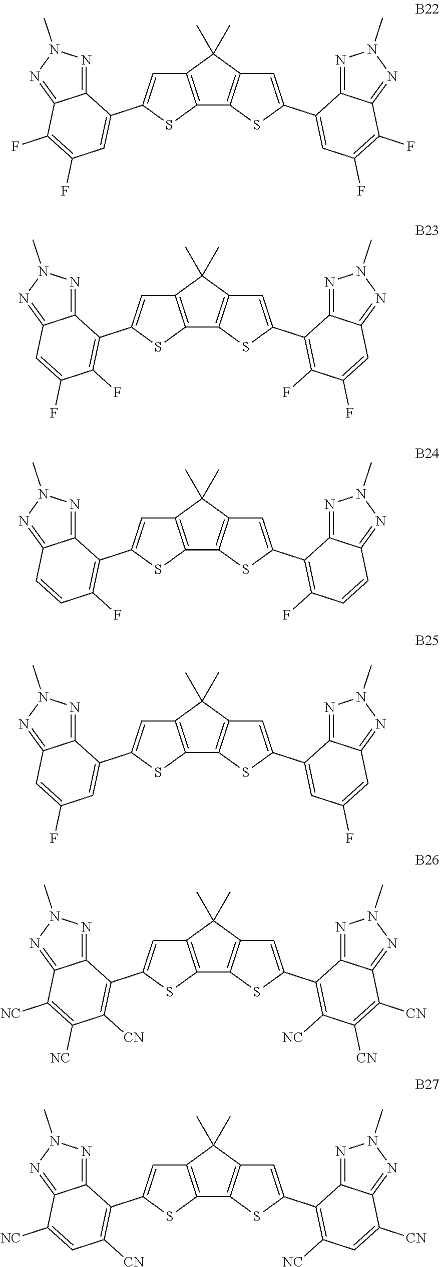 [SMILES: Cn1nc2c(-c3cc4c(s3)-c3sc(-c5cc(F)c(F)c6nn(C)nc56)cc3C4(C)C)cc(F)c(F)c2n1 ; Cn1nc2cc(F)c(F)c(-c3cc4c(s3)-c3sc(-c5c(F)c(F)cc6nn(C)nc56)cc3C4(C)C)c2n1 ; Cn1nc2ccc(F)c(-c3cc4c(s3)-c3sc(-c5c(F)ccc6nn(C)nc56)cc3C4(C)C)c2n1 ; Cn1nc2cc(F)cc(-c3cc4c(s3)-c3sc(-c5cc(F)cc6nn(C)nc56)cc3C4(C)C)c2n1 ; Cn1nc2c(C#N)c(C#N)c(C#N)c(-c3cc4c(s3)-c3sc(-c5c(C#N)c(C#N)c(C#N)c6nn(C)nc56)cc3C4(C)C)c2n1 ; Cn1nc2c(C#N)cc(C#N)c(-c3cc4c(s3)-c3sc(-c5c(C#N)cc(C#N)c6nn(C)nc56)cc3C4(C)C)c2n1]

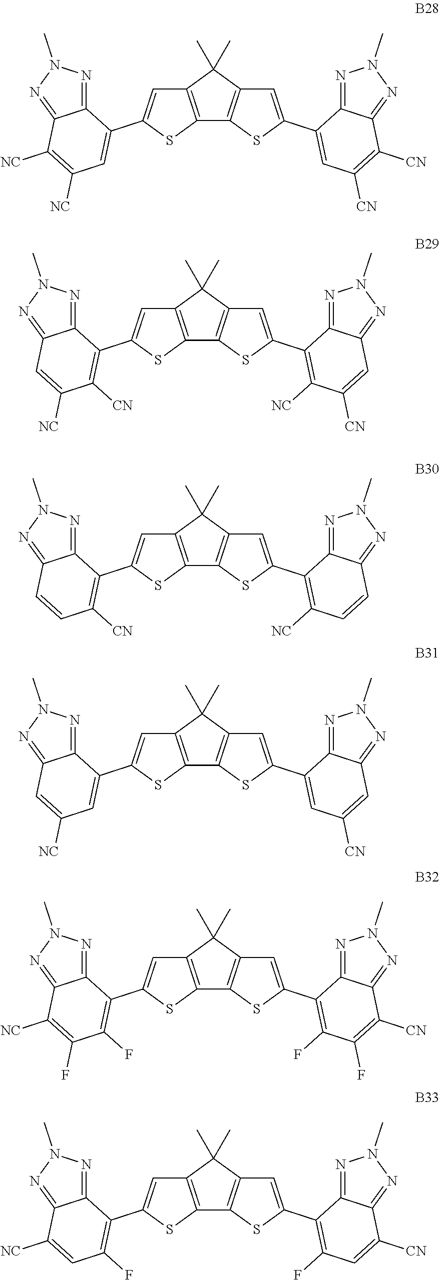 [SMILES: Cn1nc2c(-c3cc4c(s3)-c3sc(-c5cc(C#N)c(C#N)c6nn(C)nc56)cc3C4(C)C)cc(C#N)c(C#N)c2n1 ; Cn1nc2cc(C#N)c(C#N)c(-c3cc4c(s3)-c3sc(-c5c(C#N)c(C#N)cc6nn(C)nc56)cc3C4(C)C)c2n1 ; Cn1nc2ccc(C#N)c(-c3cc4c(s3)-c3sc(-c5c(C#N)ccc6nn(C)nc56)cc3C4(C)C)c2n1 ; Cn1nc2cc(C#N)cc(-c3cc4c(s3)-c3sc(-c5cc(C#N)cc6nn(C)nc56)cc3C4(C)C)c2n1 ; Cn1nc2c(C#N)c(F)c(F)c(-c3cc4c(s3)-c3sc(-c5c(F)c(F)c(C#N)c6nn(C)nc56)cc3C4(C)C)c2n1 ; Cn1nc2c(C#N)cc(F)c(-c3cc4c(s3)-c3sc(-c5c(F)cc(C#N)c6nn(C)nc56)cc3C4(C)C)c2n1]

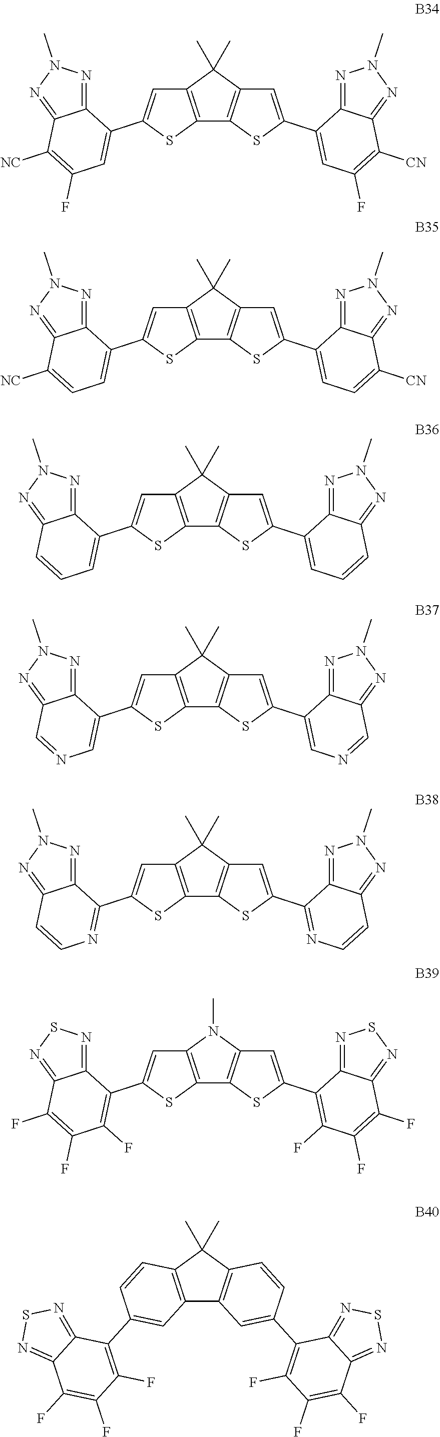

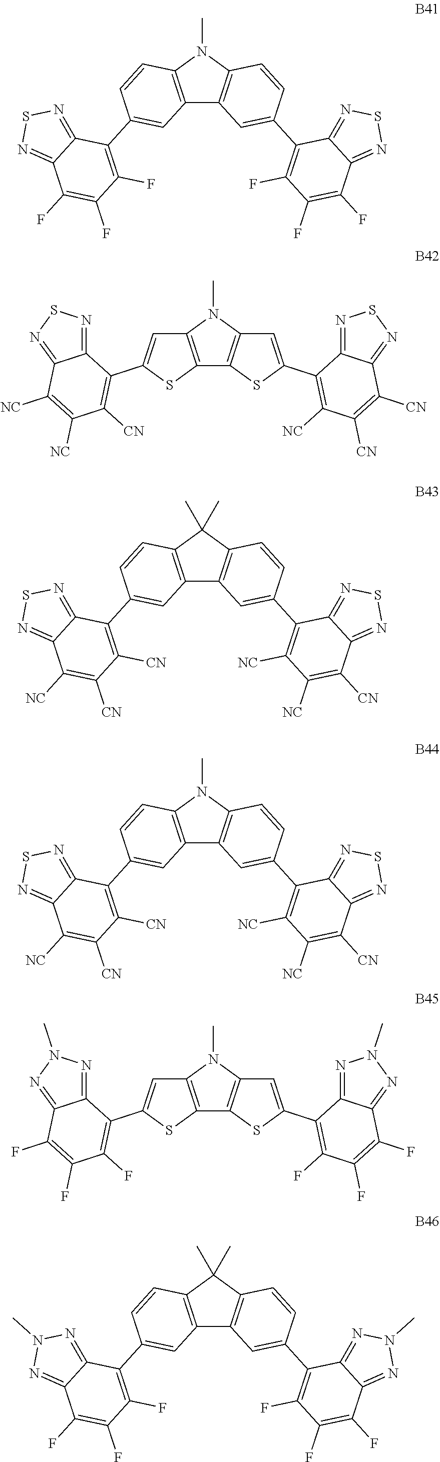

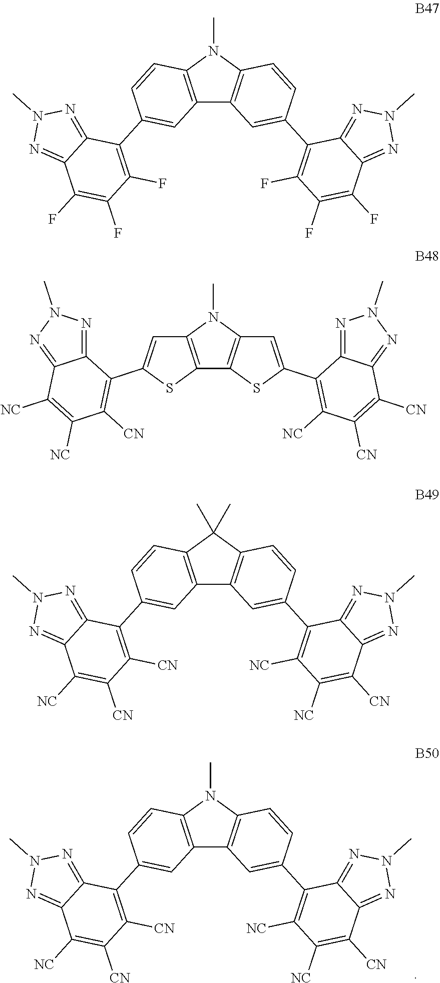

The second compound included in the composition described herein is the same as a second compound included in an optoelectronic device, an electronic apparatus, or electronic equipment described herein, and thus, a description of the second compound will not be provided in the description of the optoelectronic device, the electronic apparatus, or the electronic equipment.

### Third Compound

The third compound may be represented by Formula 3. Accordingly, the third compound is clearly (and/or should be apparent to one skilled in the art to be (e.g., upon observation)) different from (e.g., each of) a fullerene-based compound and a subphthalocyanine-based compound. The fullerene-based compound has a deposition temperature of about 400° C. or more, for example, in a range of about 400° C. to about 500° C. Accordingly, high-temperature deposition is required when the fullerene-based compound is utilized, and thus, the fullerene-based compound is not suitable for utilization as a material for an optoelectronic device. For example, to ensure processability, the third compound may have a deposition temperature of less than about 400° C. As a result, when the third compound is utilized instead of the fullerene-based compound, deposition may be performed at a relatively low temperature, and thus, an optoelectronic device may be manufactured more easily.

For example, the deposition temperature of the third compound may be about 350° C. or less, in a range of about 100° C. to about 300° C., or in a range of about 200° C. to about 300° C.

The third compound may be to absorb light having a wavelength in a range of about 400 nm to about 1,000 nm. The third compound may be to absorb blue light, green light, red light, near-infrared light, and/or any combination thereof.

In one or more embodiments, in Formula 3, at least one of X₂₁ to X₂₄ may be 0.

In one or more embodiments, in Formula 3, Z₁ may be N(R₂₅), and Z₂ may be N(R₂₆), and
R₂₁ to R₂₆ may each independently be selected from:
hydrogen, deuterium, —F, —Cl, and a cyano group;
a C₁-C₁ alkyl group unsubstituted or substituted with deuterium, —F, —Cl, a cyano group, or any combination thereof;
a C₆-C₁ aryl group unsubstituted or substituted with deuterium, —F, —Cl, a cyano group, —CF₃, or any combination thereof; and
a C₆-C₁ heteroaryl group unsubstituted or substituted with deuterium, —F, —Cl, a cyano group, —CF₃, or any combination thereof.

In one or more embodiments, a HOMO energy level of the third compound may be in a range of about −7.4 eV to about −6.5 eV. For example, an absolute value of the HOMO energy level of the third compound may be in a range of about 6.5 eV to about 7.4 eV. For example, because HOMO energy of fullerene C60 is −6.4 eV, the third compound may not be a fullerene-based compound.

In one or more embodiments, a LUMO energy level of the third compound may be about −3.5 eV or more. For example, an absolute value of the LUMO energy level of the third compound may be about 3.5 eV or less. For example, because LUMO energy of fullerene C60 is −3.7 eV, the third compound may not be a fullerene-based compound.

In one or more embodiments, the third compound may be at least one selected from among Compounds C1 to C15:

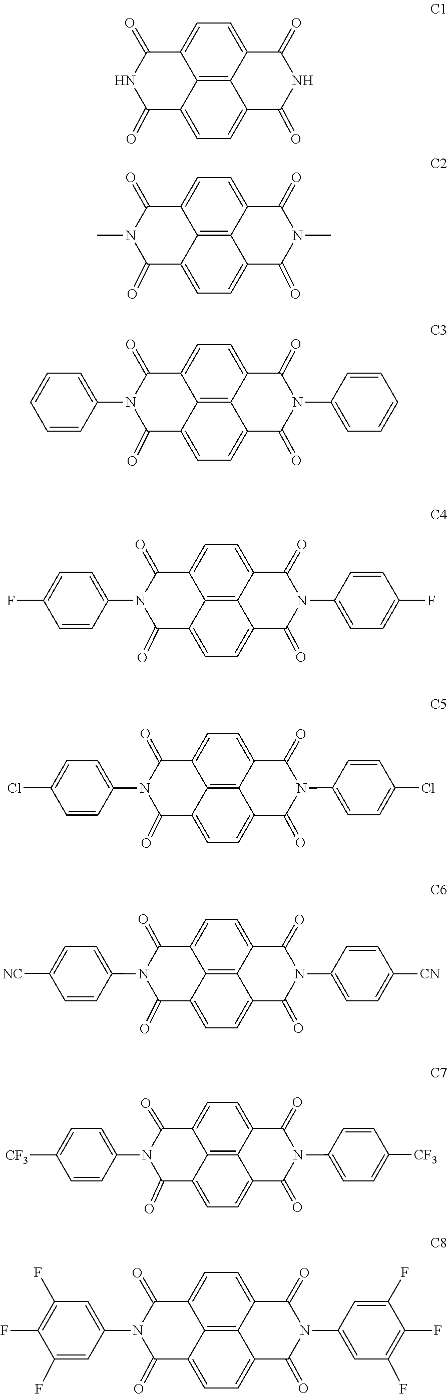

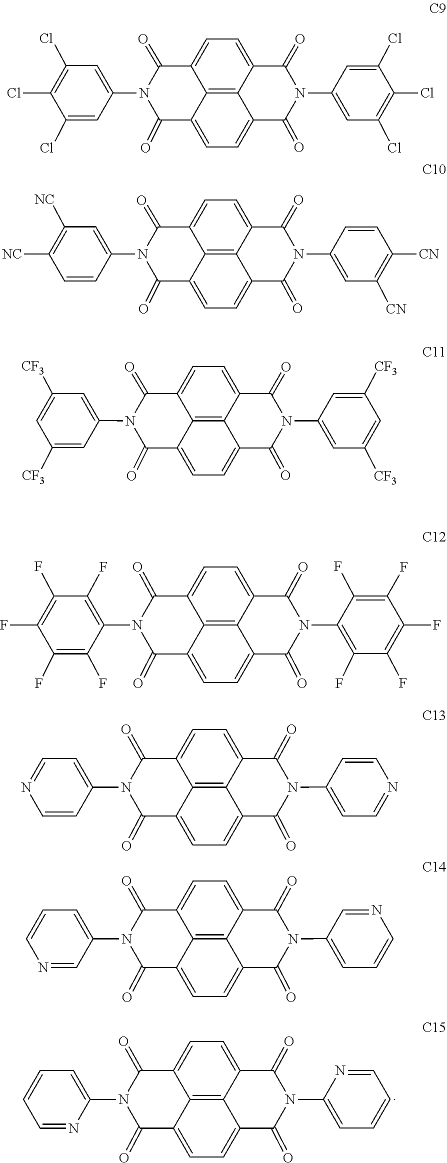

The third compound included in the composition described herein may be the same as a third compound included in an optoelectronic device, an electronic apparatus, or electronic equipment described herein, and thus, a description of the third compound will not be provided in the description of the optoelectronic device, the electronic apparatus, or the electronic equipment.

Because the composition includes each (e.g., all) of the first compound, the second compound, and the third compound, by vacuum-depositing the composition, an optical activation layer including each (e.g., all) of the first to third compounds may be easily manufactured in one chamber process.

### Electronic Apparatus

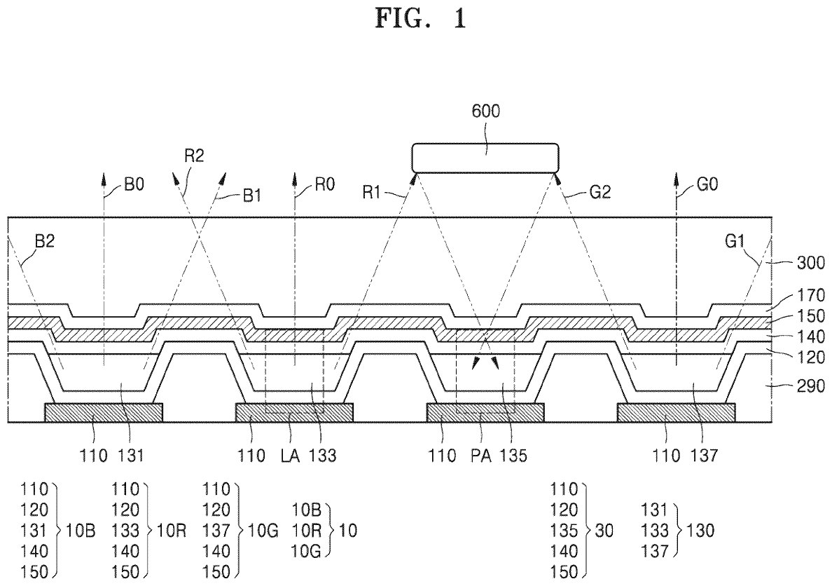

FIG. 1 is a cross-sectional view schematically illustrating a portion of an electronic apparatus according to one or more embodiments.

An aspect of the present disclosure provides an electronic apparatus including: a first electrode 110; a second electrode 150 facing the first electrode 110; an optical activation layer 135 between the first electrode 110 and the second electrode 150; and an emission layer 130, for example, first to third emission layers 131, 133, and 137, not overlapping the optical activation layer 135 between the first electrode 110 and the second electrode 150, wherein the optical activation layer 135 includes the first compound represented by Formula 1, the second compound represented by Formula 2, and the third compound represented by Formula 3.

The electronic apparatus may include a light-emitting device 10, for example, first to third light-emitting devices 10B, 10R, and 10G, and an optoelectronic device 30. The electronic apparatus may be a display apparatus, a light-emitting apparatus, an authentication apparatus, and/or the like. For example, the authentication apparatus may be a biometric authentication apparatus that authenticates an individual by utilizing biometric information (e.g., fingertips, pupils, and/or the like). For example, the electronic apparatus may be to emit light and collect biometric information.

The electronic apparatus may be applied to one or more suitable displays, light sources, lighting, personal computers (e.g., a mobile personal computer), mobile phones, digital cameras, electronic organizers, electronic dictionaries, electronic game machines, medical instruments (e.g., an electronic thermometer, a sphygmomanometer, a blood glucose meter, a pulse measurement device, a pulse wave measurement device, an electrocardiogram display, an ultrasonic diagnostic device, and an endoscope display), fish finders, one or more suitable measuring instruments, meters (e.g., meters for a vehicle, an aircraft, and a vessel), projectors, sensors (e.g., a vehicle sensor, a household sensor, and a fingerprint recognition sensor), solar cells, and/or the like.

Referring to FIG. 1, the electronic apparatus may further include a substrate, a thin-film transistor, and/or the like arranged below the first electrode(s) 110, may further include a pixel defining layer 290 for separating the first electrode 110, and may further include a capping layer 170, an encapsulation portion 300, a color filter, a color conversion layer, and/or the like arranged above the second electrode 150.

The light-emitting device 10 may include the first light-emitting device 10B emitting first-color lights B0, B1, and B2, the second light-emitting device 10R emitting second-color lights R0, R1, and R2, and the third light-emitting device 10G emitting third-color lights G0, G1, and G2. For example, the first color may be blue, the second color may be red, and the third color may be green, but embodiments are not limited thereto.

Some of the lights emitted from the first to third light-emitting devices 10B, 10G, and 10R, for example, the second-color light R1 and the third-color light G2, may be incident on an object 600 outside (e.g., and above) the electronic apparatus. For example, the object 600 may be a finger of a user of the electronic apparatus. Light reflected from the object 600 may be incident on the optoelectronic device 30. Accordingly, the optoelectronic device 30 may serve as an optical sensor, and this aspect is described in more detail herein.

### Capping Layer 170

The first capping layer may be arranged outside the first electrode 110, and/or the second capping layer may be arranged outside the second electrode 150. In detail, the light-emitting device 10 may have a structure in which the first capping layer, the first electrode 110, the emission layer 130, and the second electrode 150 are sequentially stacked in the stated order, a structure in which the first electrode 110, the emission layer 130, the second electrode 150, and the second capping layer are sequentially stacked in the stated order, or a structure in which the first capping layer, the first electrode 110, the emission layer 130, the second electrode 150, and the second capping layer are sequentially stacked in the stated order.

Light generated in the emission layer 130 of the light-emitting device 10 may be extracted toward the outside through the first electrode 110, which may be a semi-transmissive electrode or a transmissive electrode, and the first capping layer. Light generated in the emission layer 130 of the light-emitting device 10 may be extracted toward the outside through the second electrode 150, which may be a semi-transmissive electrode or a transmissive electrode, and the second capping layer.

The first capping layer and the second capping layer may increase external emission efficiency according to the principle of constructive interference. Accordingly, the light extraction efficiency of the light-emitting device 10 is increased, so that the luminescence efficiency of the light-emitting device 10 may be improved.

Each of the first capping layer and the second capping layer may include a material having a refractive index of about 1.6 or more (at about 450 nm to about 750 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and/or the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof. In one or more embodiments, at least one of the first capping layer and/or the second capping layer may each independently include an amine group-containing compound.

In one or more embodiments, at least one of the first capping layer and/or the second capping layer may each independently include a compound represented by Formula 201, a compound represented by Formula 202, or any combination thereof.

In one or more embodiments, at least one of the first capping layer and the second capping layer may each independently include at least one of Compounds HT28 to HT33, one of Compounds CP1 to CP6, β-NPB, or any combination thereof:

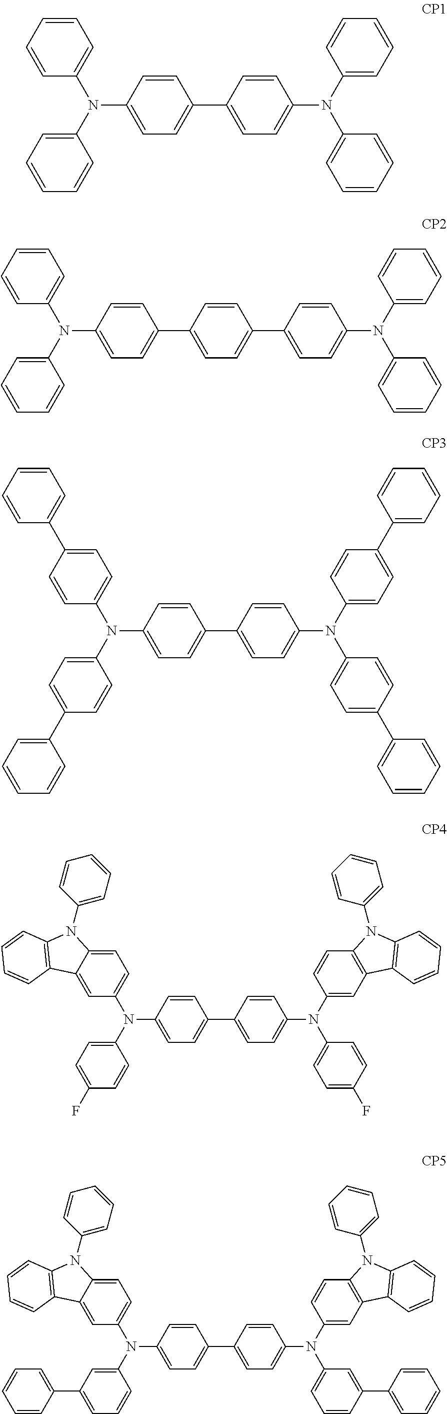 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

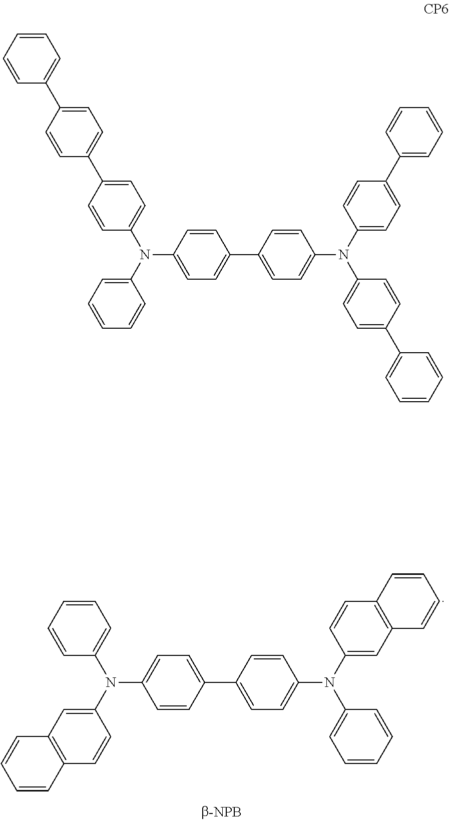 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### Film

The electronic apparatus may include a film. The film may be, for example, an optical member (or a light control component) (e.g., a color filter, a color conversion member, a capping layer, a light extraction efficiency enhancement layer, a selective light absorbing layer, a polarizing layer, a quantum dot-containing layer, and/or the like), a light blocking member (e.g., a light reflective layer, a light absorbing layer, and/or the like), a protective member (e.g., an insulating layer, a dielectric layer, and/or the like), and/or the like.

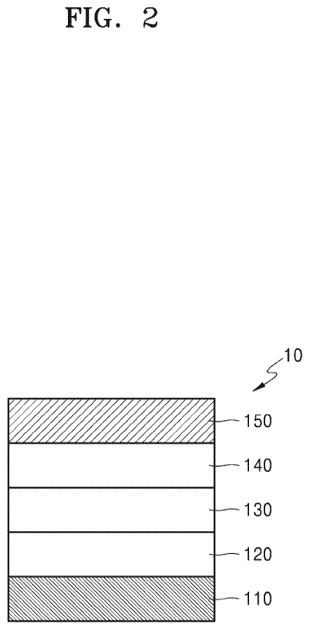

FIG. 2 is a diagram illustrating an example of an enlarged view of a region LA of a light-emitting device 10 included in the electronic apparatus of FIG. 1.

Referring to FIG. 2, the light-emitting device 10 may include a first electrode 110, a second electrode 150 facing the first electrode 110, an emission layer 130 between the first electrode 110 and the second electrode 150, a hole transport region 120 between the first electrode 110 and the emission layer 130, and an electron transport region 140 between the emission layer 130 and the second electrode 150.

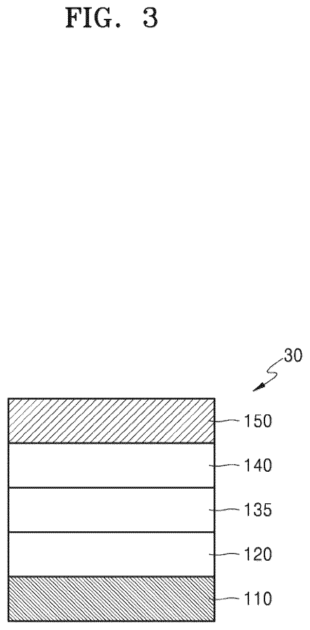

FIG. 3 is a diagram illustrating an example of an enlarged view of a region PA of an optoelectronic device 30 included in the electronic apparatus of FIG. 1.

Referring to FIG. 3, the optoelectronic device 30 may include a first electrode 110, a second electrode 150 facing the first electrode 110, an optical activation layer 135 between the first electrode 110 and the second electrode 150, a hole transport region 120 between the first electrode 110 and the optical activation layer 135, and an electron transport region 140 between the optical activation layer 135 and the second electrode 150.

Referring to FIGS. 1 to 3, the first electrodes 110 of the light-emitting device 10 and the optoelectronic device 30 may include substantially the same material, and may be formed substantially at the same time. The hole transport regions 120 of the light-emitting device 10 and the optoelectronic device 30 may include substantially the same material, may be formed substantially at the same time, and may have substantially one body with each other. The electron transport regions 140 of the light-emitting device 10 and the optoelectronic device 30 may include substantially the same material, may be formed substantially at the same time, and may have substantially one body with each other. The second electrodes 150 of the light-emitting device 10 and the optoelectronic device 30 may include substantially the same material, may be formed substantially at the same time, and may have substantially one body with each other.

Hereinafter, the light-emitting device 10 and the optoelectronic device 30 will be described in more detail.

### First Electrode 110

In FIG. 1, a substrate may be additionally arranged under the first electrode 110 or on the second electrode 150. As the substrate, a glass substrate or a plastic substrate may be utilized. The substrate may be a flexible substrate. For example, the substrate may include plastics with excellent or suitable heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a semi-transmissive electrode, or a transmissive electrode. In one or more embodiments, when the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, when the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layer structure including (e.g., consisting of) a single layer or a multi-layer structure including multiple layers. For example, the first electrode 110 may have a three-layer structure of ITO/Ag/ITO.

### Hole Transport Region 120

The hole transport region 120 may have i) a single-layer structure including (e.g., consisting of) a single layer including (e.g., consisting of) a single material, ii) a single-layer structure including (e.g., consisting of) a single layer including multiple materials that are different from each other, or iii) a multi-layer structure including multiple layers including multiple materials that are different from each other.

The hole transport region 120 may include a hole injection layer, a hole transport layer, an emission auxiliary layer, an electron blocking layer, or any combination thereof.

For example, the hole transport region 120 may have a multi-layer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein constituent layers of each structure are stacked sequentially from the first electrode 110.

The hole transport region 120 may include a compound represented by Formula 201, a compound represented by Formula 202, or any combination thereof:

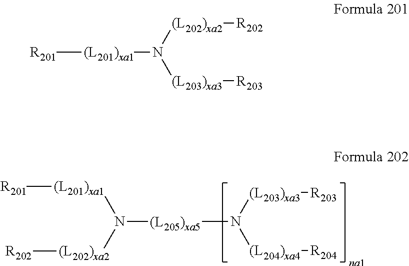

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)—*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (e.g., a carbazole group, and/or the like) unsubstituted or substituted with at least one R₁₀ₐ (e.g., Compound HT16, and/or the like),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

For example, each of Formulae 201 and 202 may include at least one of groups represented by Formulae CY201 to CY217:

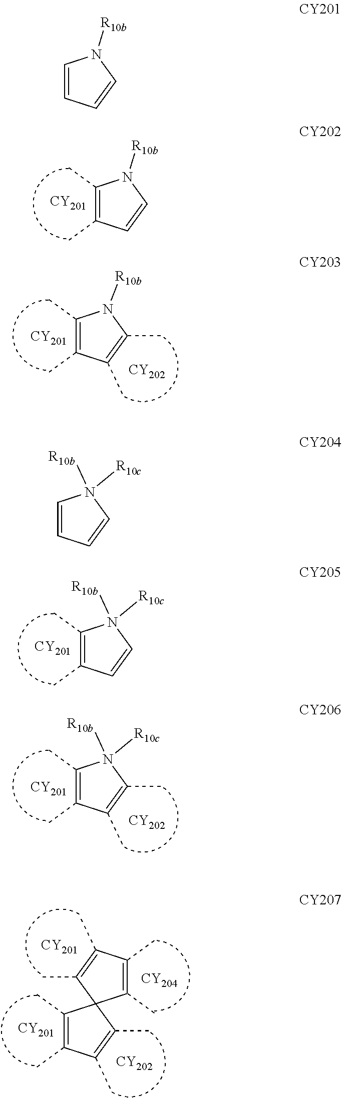

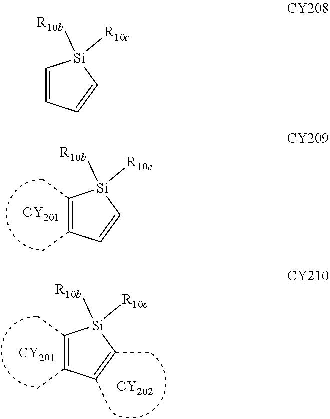

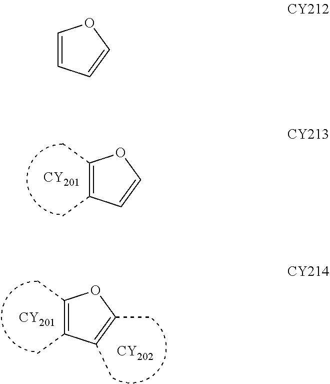

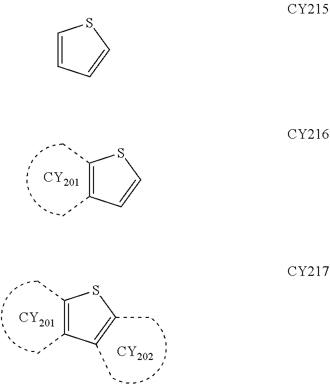

wherein, in Formulae CY201 to CY217, R₁₀ and R_{10c} are each as described in connection with R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In one or more embodiments, in Formulae CY201 to CY217, ring CY201 to ring CY₂₀₄ may each independently be a benzene group, a naphthalene group, a phenanthrene group, or an anthracene group.

In one or more embodiments, each of Formulae 201 and 202 may include at least one of the groups represented by Formulae CY201 to CY203.

In one or more embodiments, Formula 201 may include at least one of the groups represented by Formulae CY201 to CY203 and at least one of the groups represented by Formulae CY204 to CY217.

In one or more embodiments, in Formula 201, xa1 may be 1, R₂₀₁ may be one of the groups represented by Formulae CY201 to CY203, xa2 may be 0, and R₂₀₂ may be one of the groups represented by Formulae CY204 to CY207.

In one or more embodiments, each of Formulae 201 and 202 may not include (e.g., may exclude) the groups represented by Formulae CY201 to CY203.

In one or more embodiments, each of Formulae 201 and 202 may not include (e.g., may exclude) the groups represented by Formulae CY201 to CY203, and may include at least one of the groups represented by Formulae CY204 to CY217.

In one or more embodiments, each of Formulae 201 and 202 may not include (e.g., may exclude) the groups represented by Formulae CY201 to CY217.

For example, the hole transport region 120 may include: at least one of (e.g., selected from among) Compounds HT1 to HT46; m-MTDATA; TDATA; 2-TNATA; NPB(NPD); β-NPB; TPD; spiro-TPD; spiro-NPB; methylated NPB; TAPC; HMTPD; 4,4′,4″-tris(N-carbazolyl)triphenylamine (TCTA); polyaniline/dodecylbenzenesulfonic acid (PANI/DBSA); poly(3,4-ethylenedioxythiophene)/poly(4-styrenesulfonate) (PEDOT/PSS); polyaniline/camphor sulfonic acid (PANI/CSA); polyaniline/poly(4-styrenesulfonate) (PANI/PSS); and/or any combination thereof:

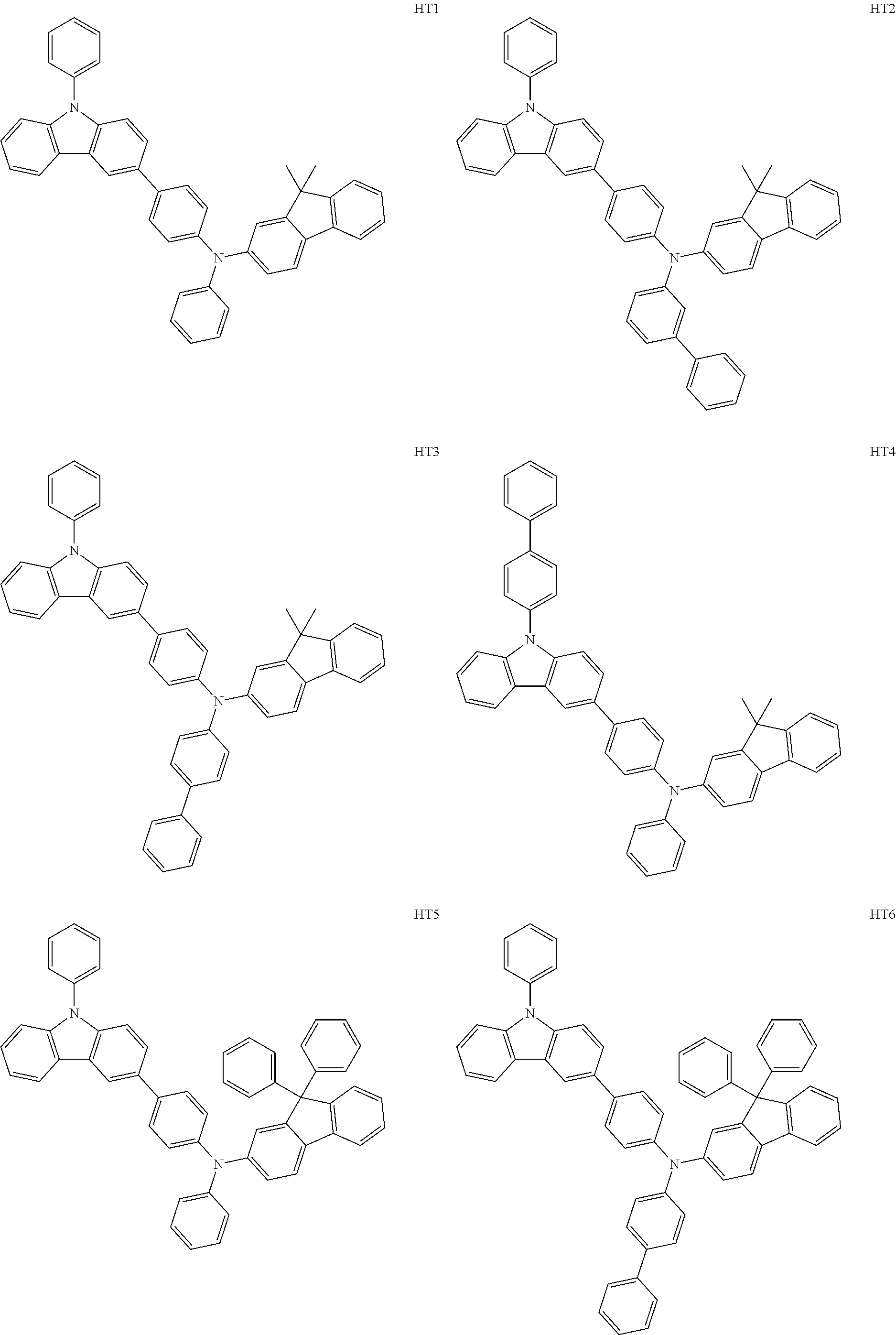

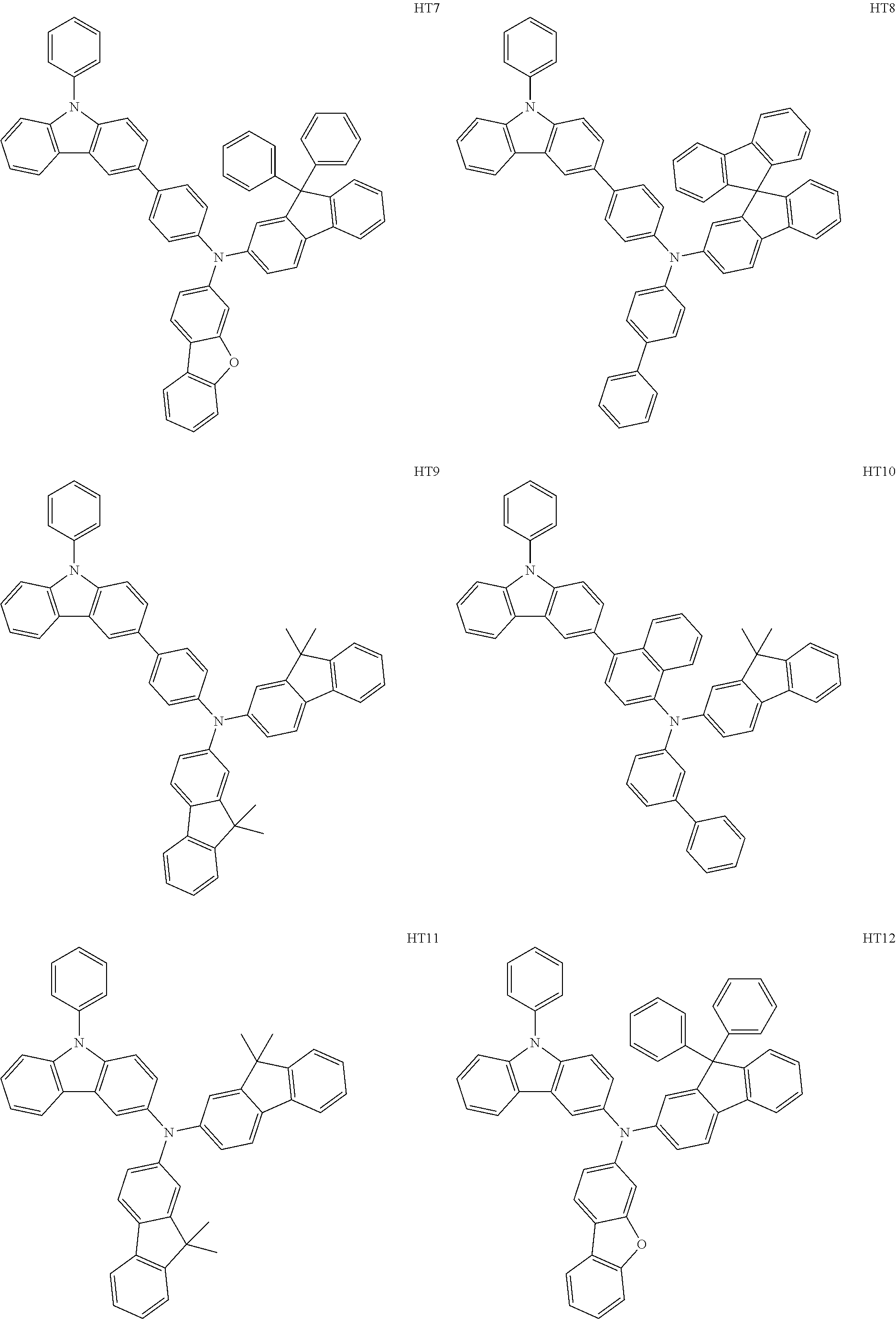

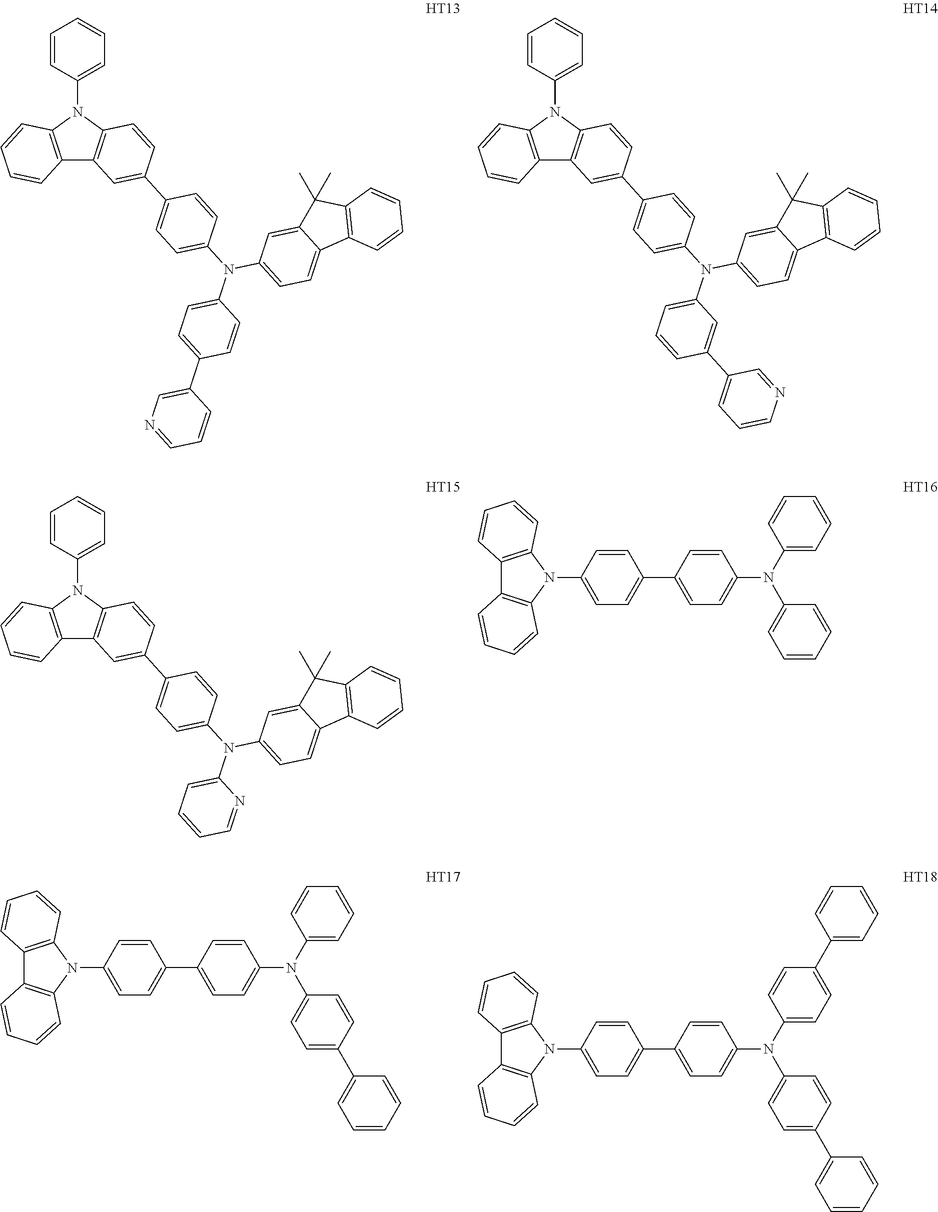 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

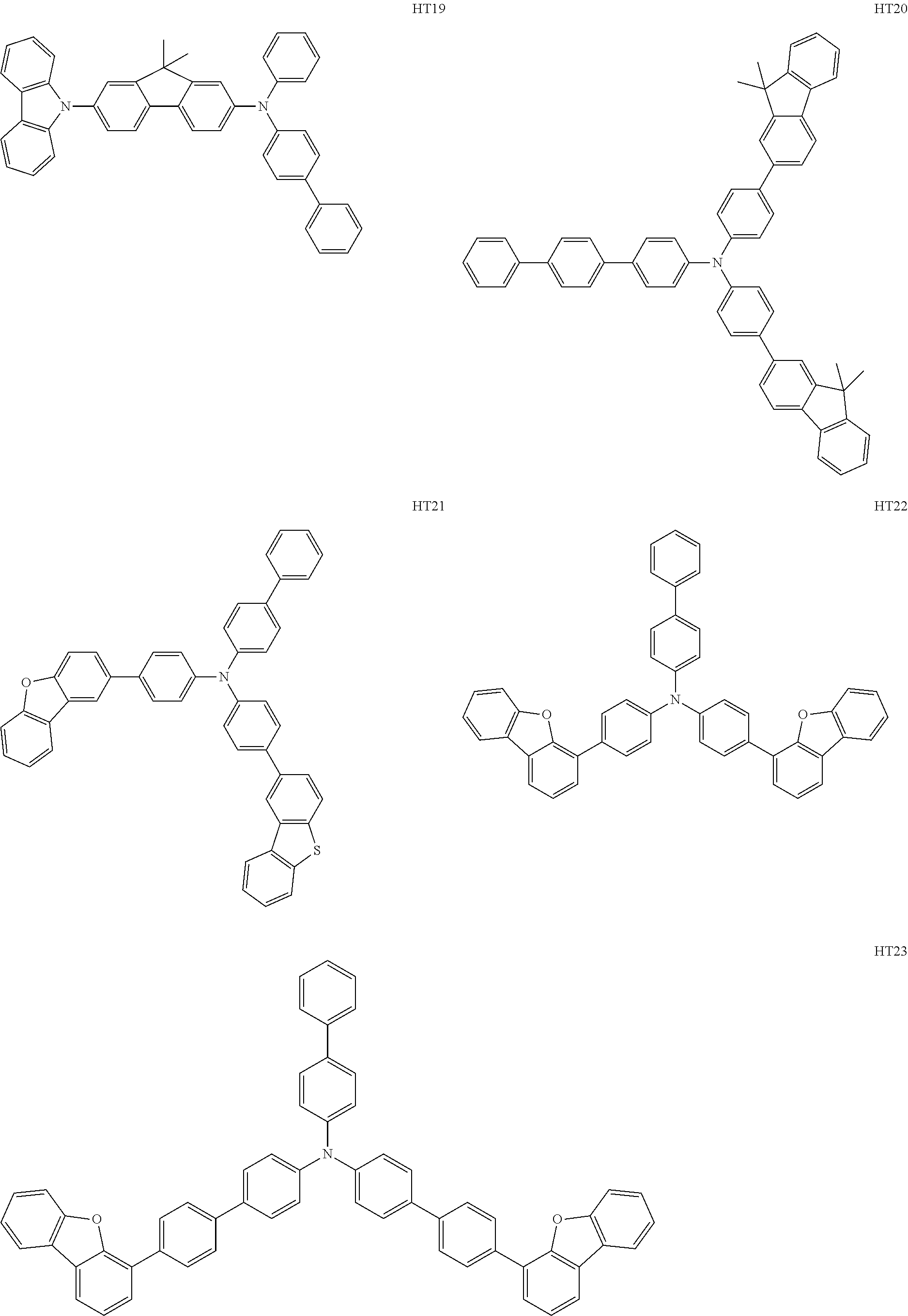 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

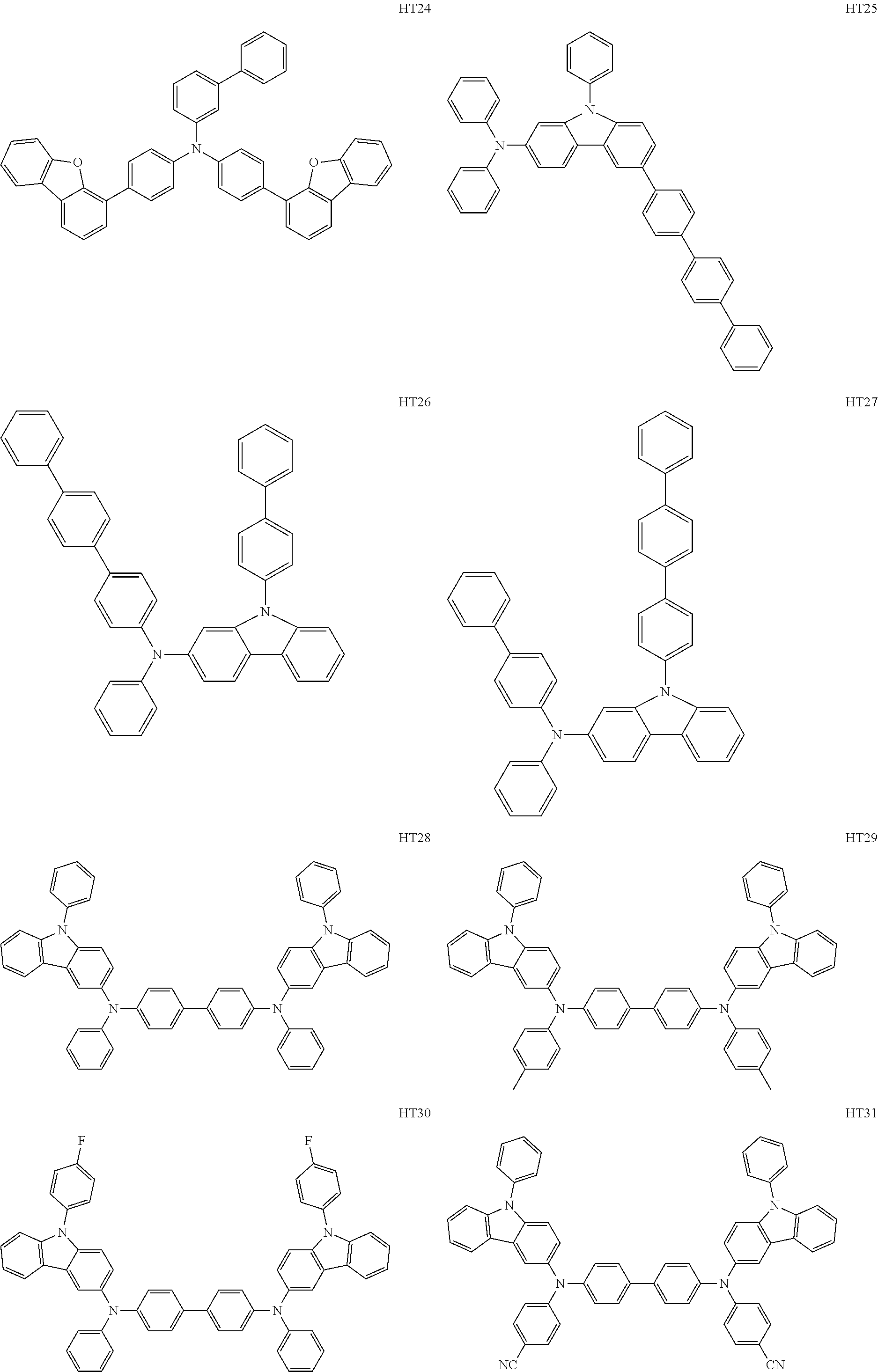

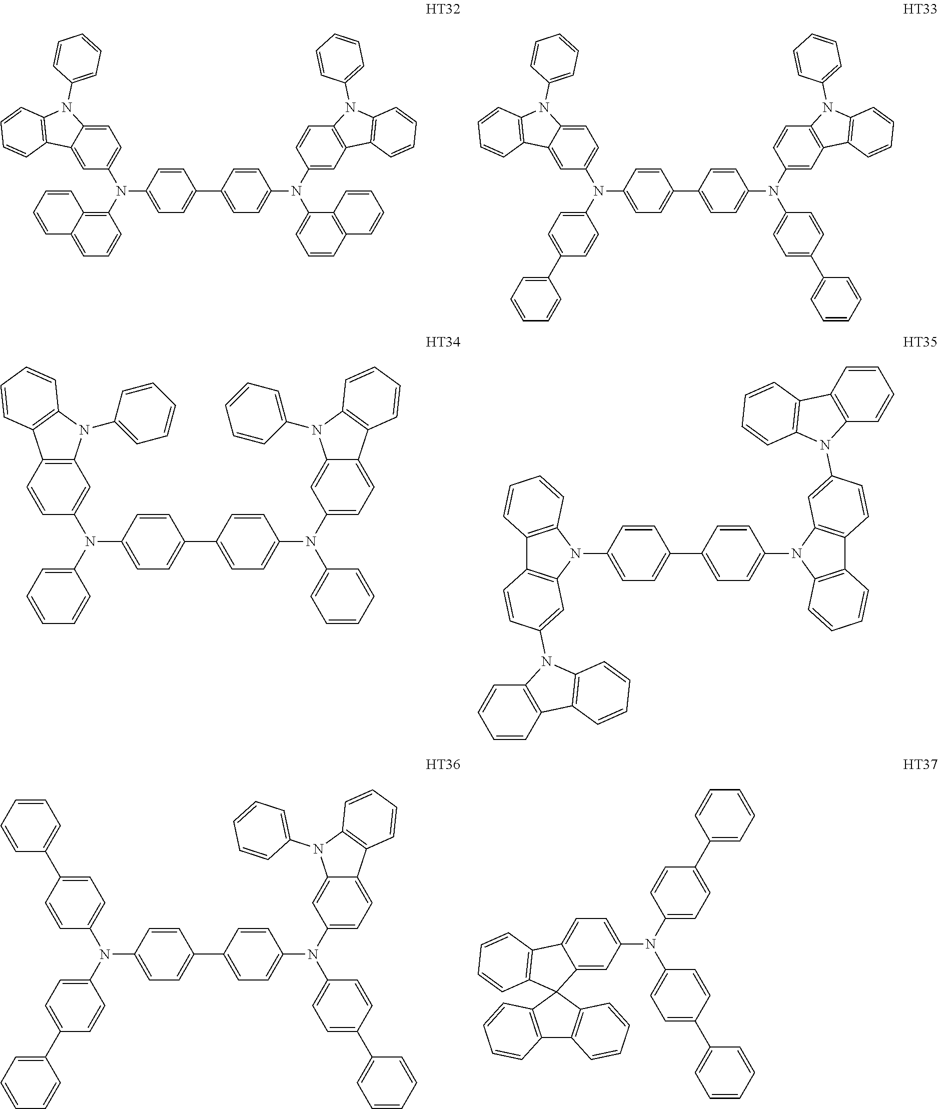

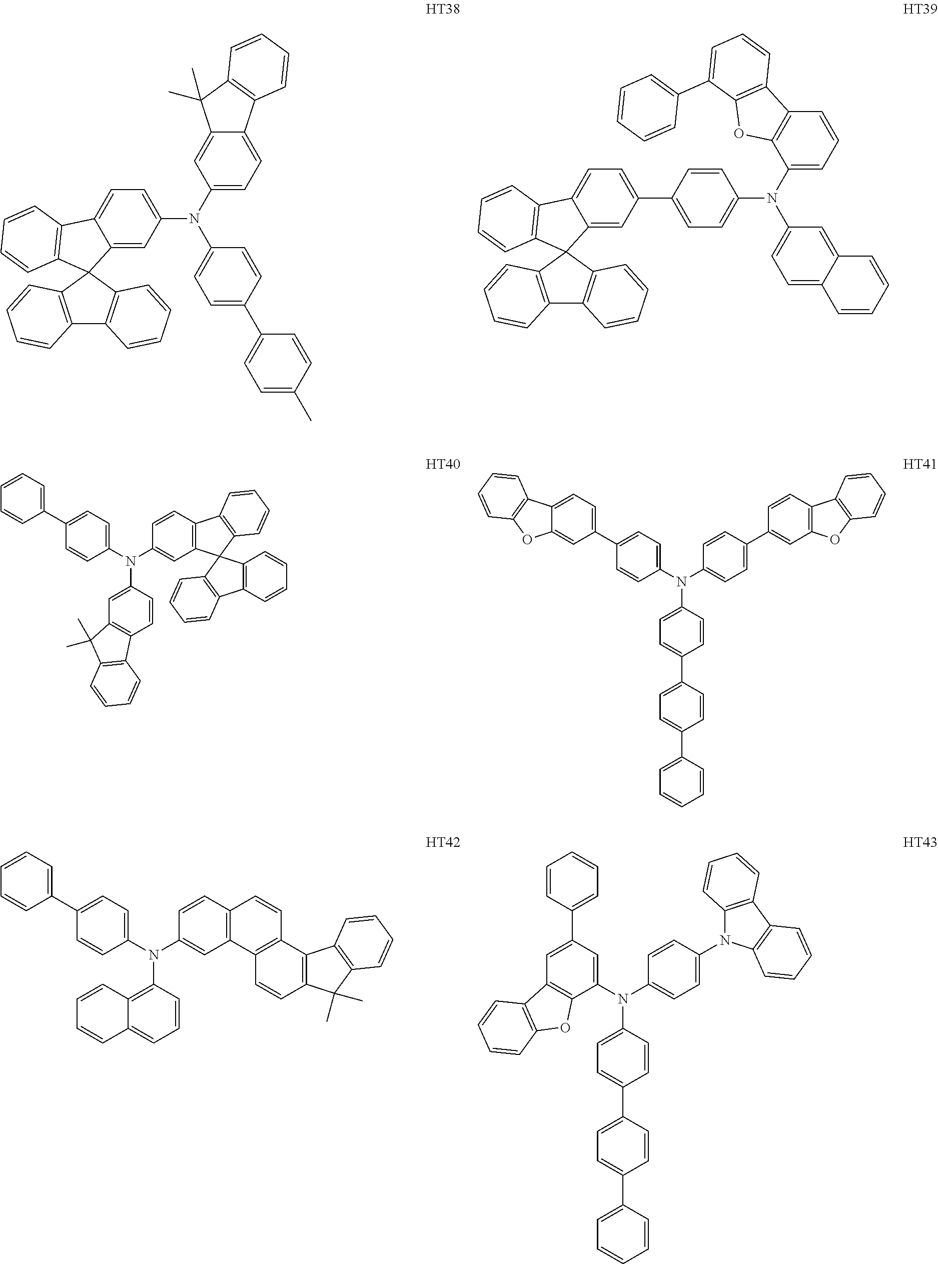

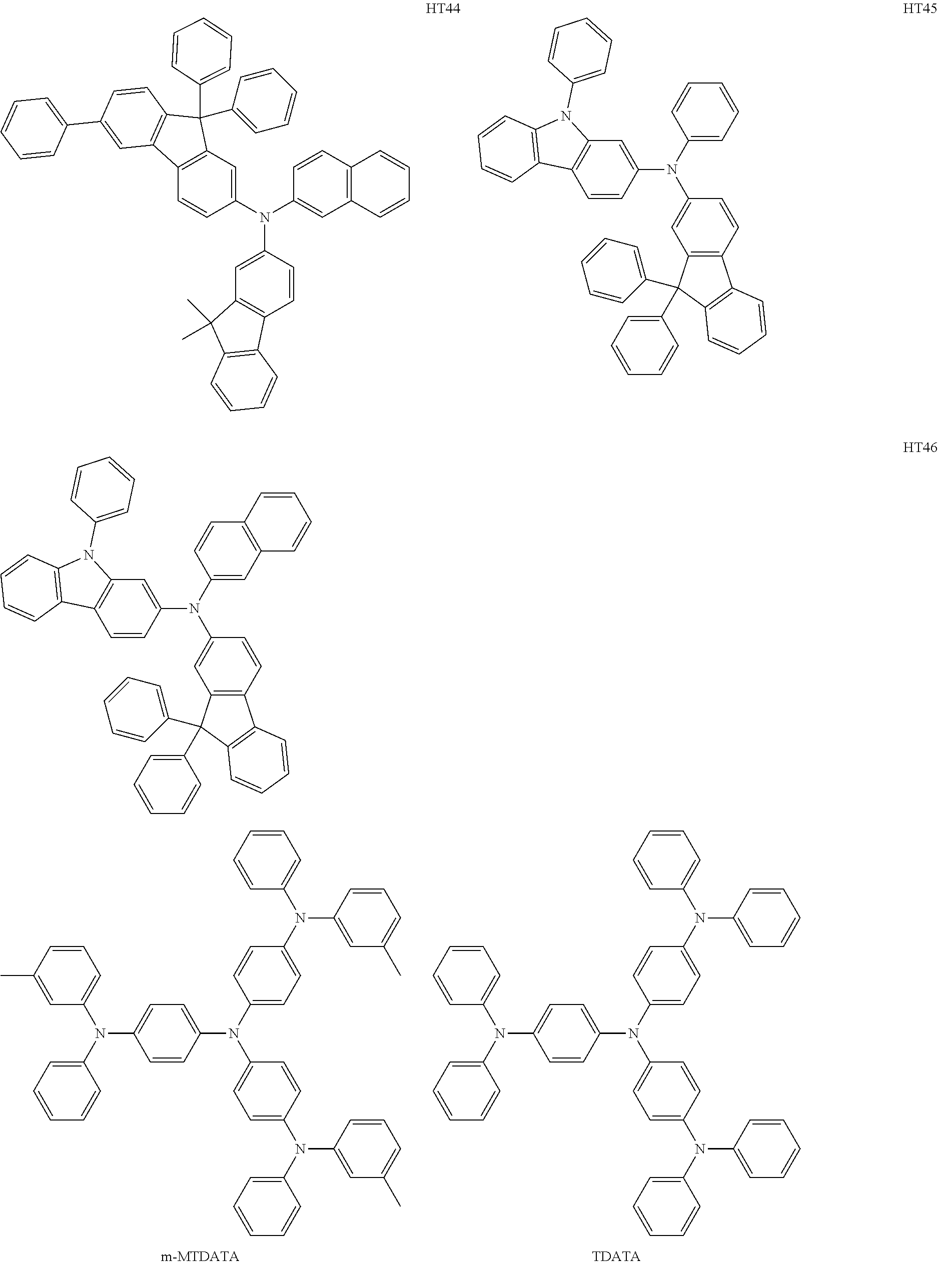

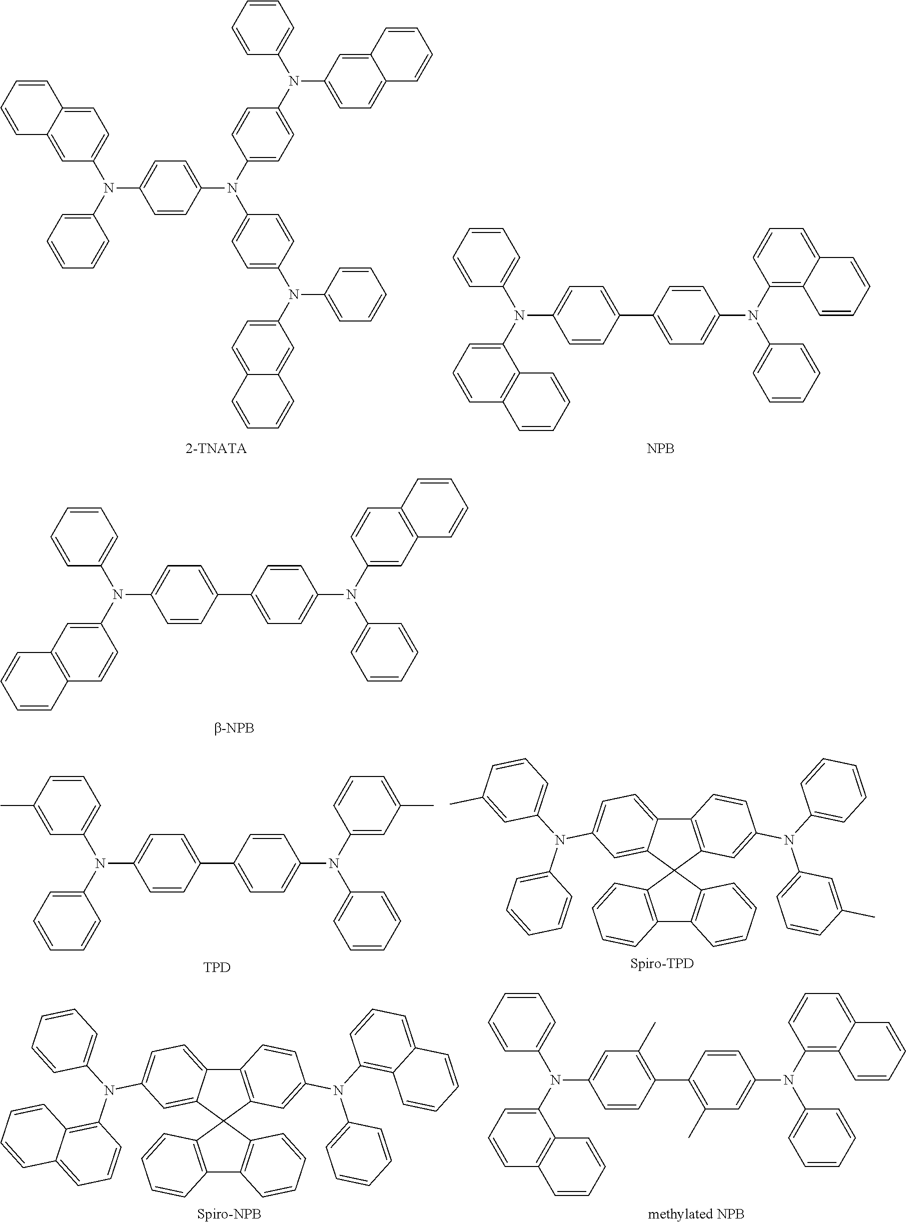

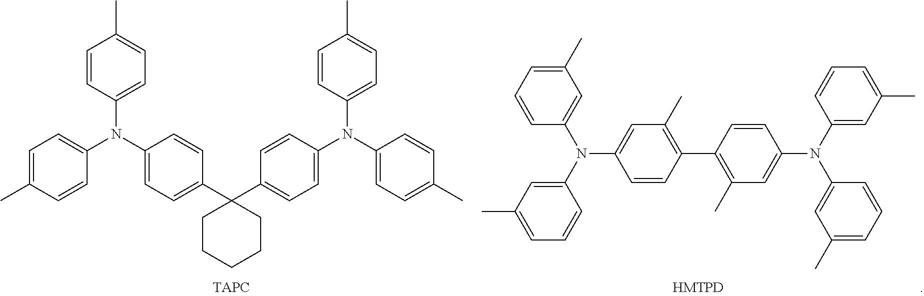

A thickness of the hole transport region 120 may be in a range of about 50 Å to about 10,000 Å, for example, about 100 Å to about 4,000 Å. When the hole transport region 120 includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region 120, the hole injection layer, and the hole transport layer are within the ranges described, satisfactory hole transporting characteristics may be obtained without a substantial increase in driving voltage.

The emission auxiliary layer may increase light-emission efficiency by compensating for an optical resonance distance according to the wavelength of light emitted by the emission layer, and the electron blocking layer may block or reduce the leakage of electrons from the emission layer to the hole transport region. The materials that may be included in the hole transport region 120 may be included in the emission auxiliary layer and the electron blocking layer.

p-Dopant

The hole transport region 120 may further include, in addition to the aforementioned materials, a charge-generation material for the improvement of conductive properties. The charge-generation material may be uniformly or non-uniformly dispersed in the hole transport region 120 (e.g., in the form of a single layer consisting of a charge-generation material).

The charge-generation material may be, for example, a p-dopant.

For example, a LUMO energy level of the p-dopant may be −3.5 eV or less.

In one or more embodiments, the p-dopant may include a quinone derivative, a cyano group-containing compound, a compound including element EL1 and element EL2, or any combination thereof.

Examples of the quinone derivative are TCNQ, F4-TCNQ, and/or the like.

Examples of the cyano group-containing compound are HAT-CN, a compound represented by Formula 221, and/or the like:

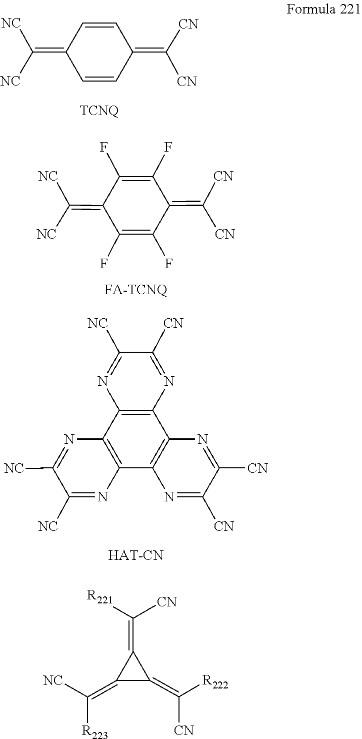

wherein, in Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be metal, metalloid, or any combination thereof, and element EL2 may be non-metal, metalloid, or any combination thereof.

Examples of the metal are: alkali metal (e.g., lithium (Li), sodium (Na), potassium (K), rubidium (Rb), cesium (Cs), and/or the like); alkaline earth metal (e.g., beryllium (Be), magnesium (Mg), calcium (Ca), strontium (Sr), barium (Ba), and/or the like); transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); post-transition metal (e.g., zinc (Zn), indium (In), tin (Sn), and/or the like); lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like); and/or the like.

Examples of the metalloid are silicon (Si), antimony (Sb), tellurium (Te), and/or the like.

Examples of the non-metal are oxygen (O), halogen (e.g., F, Cl, Br, I, and/or the like), and/or the like.

For example, the compound including element EL1 and element EL2 may include metal oxide, metal halide (e.g., metal fluoride, metal chloride, metal bromide, metal iodide, and/or the like), metalloid halide (e.g., metalloid fluoride, metalloid chloride, metalloid bromide, metalloid iodide, and/or the like), metal telluride, or any combination thereof.

Examples of the metal oxide are tungsten oxide (e.g., WO, W₂O₃, WO₂, WO₃, W₂O₅, and/or the like), vanadium oxide (e.g., VO, V₂O₃, VO₂, V₂O₅, and/or the like), molybdenum oxide (e.g., MoO, Mo₂O₃, MoO₂, MoO₃, Mo₂O₅, and/or the like), rhenium oxide (e.g., ReO₃, and/or the like), and/or the like.

Examples of the metal halide are alkali metal halide, alkaline earth metal halide, transition metal halide, post-transition metal halide, lanthanide metal halide, and/or the like.

Examples of the alkali metal halide are LiF, NaF, KF, RbF, CsF, LiCl, NaCl, KCl, RbCl, CsCl, LiBr, NaBr, KBr, RbBr, CsBr, LiI, NaI, KI, RbI, CsI, and/or the like.

Examples of the alkaline earth metal halide are BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, BaI₂, and/or the like.

Examples of the transition metal halide are titanium halide (e.g., TiF₄, TiCl₄, TiBr₄, TiI₄, and/or the like), zirconium halide (e.g., ZrF₄, ZrCl₄, ZrBr₄, ZrI₄, and/or the like), hafnium halide (e.g., HfF₄, HfC₁₄, HfBr₄, HfI₄, and/or the like), vanadium halide (e.g., VF₃, VCl₃, VBr₃, VI₃, and/or the like), niobium halide (e.g., NbF₃, NbCl₃, NbBr₃, NbI₃, and/or the like), tantalum halide (e.g., TaF₃, TaCl₃, TaBr₃, TaI₃, and/or the like), chromium halide (e.g., CrF₃, CrO₃, CrBr₃, CrI₃, and/or the like), molybdenum halide (e.g., MoF₃, MoCl₃, MoBr₃, MoI₃, and/or the like), tungsten halide (e.g., WF₃, WCl₃, WBr3, WI3, and/or the like), manganese halide (e.g., MnF2, MnCl2, MnBr2, MnI2, and/or the like), technetium halide (e.g., TcF₂, TcCl₂, TcBr₂, TcI₂, and/or the like), rhenium halide (e.g., ReF₂, ReCl₂, ReBr₂, ReI₂, and/or the like), iron halide (e.g., FeF₂, FeCl₂, FeBr₂, FeI₂, and/or the like), ruthenium halide (e.g., RuF₂, RuCl₂, RuBr₂, RuI₂, and/or the like), osmium halide (e.g., OsF₂, OsCl₂, OsBr₂, OsI₂, and/or the like), cobalt halide (e.g., CoF₂, COCl₂, CoBr₂, CoI₂, and/or the like), rhodium halide (e.g., RhF₂, RhCl₂, RhBr₂, RhI₂, and/or the like), iridium halide (e.g., IrF₂, IrCl₂, IrBr₂, IrI₂, and/or the like), nickel halide (e.g., NiF₂, NiCl₂, NiBr₂, NiI₂, and/or the like), palladium halide (e.g., PdF₂, PdCl₂, PdBr₂, PdI₂, and/or the like), platinum halide (e.g., PtF₂, PtCl₂, PtBr₂, PtI₂, and/or the like), copper halide (e.g., CuF, CuCl, CuBr, CuI, and/or the like), silver halide (e.g., AgF, AgCl, AgBr, AgI, and/or the like), gold halide (e.g., AuF, AuCl, AuBr, AuI, and/or the like), and/or the like.

Examples of the post-transition metal halide are zinc halide (e.g., ZnF₂, ZnCl₂, ZnBr₂, ZnI₂, and/or the like), indium halide (e.g., InI₃, and/or the like), tin halide (e.g., SnI₂, and/or the like), and/or the like.

Examples of the lanthanide metal halide are YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, and/or the like.

Examples of the metalloid halide are antimony halide (e.g., SbCl₅, and/or the like) and/or the like.

Examples of the metal telluride are alkali metal telluride (e.g., Li₂Te, Na₂Te, K₂Te, Rb₂Te, Cs₂Te, and/or the like), alkaline earth metal telluride (e.g., BeTe, MgTe, CaTe, SrTe, BaTe, and/or the like), transition metal telluride (e.g., TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, and/or the like), post-transition metal telluride (e.g., ZnTe, and/or the like), lanthanide metal telluride (e.g., LaTe, CeTe, PrTe, NdTe, PmTe, EuTe, GdTe, TbTe, DyTe, HoTe, ErTe, TmTe, YbTe, LuTe, and/or the like), and/or the like.

### Emission Layer 130

The light-emitting device 10 may include an emission layer 130 on the hole transport region 120.

The emission layer 130 may further include, in addition to one or more suitable organic materials, a metal-containing compound such as an organometallic compound, an inorganic material such as a quantum dot, and/or the like.

The emission layer 130 may include i) two or more emitting units sequentially stacked between the first electrode 110 and the second electrode 150, and ii) a charge generation layer between the two or more emitting units. When the emission layer 130 includes the two or more emitting units and the charge generation layer, the light-emitting device 10 may be a tandem light-emitting device.

When the light-emitting device 10 is a full-color light-emitting device, the emission layer 130 may be patterned into a red emission layer, a green emission layer, and/or a blue emission layer, according to a sub-pixel. In one or more embodiments, the emission layer 130 may have a stacked structure of two or more layers of a red emission layer, a green emission layer, and a blue emission layer, in which the two or more layers contact each other or are separated from each other, to emit white light. In one or more embodiments, the emission layer 130 may include two or more materials of a red light-emitting material, a green light-emitting material, and a blue light-emitting material, in which the two or more materials are mixed with each other in a single layer, to emit white light.

The emission layer 130 may include a host and a dopant. The dopant may include a phosphorescent dopant, a fluorescent dopant, or any combination thereof.

An amount of the dopant in the emission layer 130 may be in a range of about 0.01 parts by weight to about 15 parts by weight based on 100 parts by weight of the host.

In one or more embodiments, the emission layer 130 may include a quantum dot.

In one or more embodiments, the emission layer 130 may include a delayed fluorescence material. The delayed fluorescence material may act as a host or a dopant in the emission layer 130.

A thickness of the emission layer 130 may be in a range of about 100 Å to about 1,000 Å, for example, about 200 Å to about 600 Å. When the thickness of the emission layer 130 is within the ranges described, excellent or suitable luminescence characteristics may be obtained without a substantial increase in driving voltage.

### Host

The host may include a compound represented by Formula 301:

[Ar₃₀₁]_{xb11}-[(L₃₀₁)_{xb1}-R₃₀₁]_{xb21} Formula 301
wherein, in Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to 0303 may each be as described in connection with Q₁.

For example, when xb11 in Formula 301 is 2 or more, two or more of Ar₃₀₁ may be linked to each other via a single bond.

In one or more embodiments, the host may include a compound represented by Formula 301-1, a compound represented by Formula 301-2, or any combination thereof:

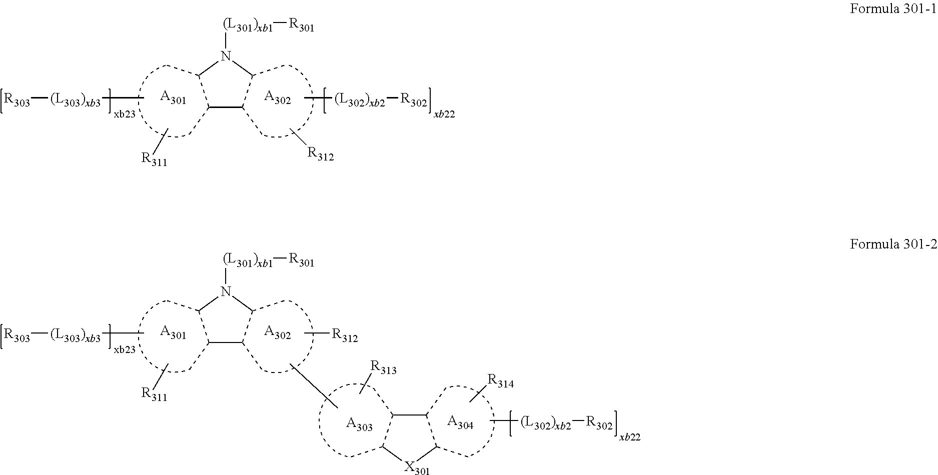

wherein, in Formula 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each be as described herein,
L₃₀₂ to L₃₀₄ may each independently be as described in connection with L₃₀₁,
xb2 to xb4 may each independently be as described in connection with xb1, and
R₃₀₂ to R₃₀₅ and R₃₁₁ to R₃₁₄ may each be as described in connection with R₃₀₁.

In one or more embodiments, the host may include an alkali earth metal complex, a post-transition metal complex, or any combination thereof. In one or more embodiments, the host may include a Be complex (e.g., Compound H55), a Mg complex, a Zn complex, or any combination thereof.

In one or more embodiments, the host may include: at least one selected from among Compounds H1 to H128; 9,10-di(2-naphthyl)anthracene (ADN); 2-methyl-9,10-bis(naphthalen-2-yl)anthracene (MADN); 9,10-di-(2-naphthyl)-2-t-butyl-anthracene (TBADN); 4,4′-bis(N-carbazolyl)-1,1′-biphenyl (CBP); 1,3-di(carbazol-9-yl)benzene (mCP); 1,3,5-tri(carbazol-9-yl)benzene (TCP); and/or any combination thereof:

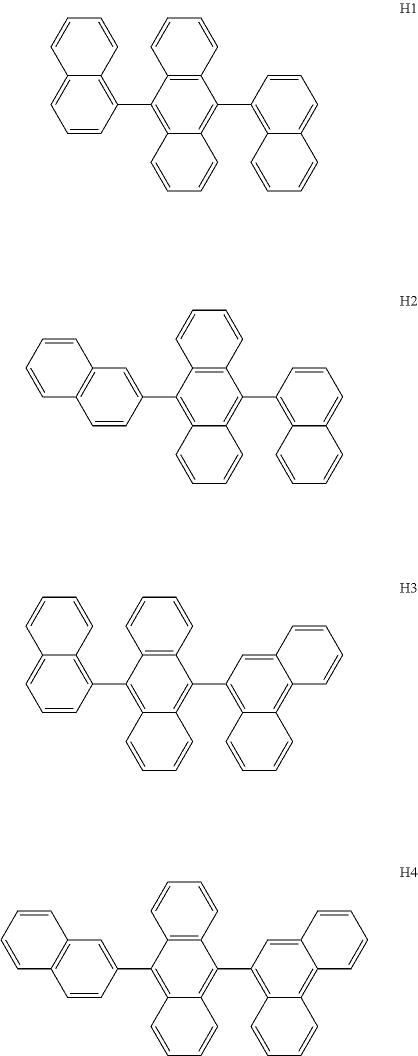

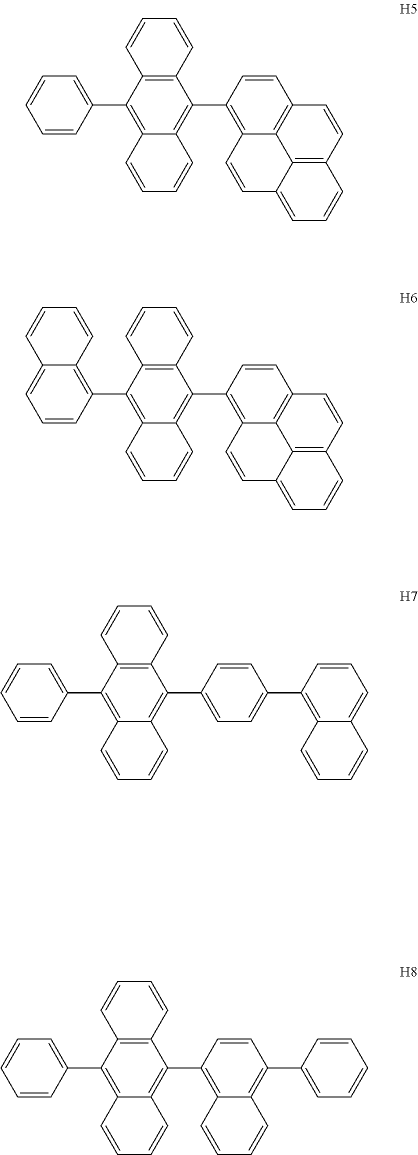

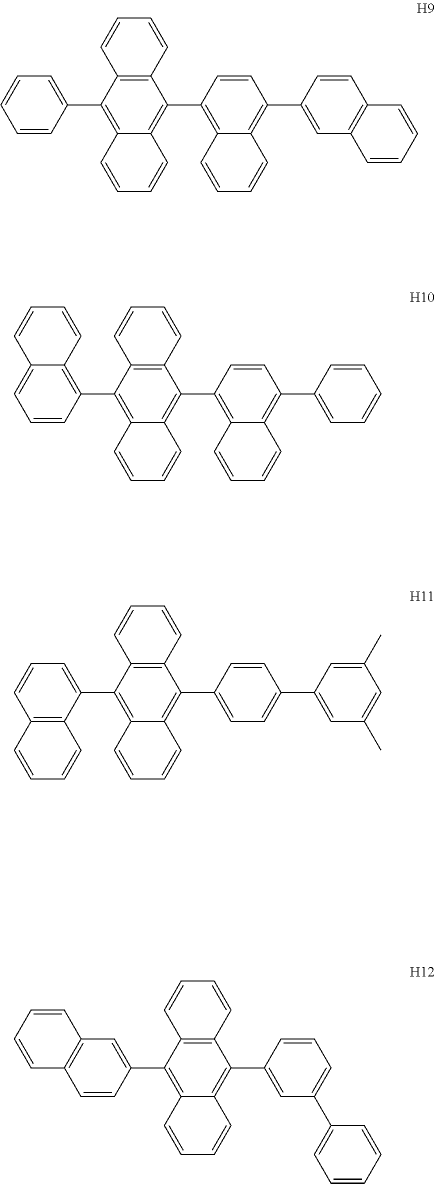

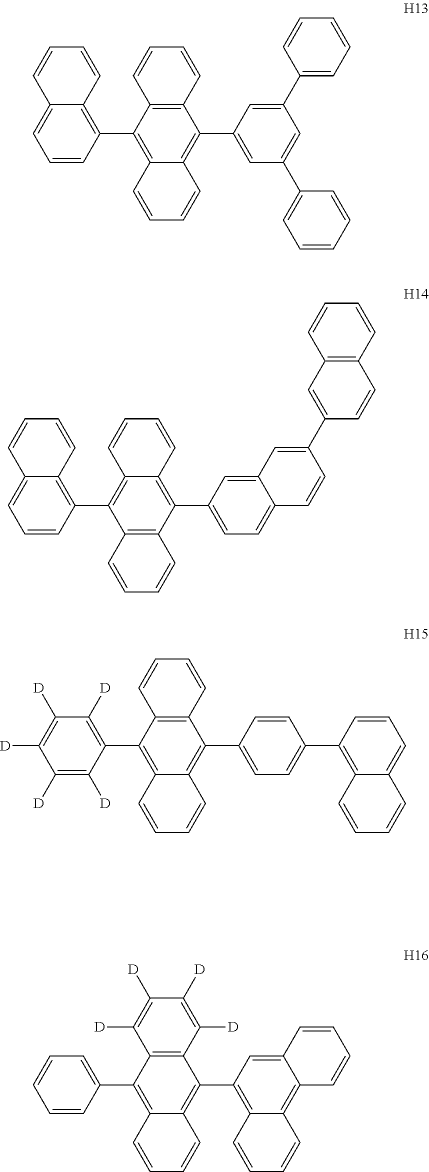

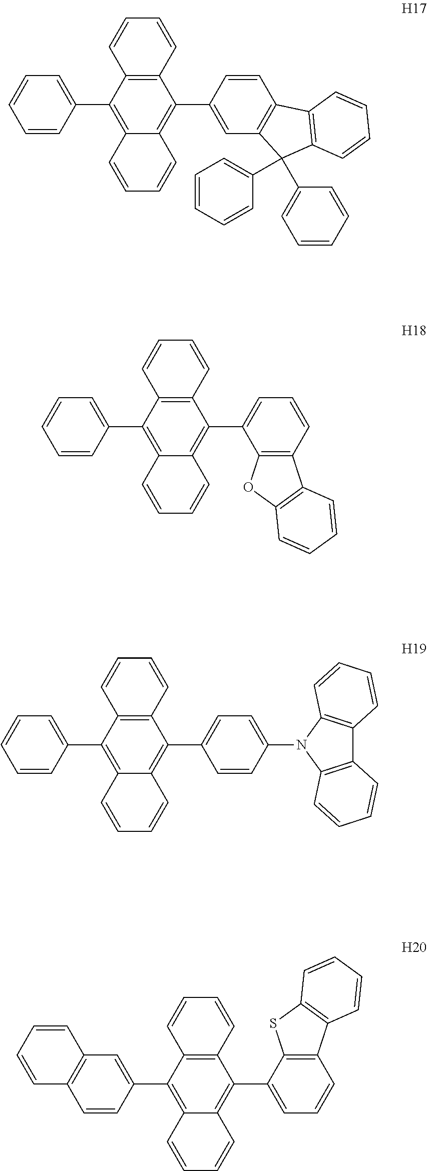

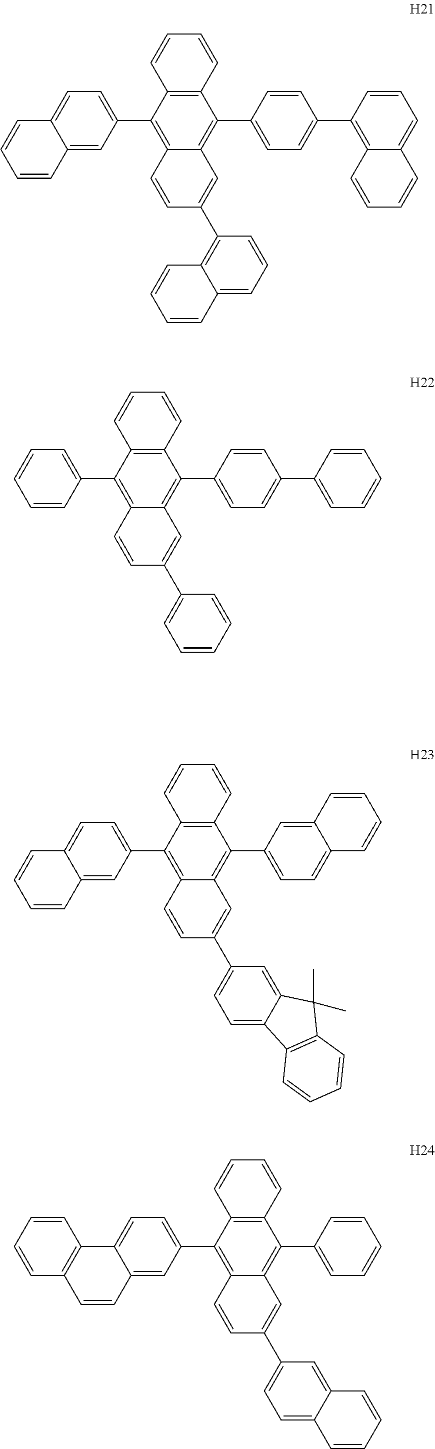

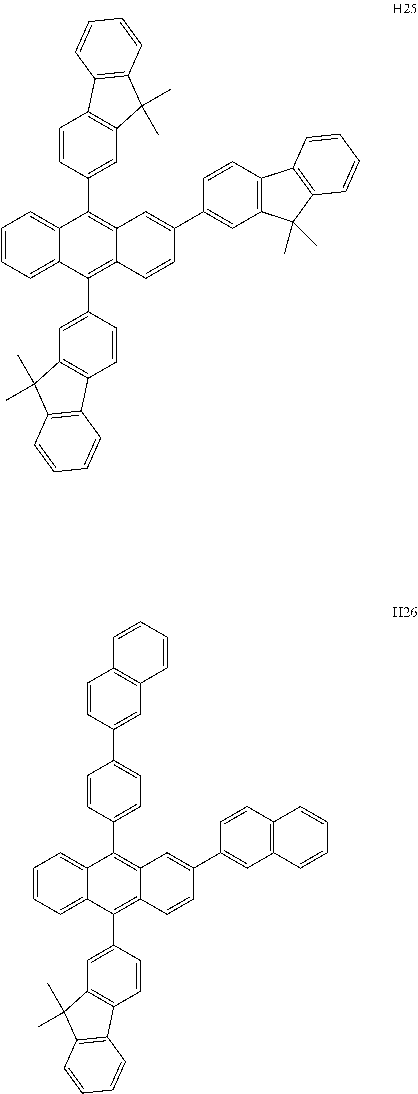

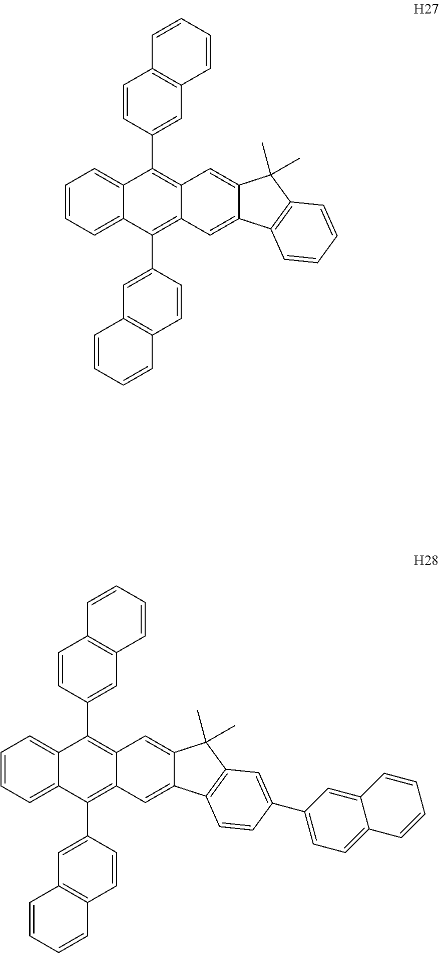

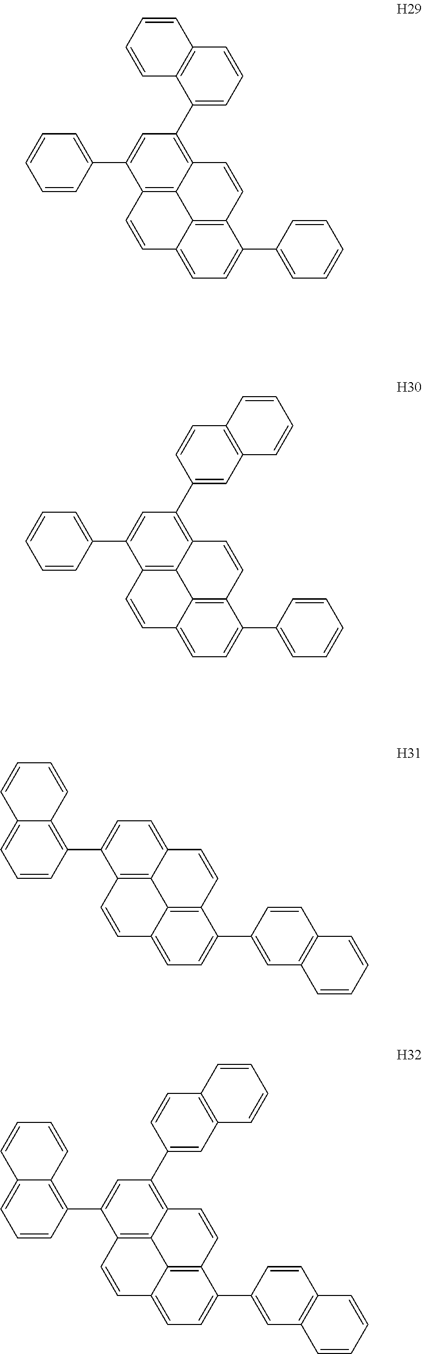

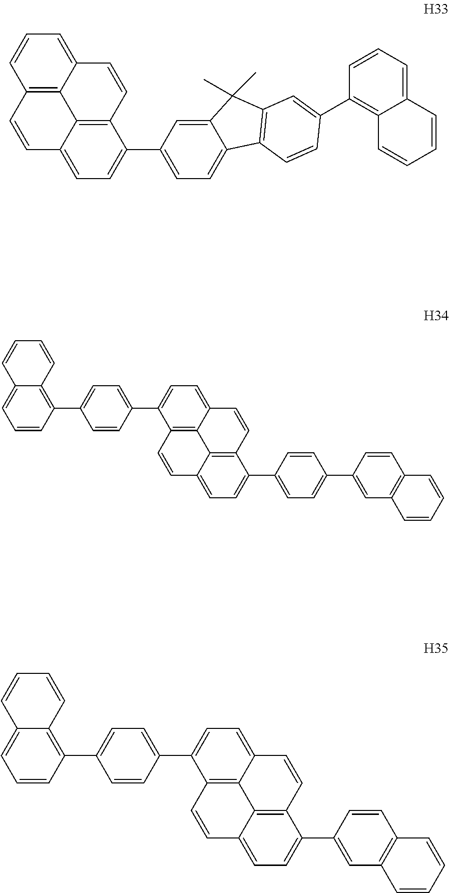

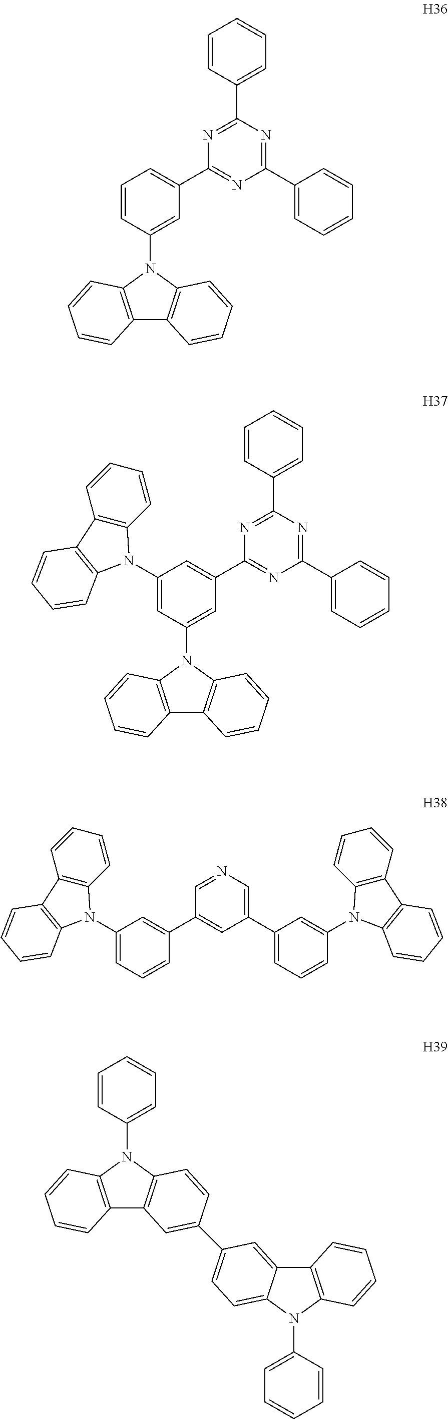 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1]

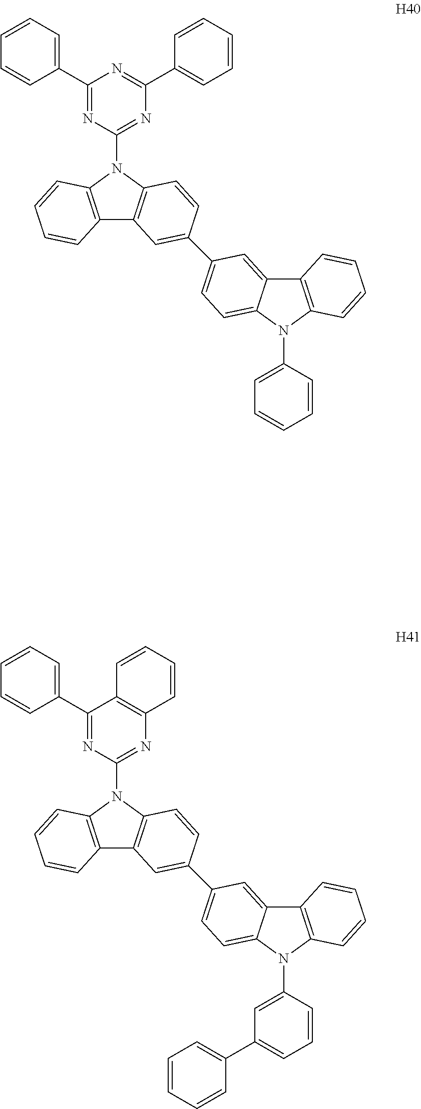 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1]

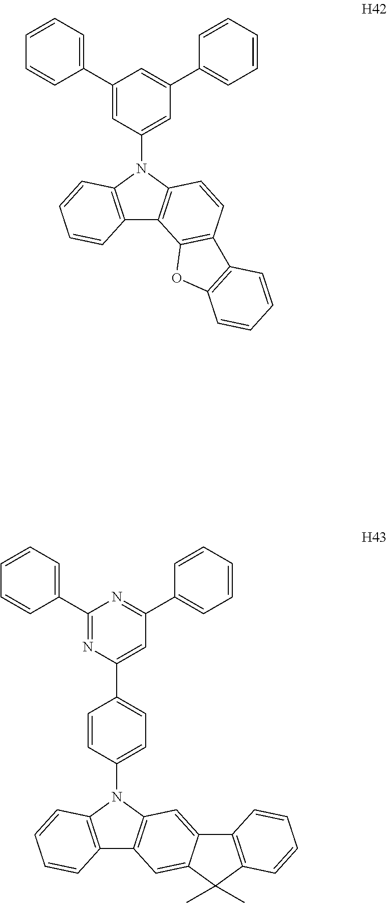 [SMILES: c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1ccc(-c2cc(-c3ccccc3)nc(-c3ccccc3)n2)cc1]

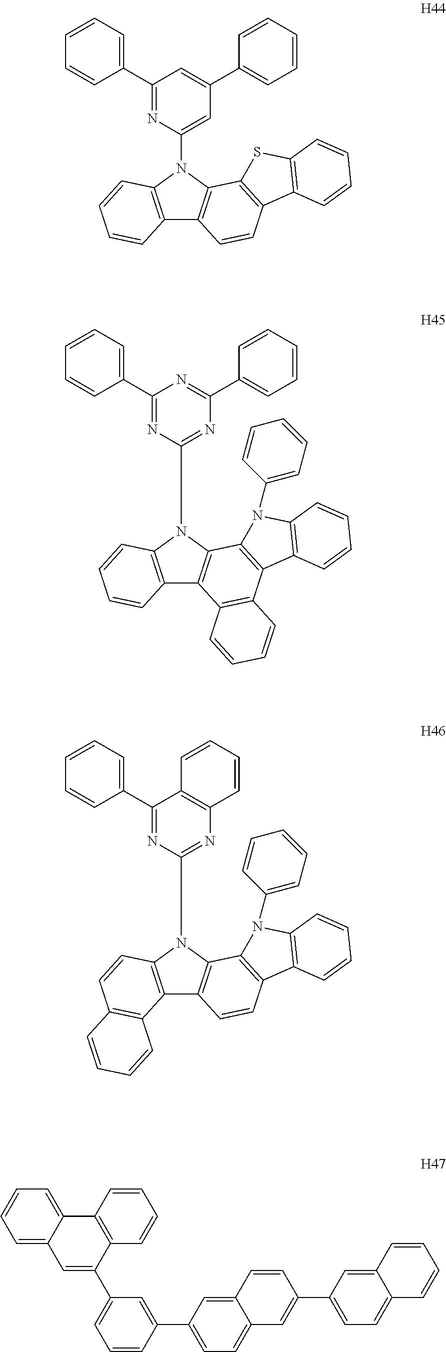

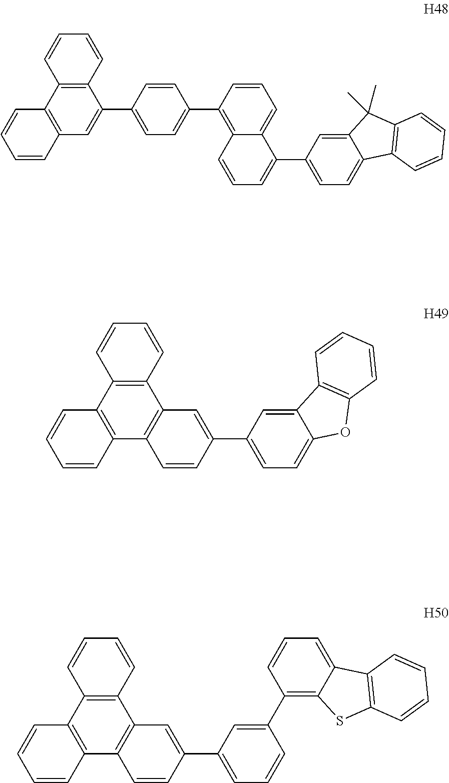

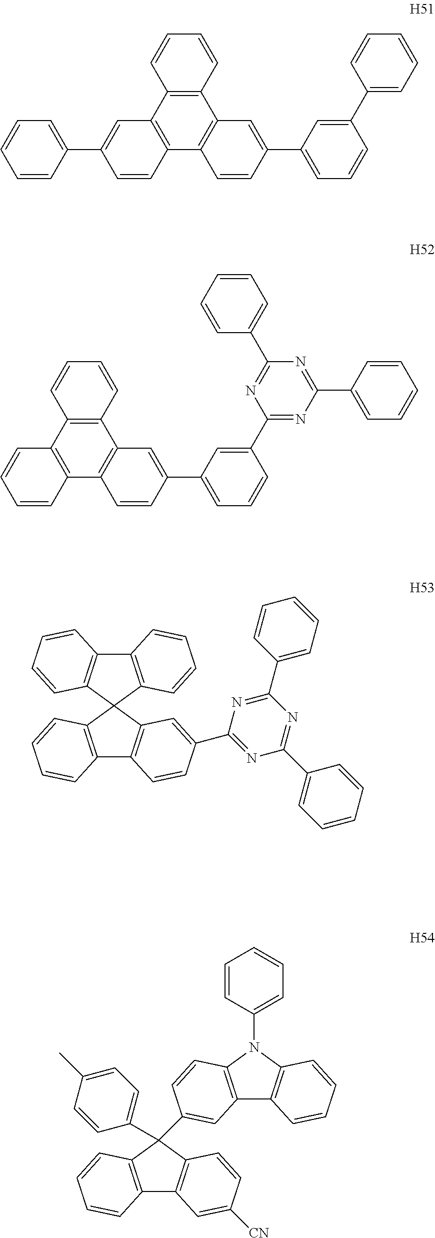

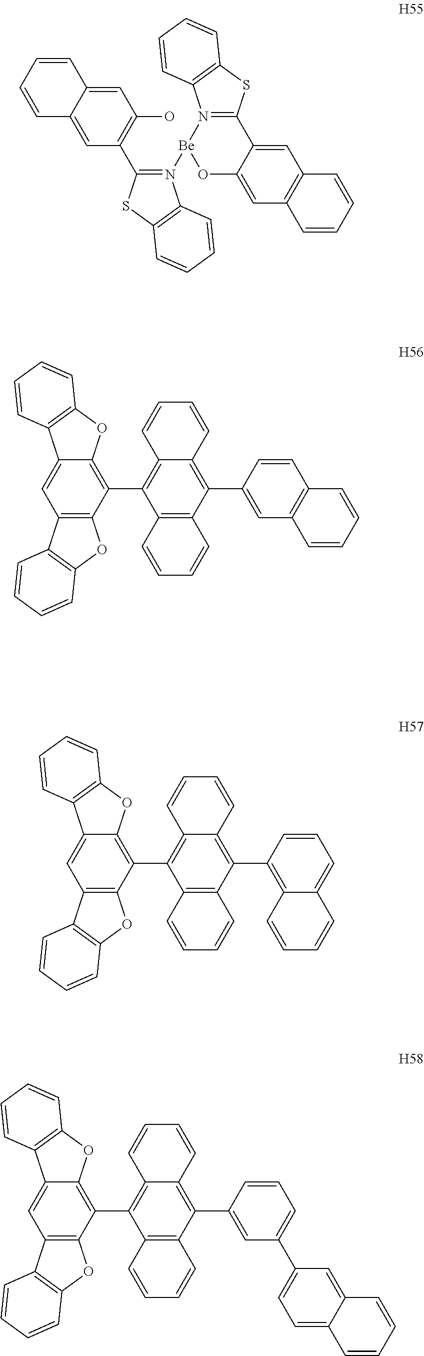

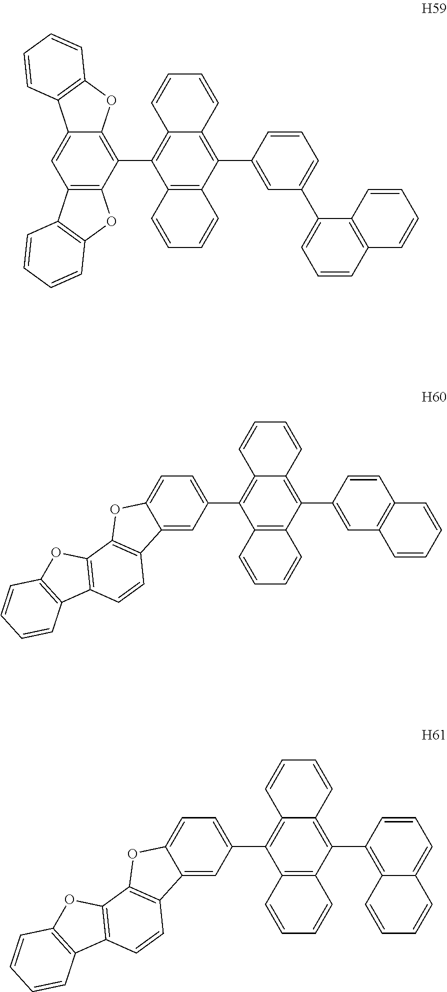 [SMILES: c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1]

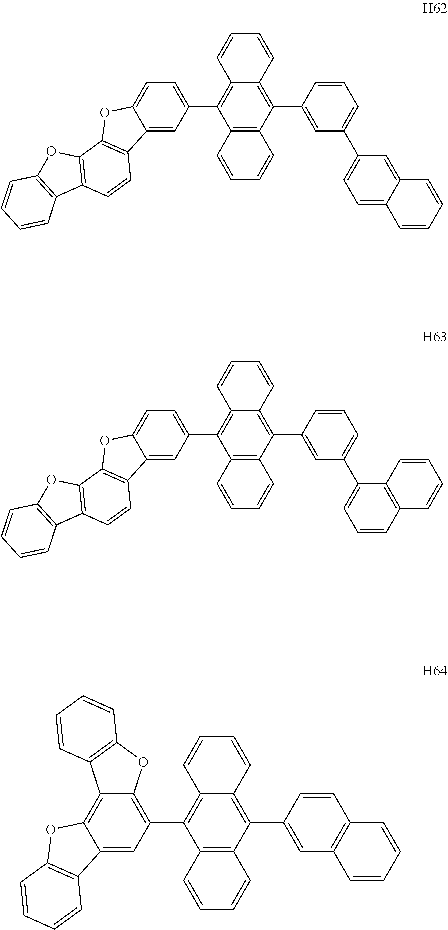 [SMILES: c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1]

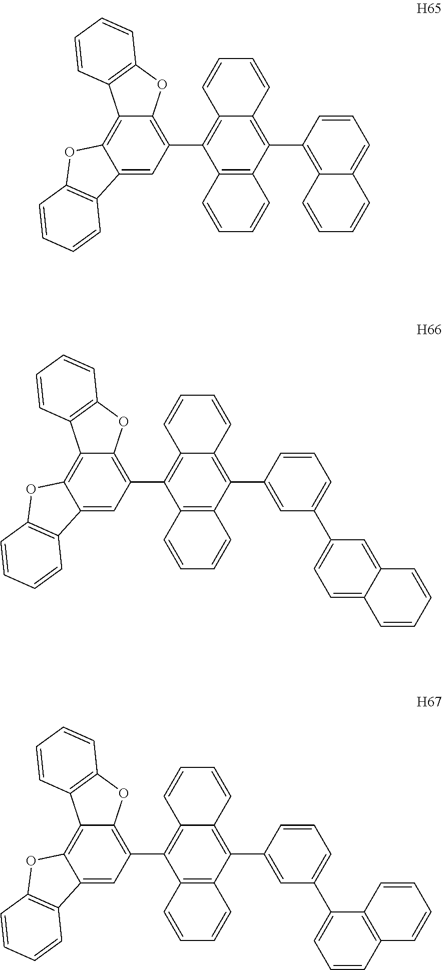 [SMILES: c1ccc2c(-c3c4ccccc4c(-c4cc5c6ccccc6oc5c5c4oc4ccccc45)c4ccccc34)cccc2c1 ; c1cc(-c2ccc3ccccc3c2)cc(-c2c3ccccc3c(-c3cc4c5ccccc5oc4c4c3oc3ccccc34)c3ccccc23)c1 ; c1cc(-c2cccc3ccccc23)cc(-c2c3ccccc3c(-c3cc4c5ccccc5oc4c4c3oc3ccccc34)c3ccccc23)c1]

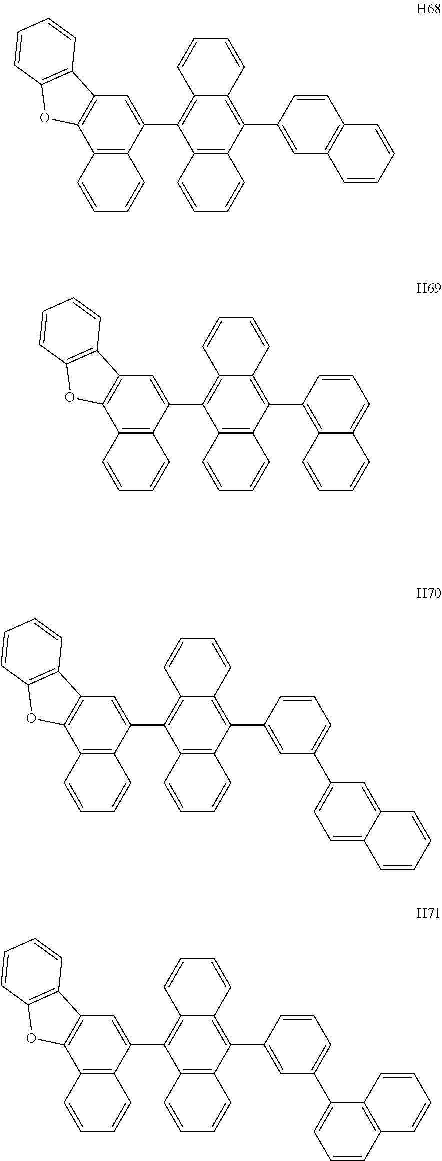 [SMILES: c1ccc2cc(-c3c4ccccc4c(-c4cc5c6ccccc6oc5c5ccccc45)c4ccccc34)ccc2c1 ; c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1]

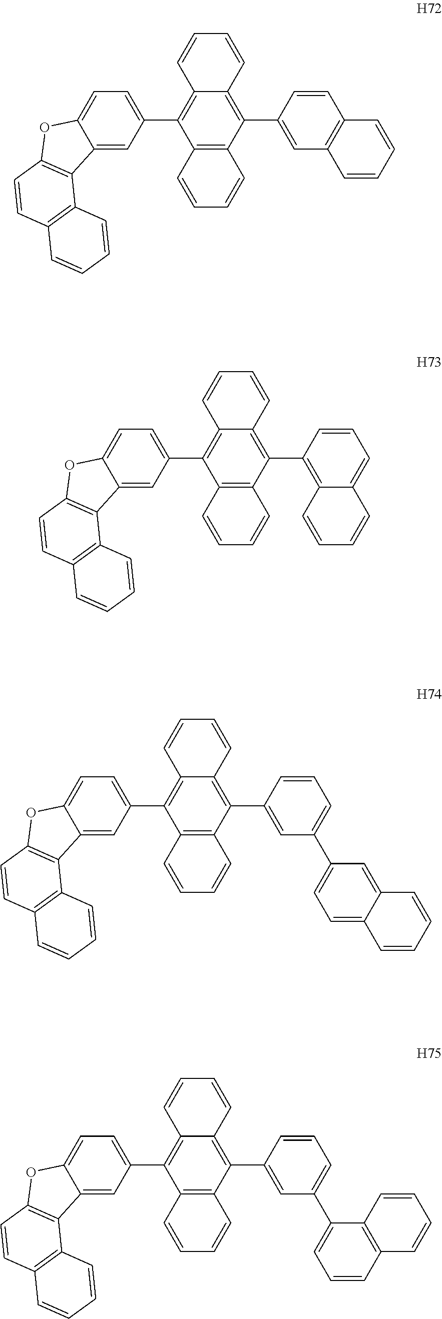 [SMILES: c1ccc2cc(-c3c4ccccc4c(-c4ccc5oc6ccc7ccccc7c6c5c4)c4ccccc34)ccc2c1 ; c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1]

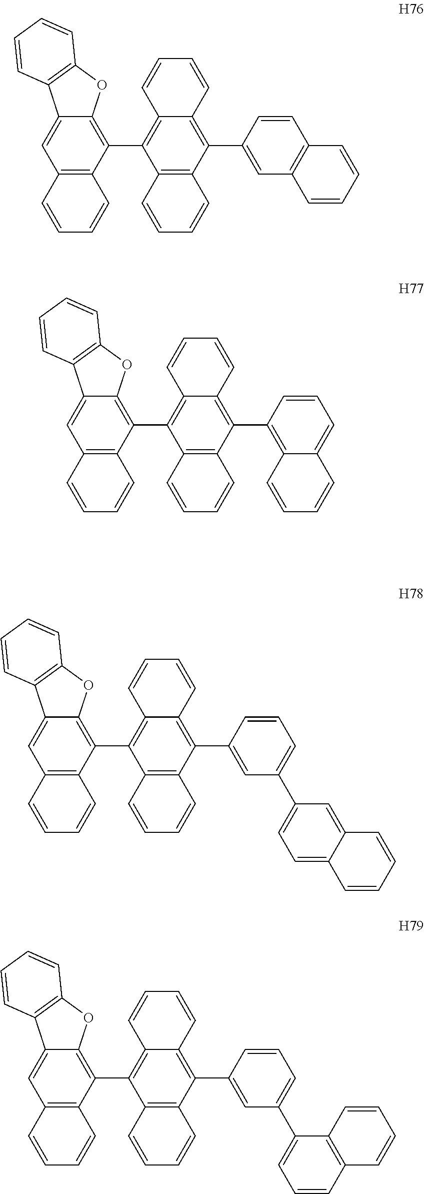 [SMILES: c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1]

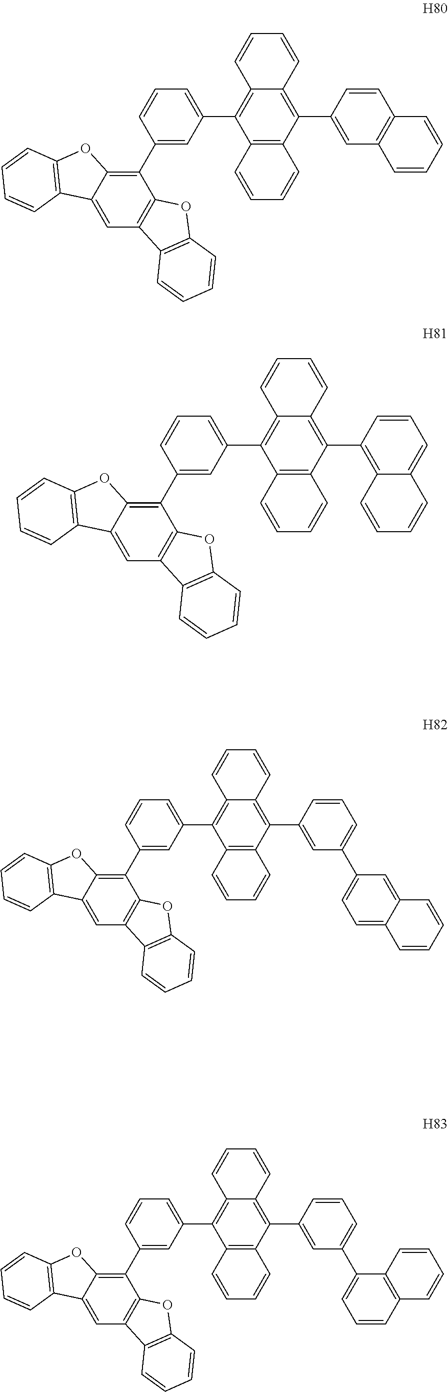 [SMILES: c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1]

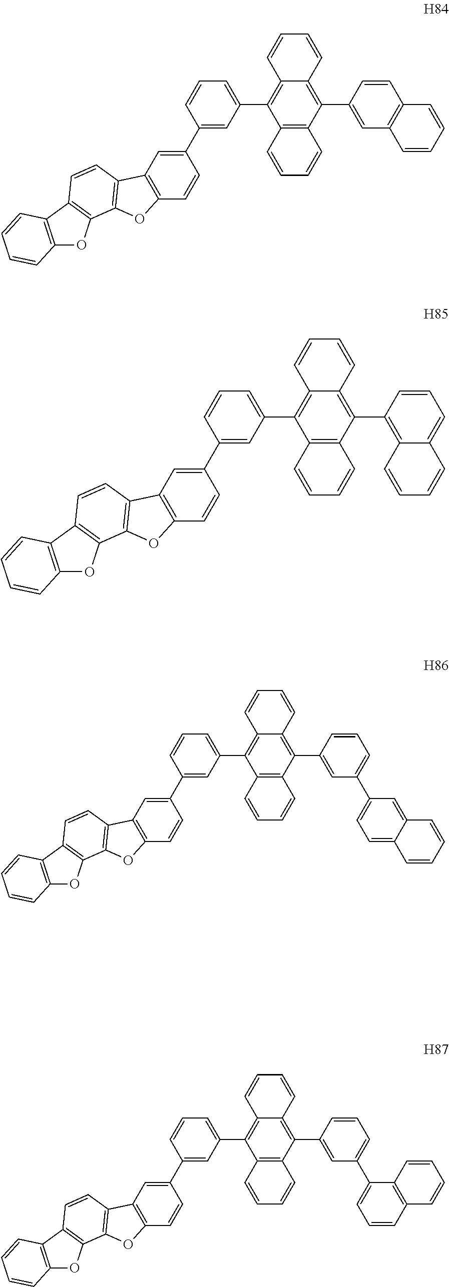 [SMILES: c1cc(-c2ccc3oc4c(ccc5c6ccccc6oc54)c3c2)cc(-c2c3ccccc3c(-c3ccc4ccccc4c3)c3ccccc23)c1 ; c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1]

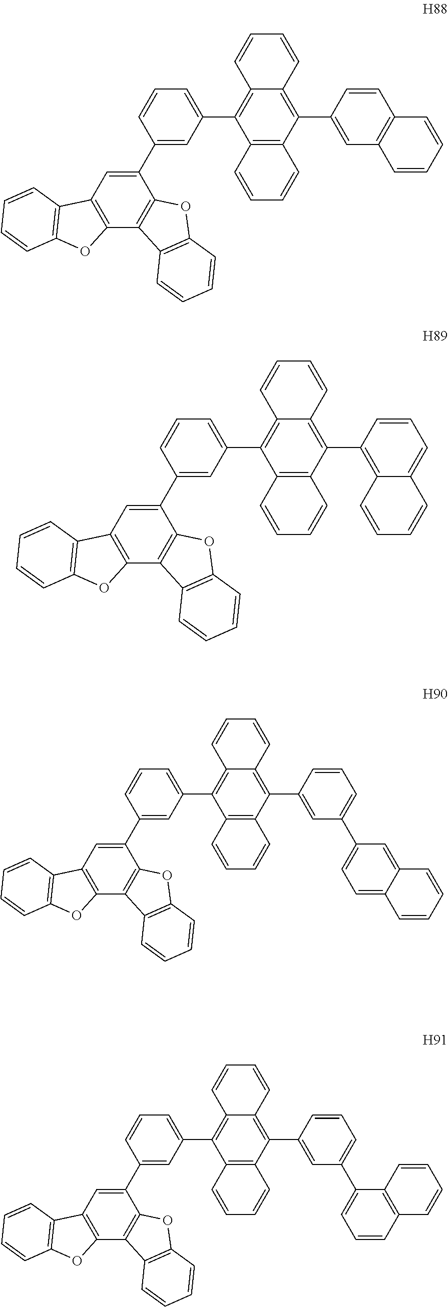 [SMILES: c1cc(-c2c3ccccc3c(-c3ccc4ccccc4c3)c3ccccc23)cc(-c2cc3c4ccccc4oc3c3c2oc2ccccc23)c1 ; c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1]

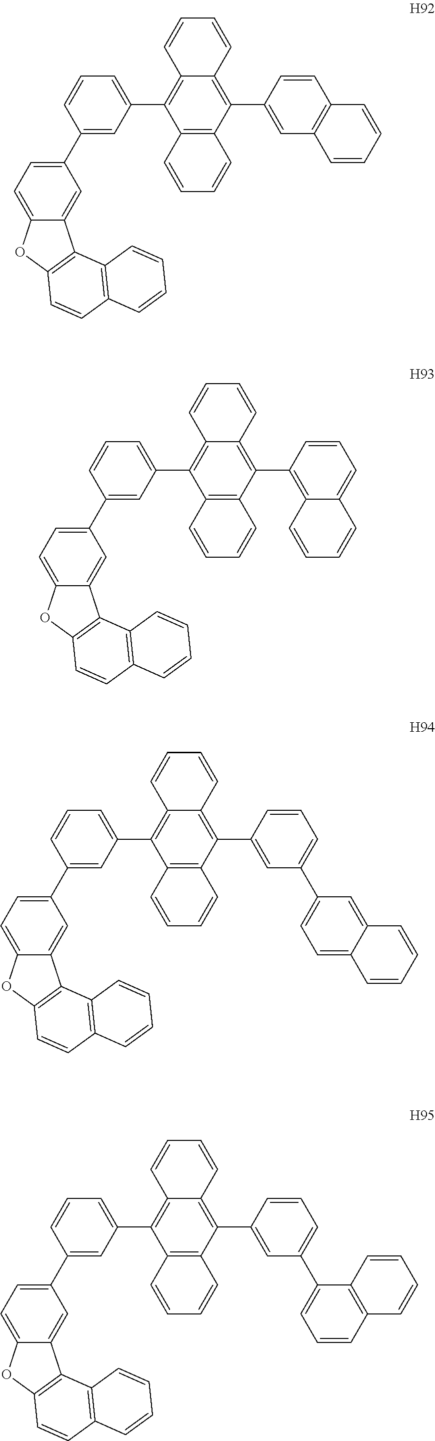 [SMILES: c1cc(-c2ccc3oc4ccc5ccccc5c4c3c2)cc(-c2c3ccccc3c(-c3ccc4ccccc4c3)c3ccccc23)c1 ; c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1]

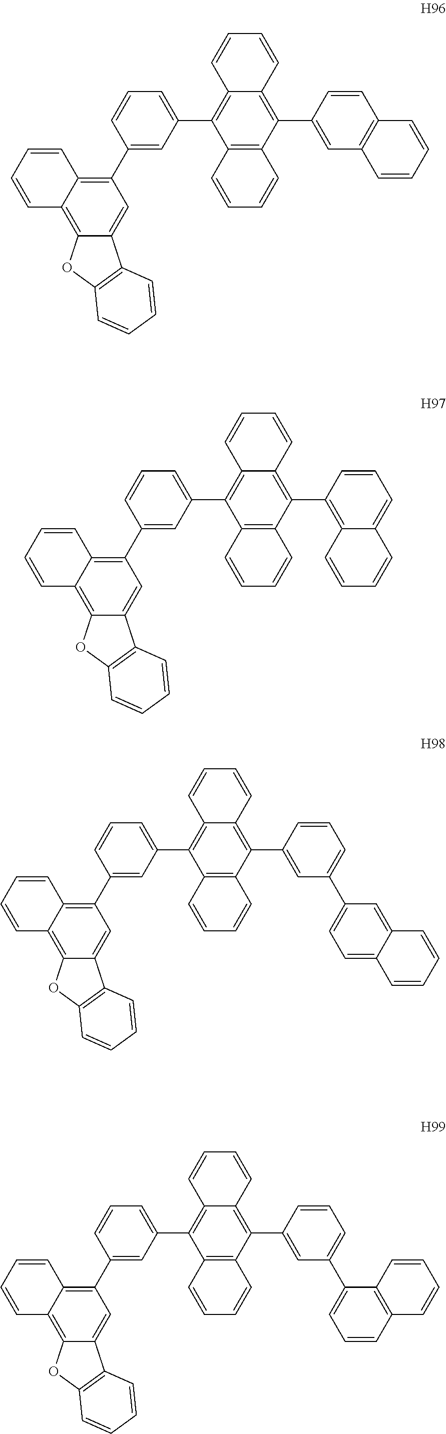 [SMILES: c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1]

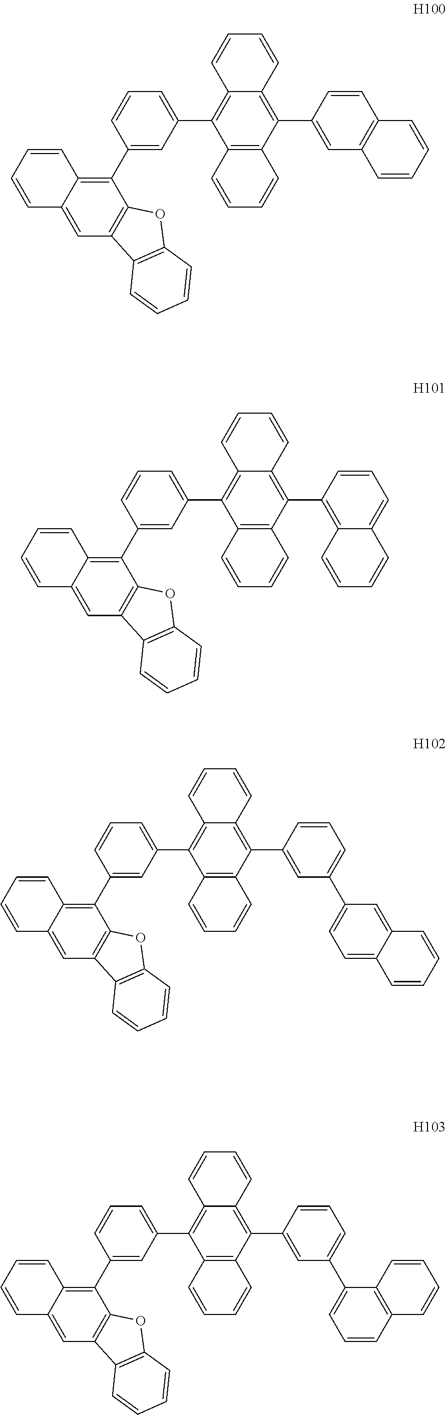 [SMILES: c1cc(-c2c3ccccc3c(-c3ccc4ccccc4c3)c3ccccc23)cc(-c2c3ccccc3cc3c2oc2ccccc23)c1 ; c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1]

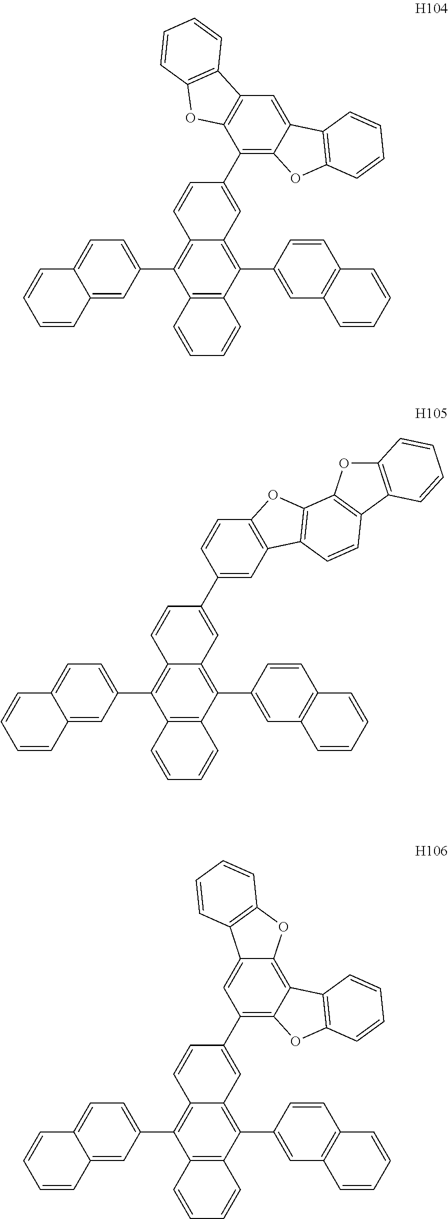 [SMILES: c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1]

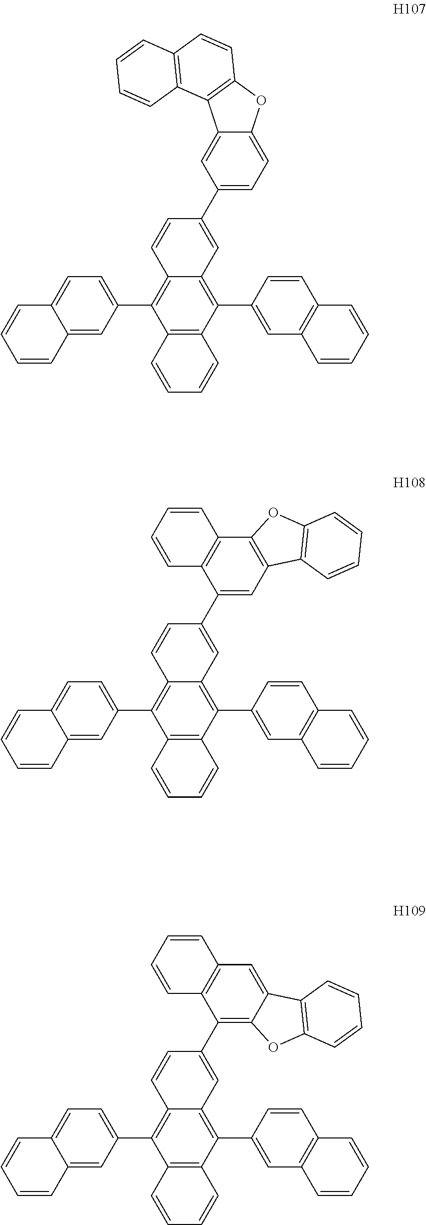 [SMILES: c1ccc2cc(-c3c4ccccc4c(-c4ccc5ccccc5c4)c4cc(-c5ccc6oc7ccc8ccccc8c7c6c5)ccc34)ccc2c1 ; c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1]

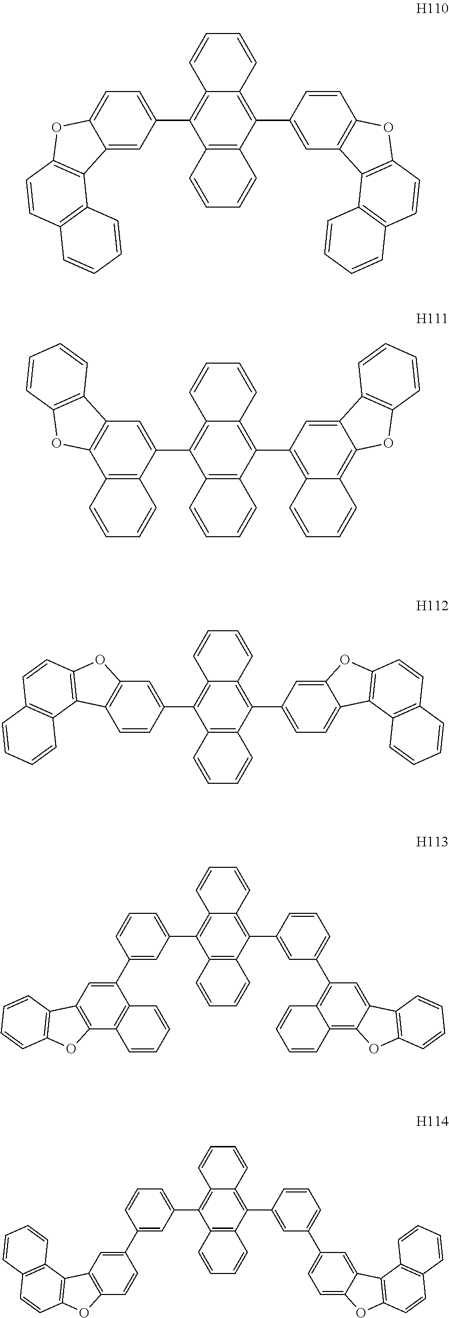 [SMILES: c1ccc2c(c1)ccc1oc3ccc(-c4c5ccccc5c(-c5ccc6oc7ccc8ccccc8c7c6c5)c5ccccc45)cc3c12 ; c1ccc2c(c1)oc1c3ccccc3c(-c3c4ccccc4c(-c4cc5c6ccccc6oc5c5ccccc45)c4ccccc34)cc21 ; c1ccc2c(c1)ccc1oc3cc(-c4c5ccccc5c(-c5ccc6c(c5)oc5ccc7ccccc7c56)c5ccccc45)ccc3c12 ; c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1]

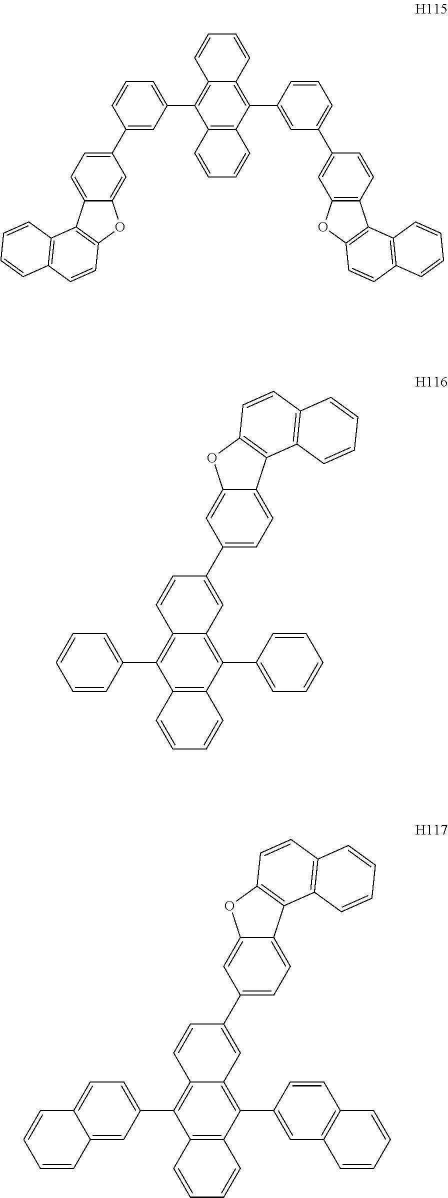 [SMILES: c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1]

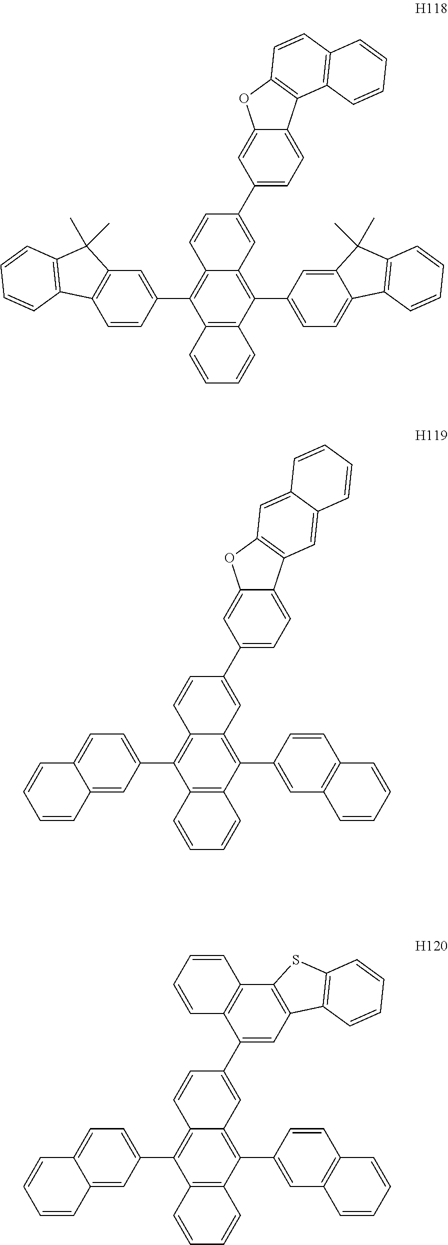 [SMILES: CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1 ; c1ccc2cc(-c3c4ccccc4c(-c4ccc5ccccc5c4)c4cc(-c5cc6c7ccccc7sc6c6ccccc56)ccc34)ccc2c1]

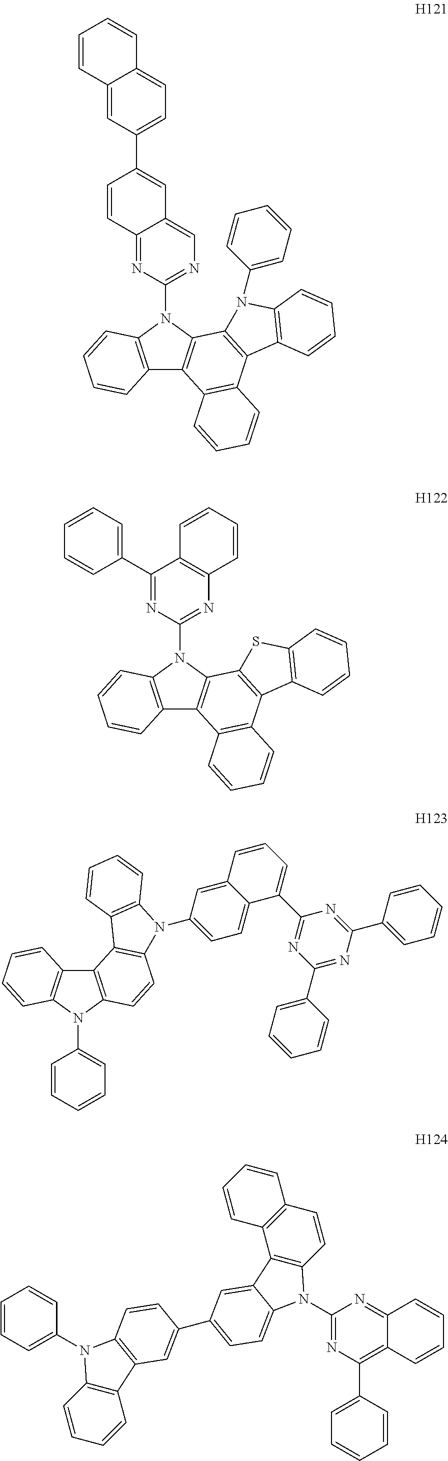 [SMILES: c1ccc(-n2c3ccccc3c3c4ccccc4c4c5ccccc5n(-c5ncc6cc(-c7ccc8ccccc8c7)ccc6n5)c4c32)cc1 ; c1ccc(-c2nc(-n3c4ccccc4c4c5ccccc5c5c6ccccc6sc5c43)nc3ccccc23)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

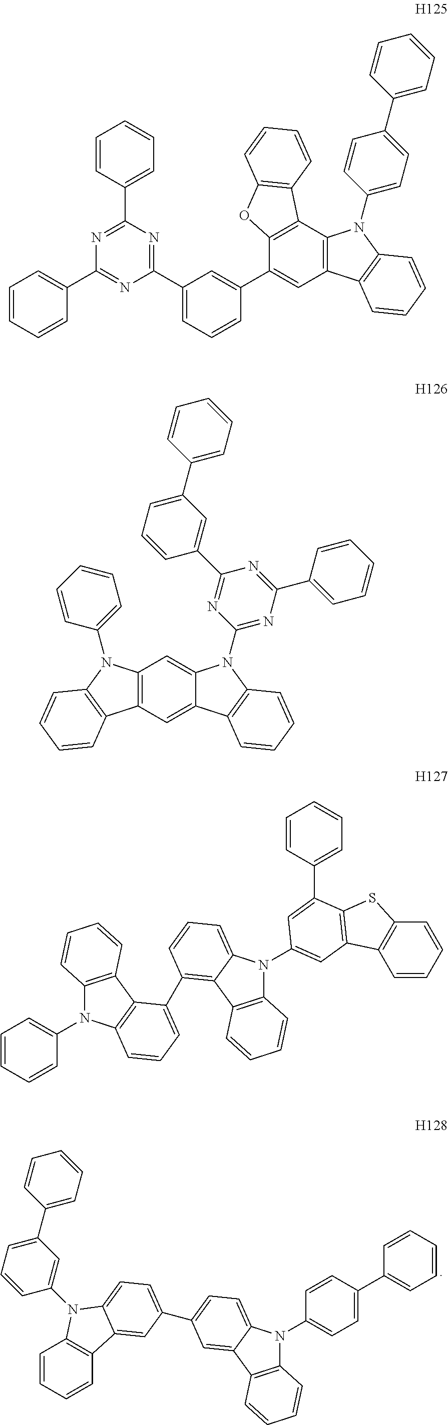 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

### Phosphorescent Dopant

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

For example, the phosphorescent dopant may include an organometallic compound represented by Formula 401:

M(L₄₀₁)_{xc1}(L₄₀₂)_{xc2} Formula 401

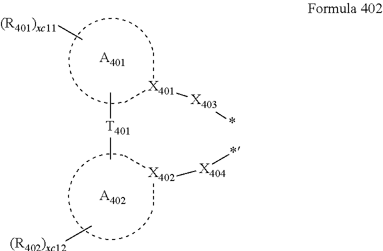

wherein, in Formulae 401 and 402,
M may be a transition metal (e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein, when xc1 is 2 or more, two or more of L₄₀₁ may be identical to or different from each other,
L₄₀₂ may be an organic ligand, and xc2 may be 0, 1, 2, 3, or 4, wherein, when xc2 is 2 or more, two or more of L₄₀₂ may be identical to or different from each other,
X₄₀₁ and X₄₀₂ may each independently be nitrogen or carbon,
ring A401 and ring A402 may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)—*′, *—C(Q₄₁₁)(Q₄₁₂)—*′, *—C(Q₄₁₁)=C(Q₄₁₂)—*′, *—C(Q₄₁₁)=*′, or *═C═*′,
X₄₀₃ and X₄₀₄ may each independently be a chemical bond (e.g., a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each be as described in connection with Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ are each the same as described in connection with Q₁,
xc11 and xc12 may each independently be an integer from 0 to 10, and
* and *′ in Formula 402 each indicate a binding site to M in Formula 401.

For example, in Formula 402, i) X₄₀₁ may be nitrogen and X₄₀₂ may be carbon, or ii) each of X₄₀₁ and X₄₀₂ may be nitrogen.

In one or more embodiments, when xc1 in Formula 401 is 2 or more, two ring A401 (s) among two or more of L₄₀₁ may optionally be linked to each other via T₄₀₂, which is a linking group, and two ring A402(s) among two or more of L₄₀₁ may optionally be linked to each other via T₄₀₃, which is a linking group (see Compounds PD1 to PD4 and PD7). T₄₀₂ and T₄₀₃ may each be the as described in connection with T₄₀₁.

In Formula 401, L₄₀₂ may be an organic ligand. For example, L₄₀₂ may include a halogen group, a diketone group (e.g., an acetylacetonate group), a carboxylic acid group (e.g., a picolinate group), —C(═O), an isonitrile group, —CN group, a phosphorus group (e.g., a phosphine group, a phosphite group, and/or the like), or any combination thereof.

The phosphorescent dopant may include, for example, at least one of (e.g., selected from among) Compounds PD1 to PD39, and/or any combination thereof:

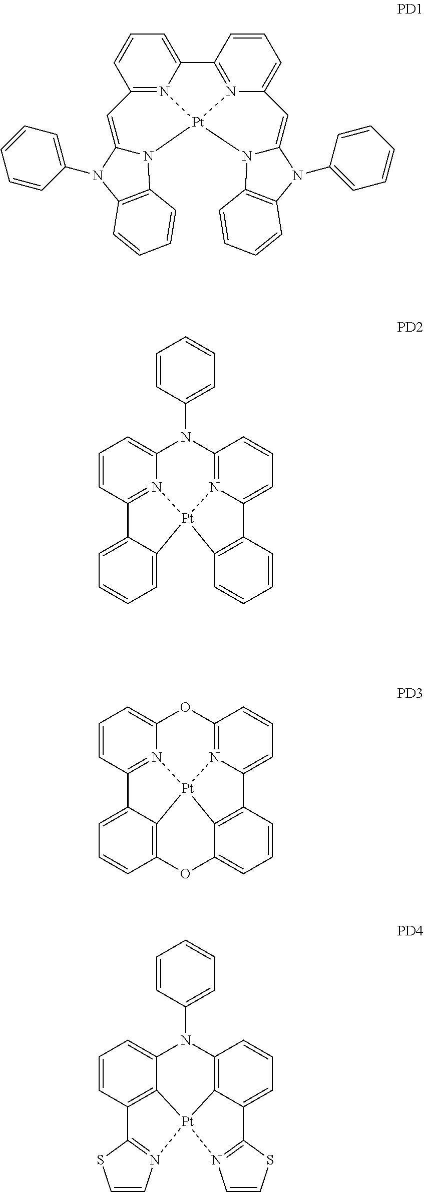

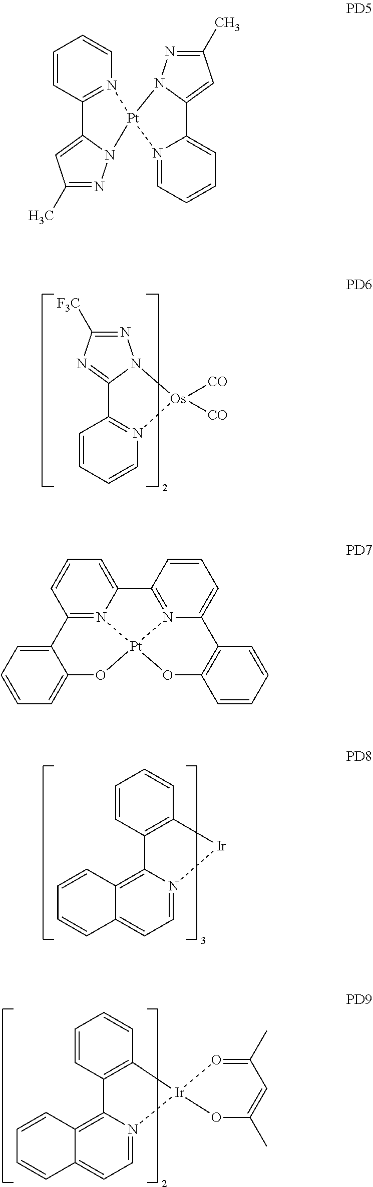

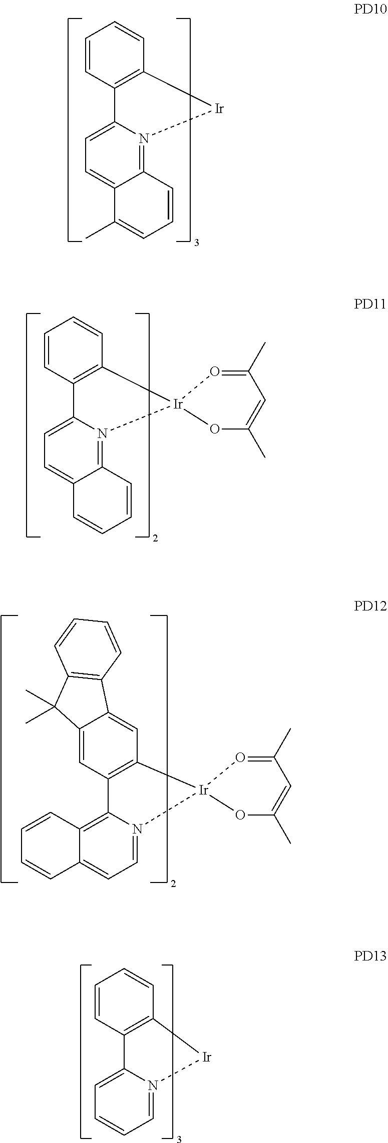

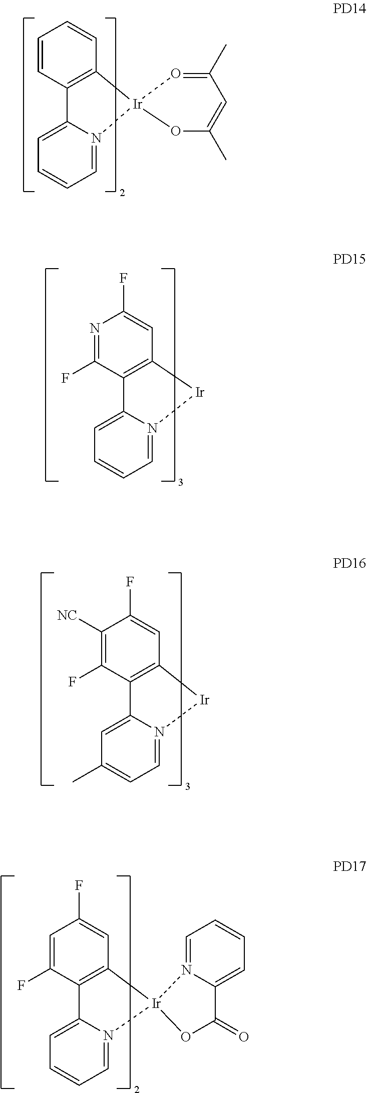

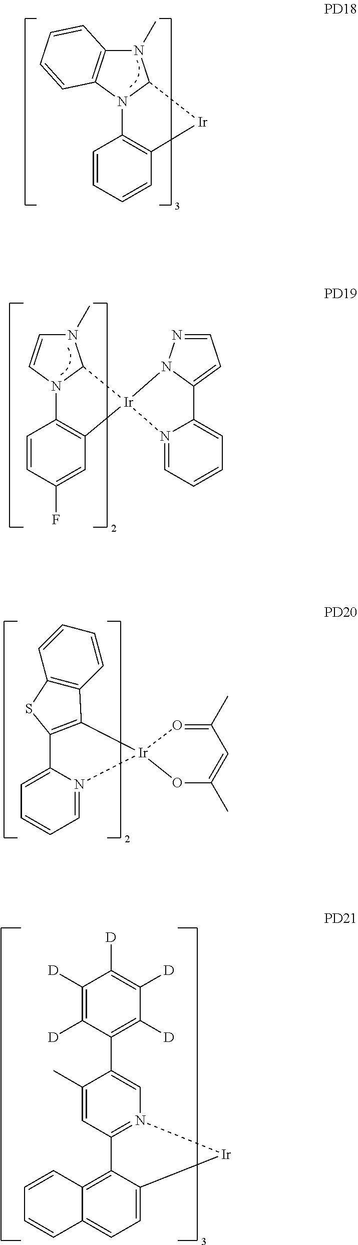

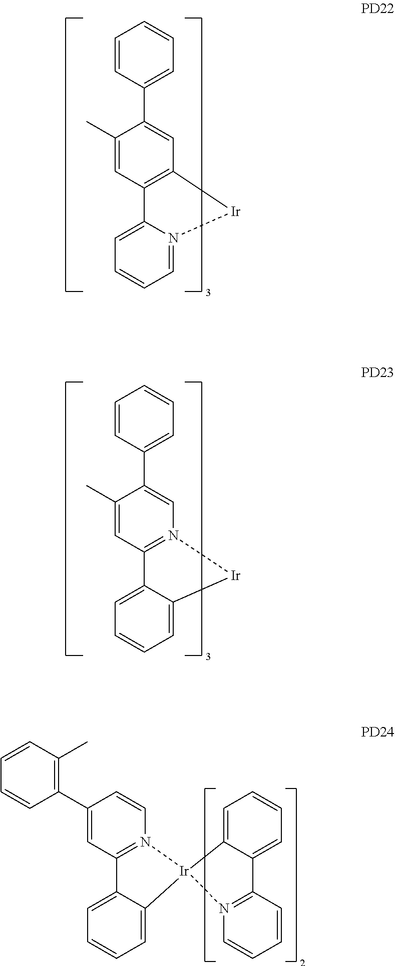

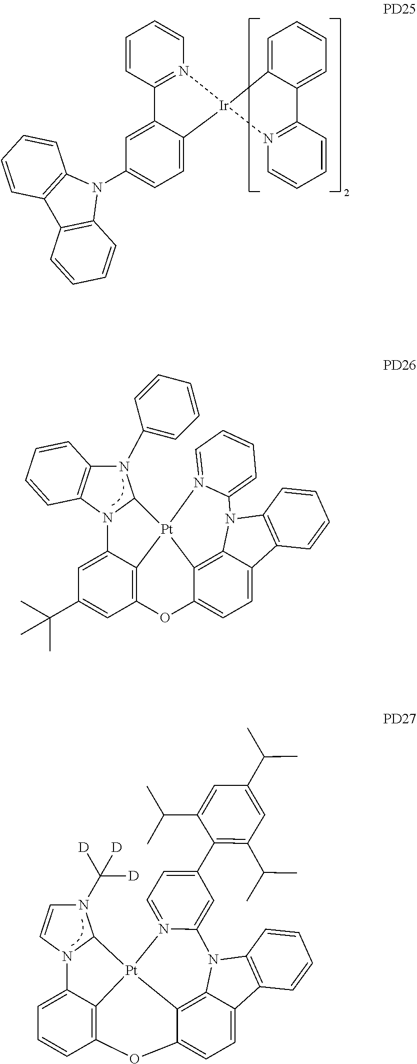

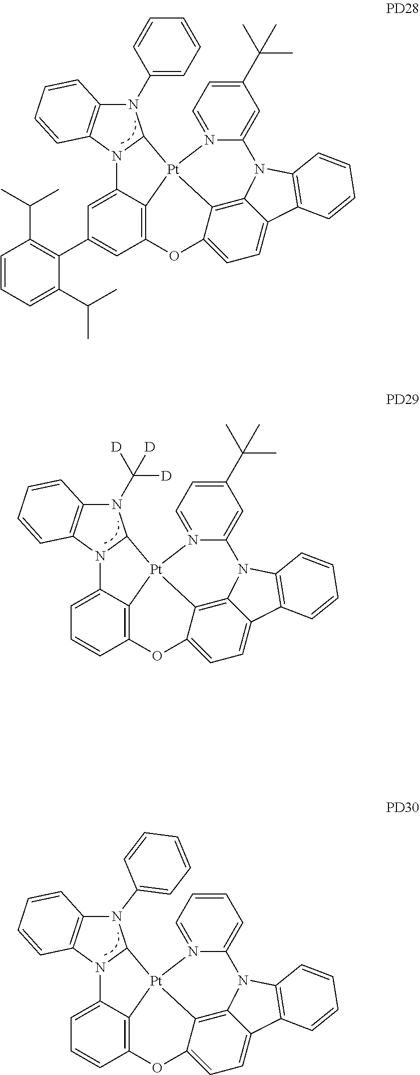

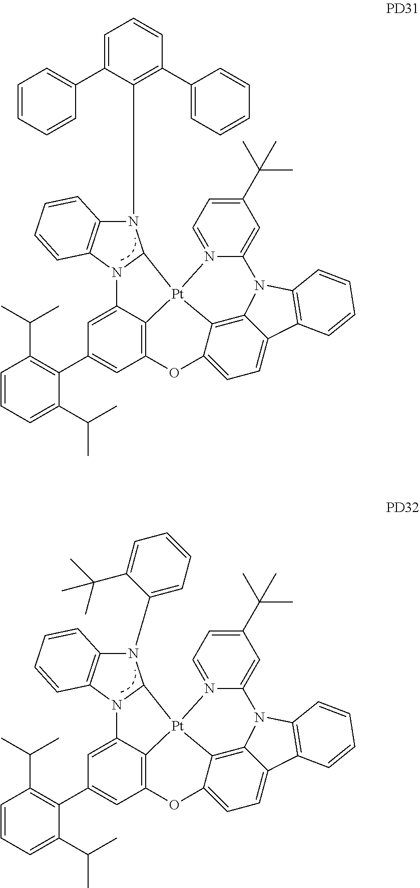

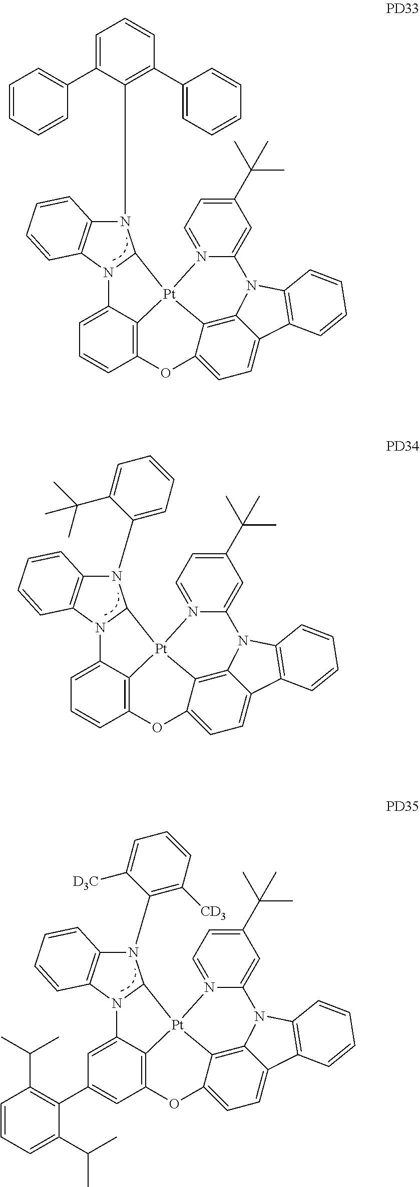

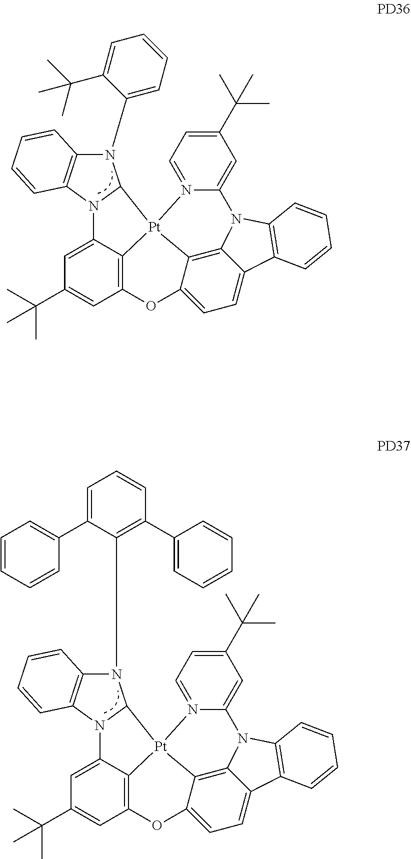

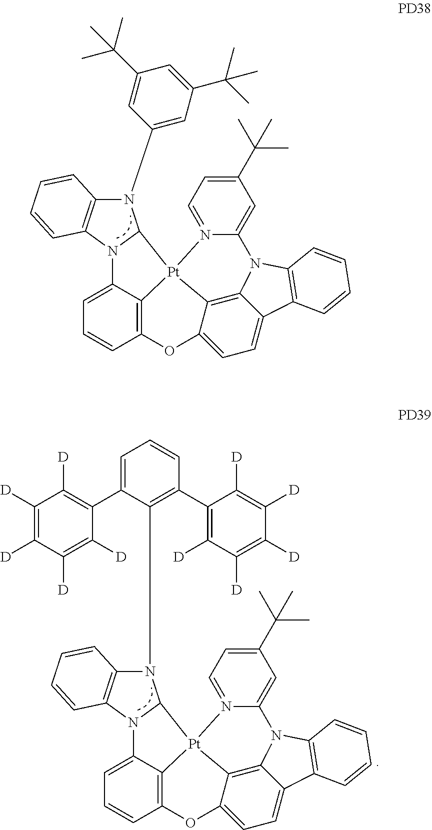

### Fluorescent Dopant

The fluorescent dopant may include an amine group-containing compound, a styryl group-containing compound, or any combination thereof.

For example, the fluorescent dopant may include at least one compound represented by Formula 501:

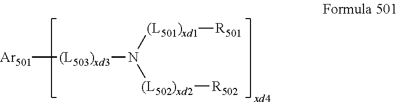

wherein, in Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

For example, Ar₅₀₁ in Formula 501 may be a condensed cyclic group (e.g., an anthracene group, a chrysene group, a pyrene group, and/or the like) in which three or more monocyclic groups are condensed together.

In one or more embodiments, xd4 in Formula 501 may be 2.

In one or more embodiments, the fluorescent dopant may include: at least one of (e.g., selected from among) Compounds FD1 to FD37; DPVBi; DPAVBi; and/or any combination thereof:

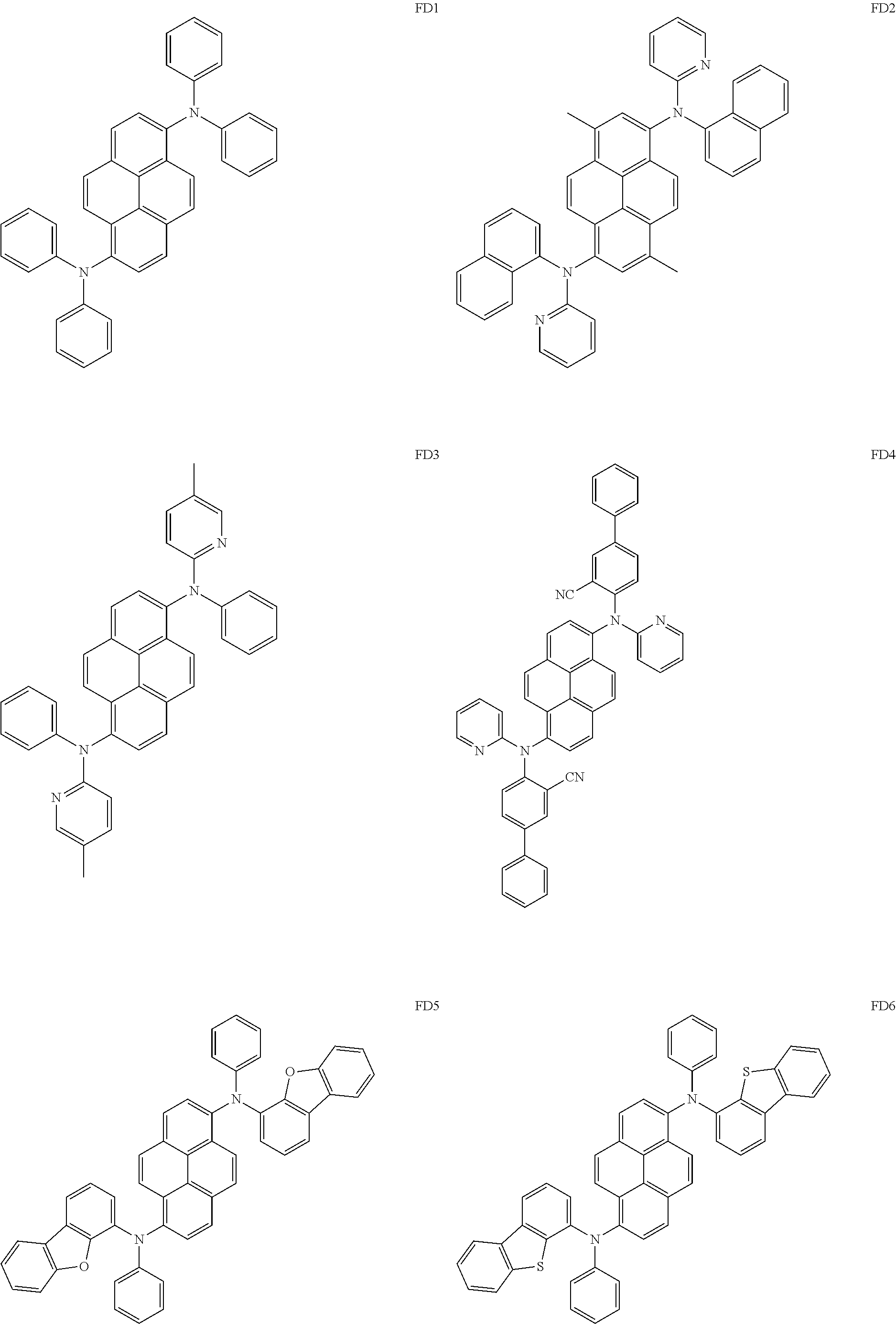

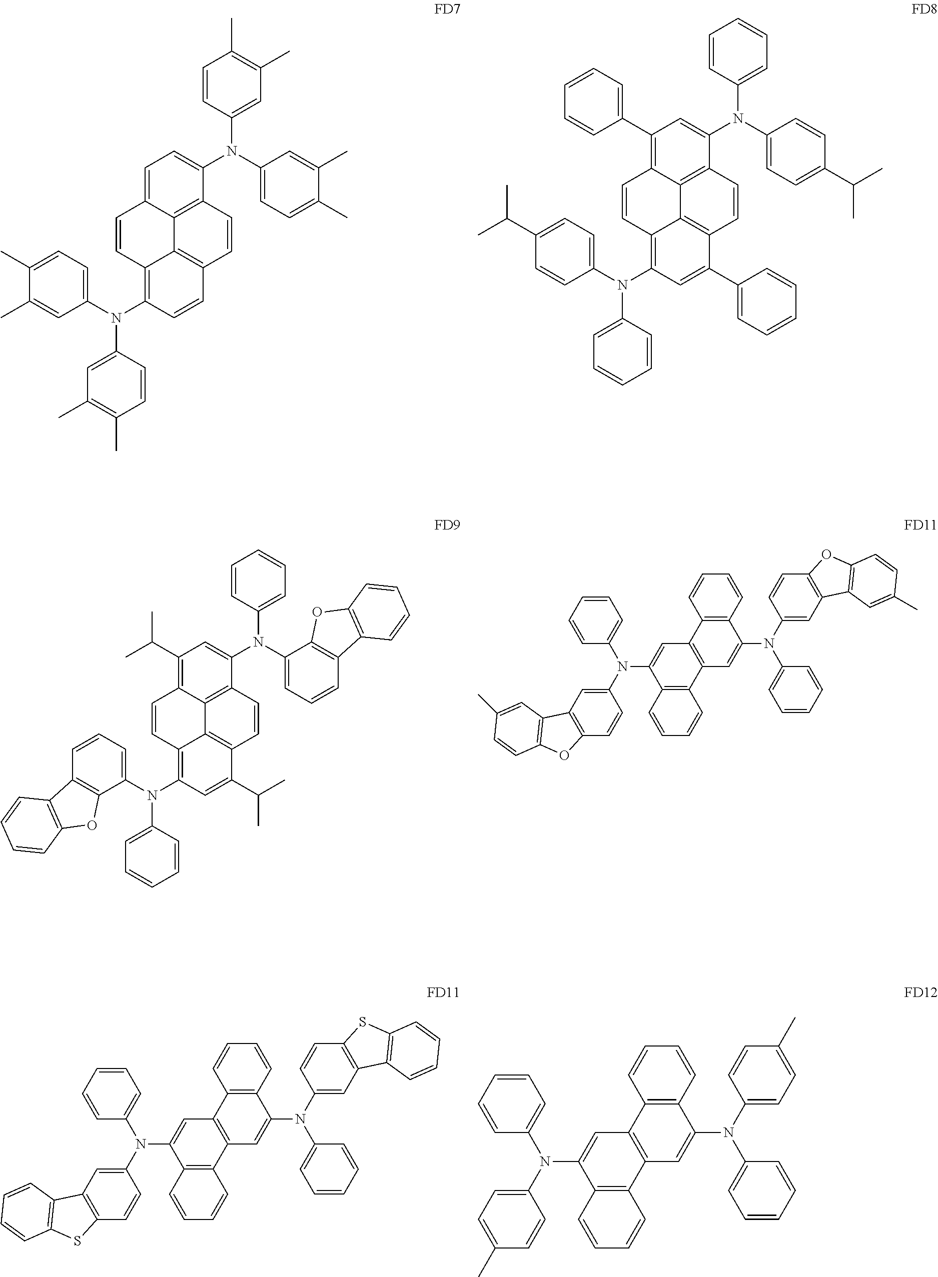

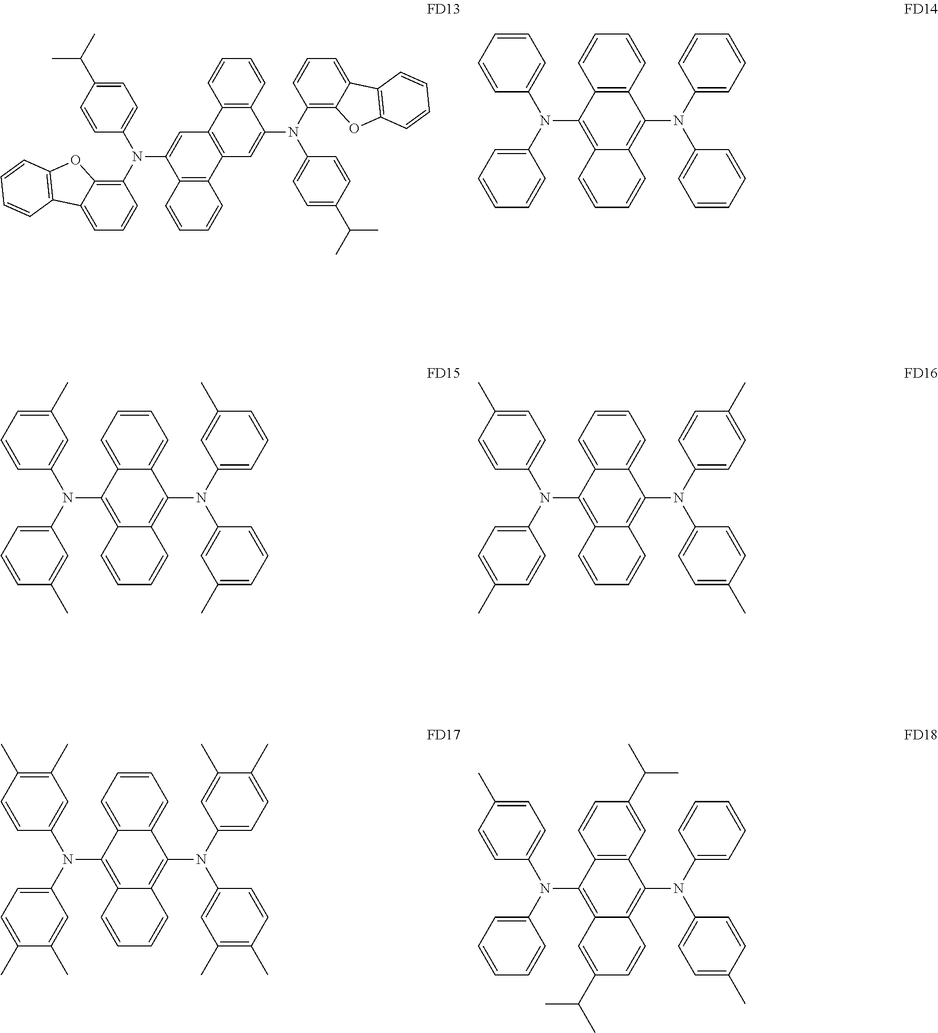 [SMILES: CC(C)c1ccc(N(c2cc3c4ccccc4c(N(c4ccc(C(C)C)cc4)c4cccc5c4oc4ccccc45)cc3c3ccccc23)c2cccc3c2oc2ccccc23)cc1 ; c1ccc(N(c2ccccc2)c2c3ccccc3c(N(c3ccccc3)c3ccccc3)c3ccccc23)cc1 ; Cc1cccc(N(c2cccc(C)c2)c2c3ccccc3c(N(c3cccc(C)c3)c3cccc(C)c3)c3ccccc23)c1 ; Cc1ccc(N(c2ccc(C)cc2)c2c3ccccc3c(N(c3ccc(C)cc3)c3ccc(C)cc3)c3ccccc23)cc1 ; Cc1ccc(N(c2ccc(C)c(C)c2)c2c3ccccc3c(N(c3ccc(C)c(C)c3)c3ccc(C)c(C)c3)c3ccccc23)cc1C ; Cc1ccc(N(c2ccccc2)c2c3ccc(C(C)C)cc3c(N(c3ccccc3)c3ccc(C)cc3)c3ccc(C(C)C)cc23)cc1]

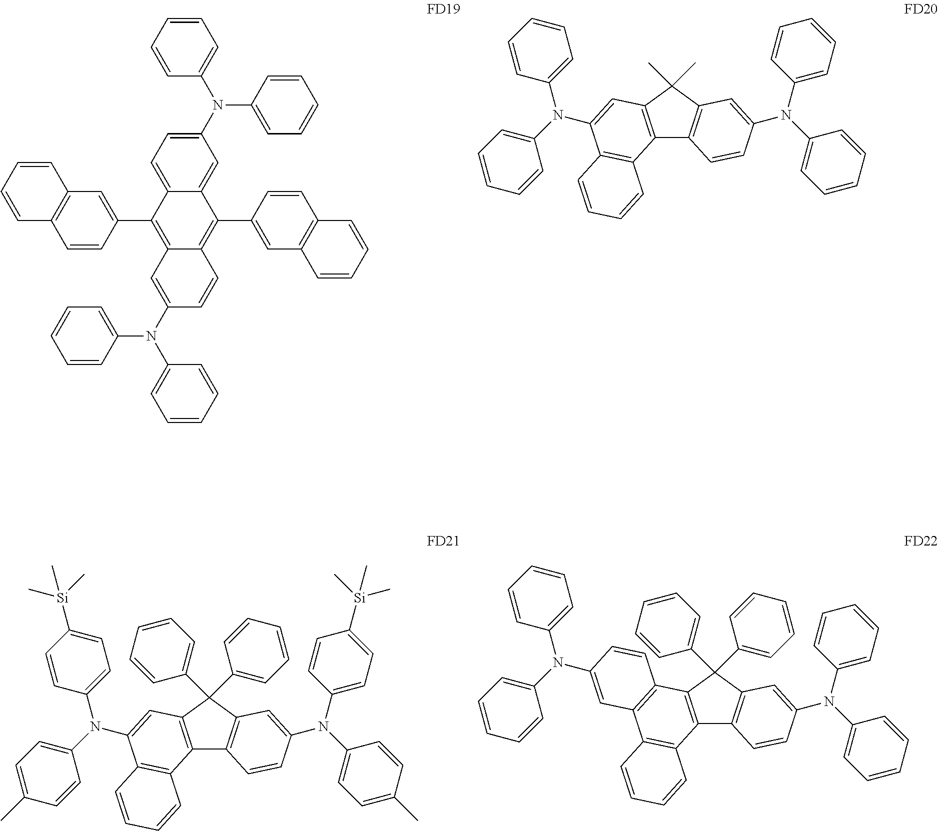

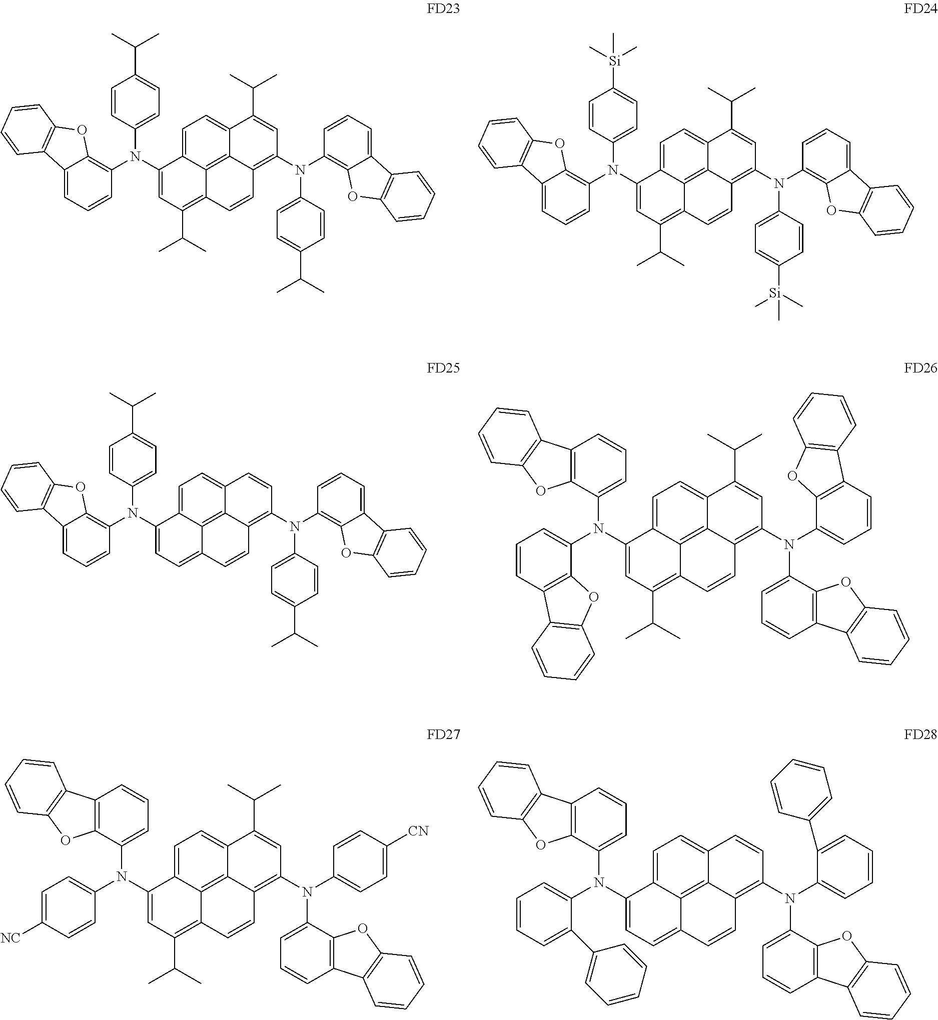

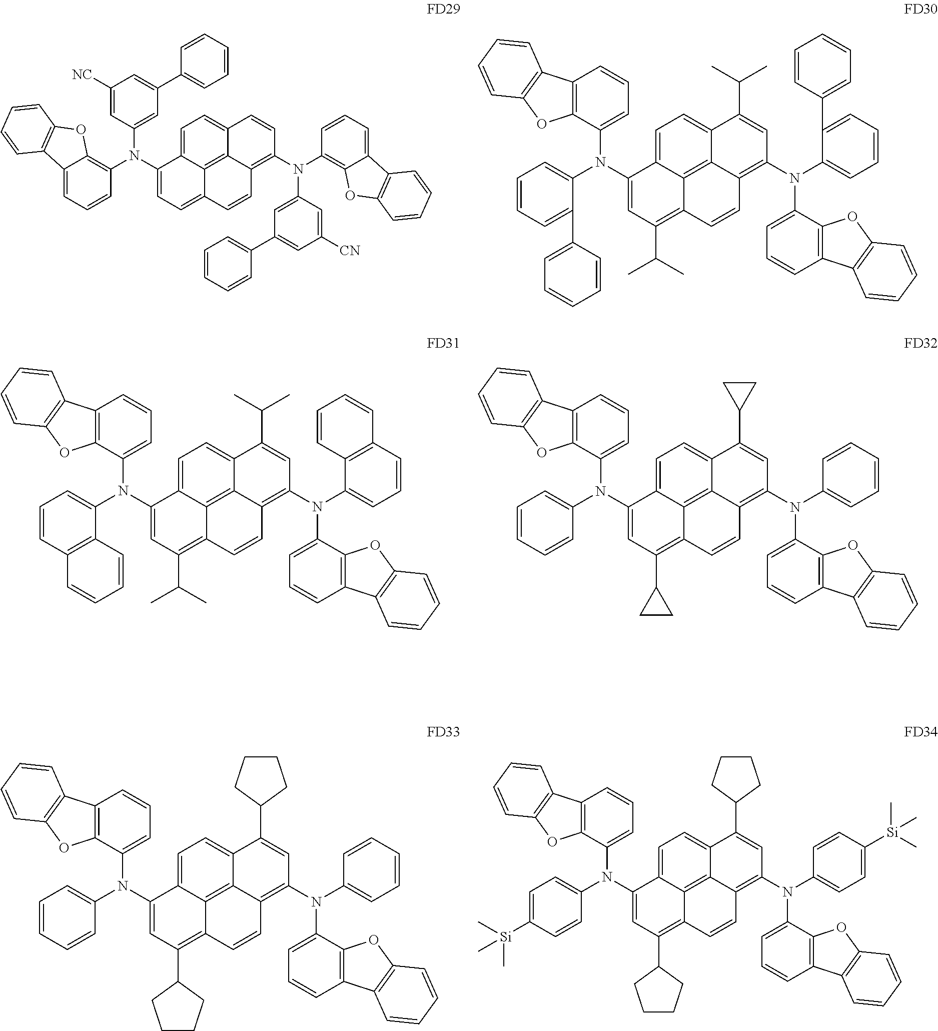

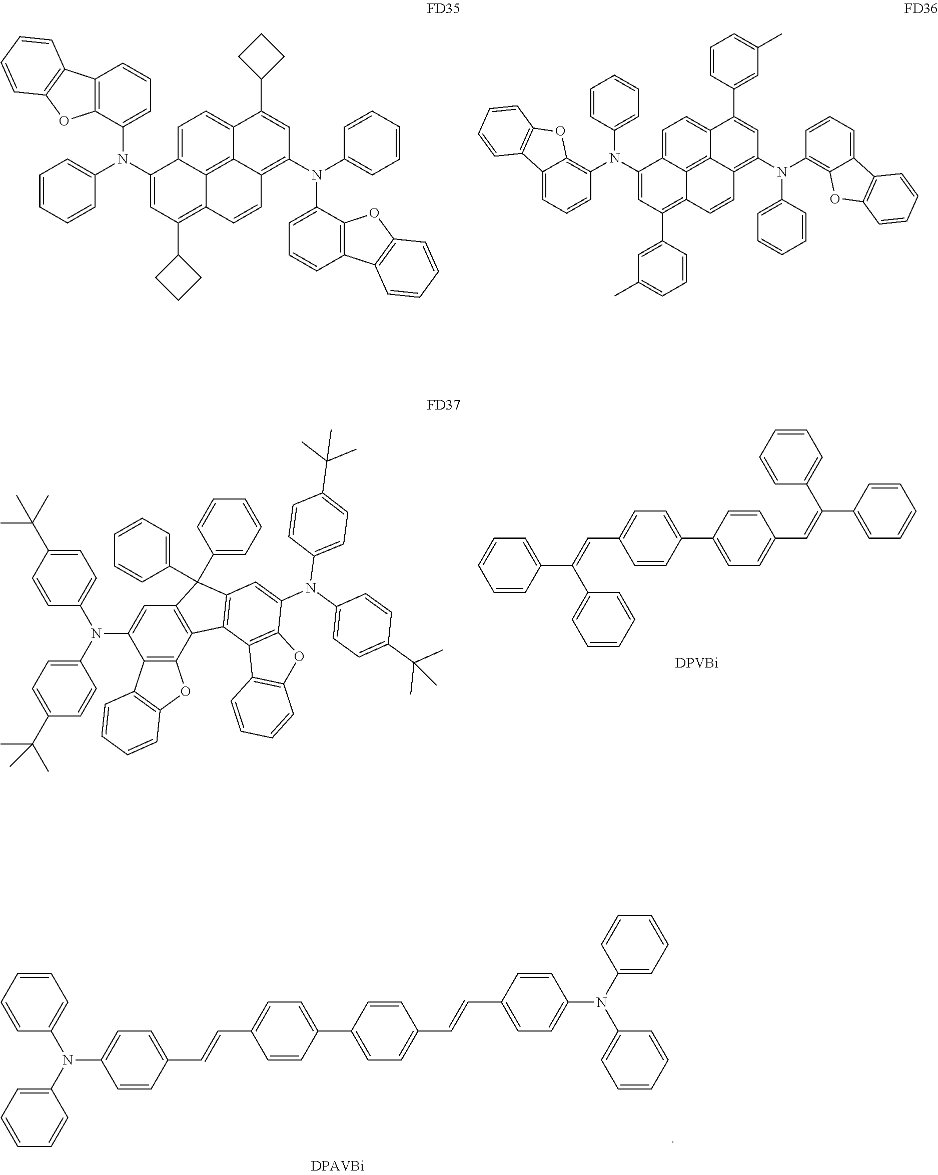

### Delayed Fluorescence Material

The emission layer 130 may include a delayed fluorescence material.

The delayed fluorescence material described herein may be selected from compounds capable of emitting delayed fluorescence based on a delayed fluorescence emission mechanism.

The delayed fluorescence material included in the emission layer 130 may act as a host or a dopant depending on the type or kind of other materials included in the emission layer 130.

In one or more embodiments, a difference between a triplet energy level (eV) of the delayed fluorescence material and a singlet energy level (eV) of the delayed fluorescence material may be 0 eV to about 0.5 eV. When the difference between the triplet energy level (eV) of the delayed fluorescence material and the singlet energy level (eV) of the delayed fluorescence material is satisfied within the range described, up-conversion from the triplet state to the singlet state of the delayed fluorescence material may effectively occur, and thus, the light-emitting device 10 may have improved luminescence efficiency.

For example, the delayed fluorescence material may include i) a material including at least one electron donor (e.g., a π electron-rich C₃-C₆₀ cyclic group, such as a carbazole group, and/or the like) and at least one electron acceptor (e.g., a sulfoxide group, a cyano group, a π electron-deficient nitrogen-containing C₁-C₆₀ cyclic group, and/or the like), and ii) a material including a C₈-C₆₀ polycyclic group in which two or more cyclic groups are condensed while sharing boron (B).

Examples of the delayed fluorescence material may include at least one of (e.g., selected from among) Compounds DF1 to DF14:

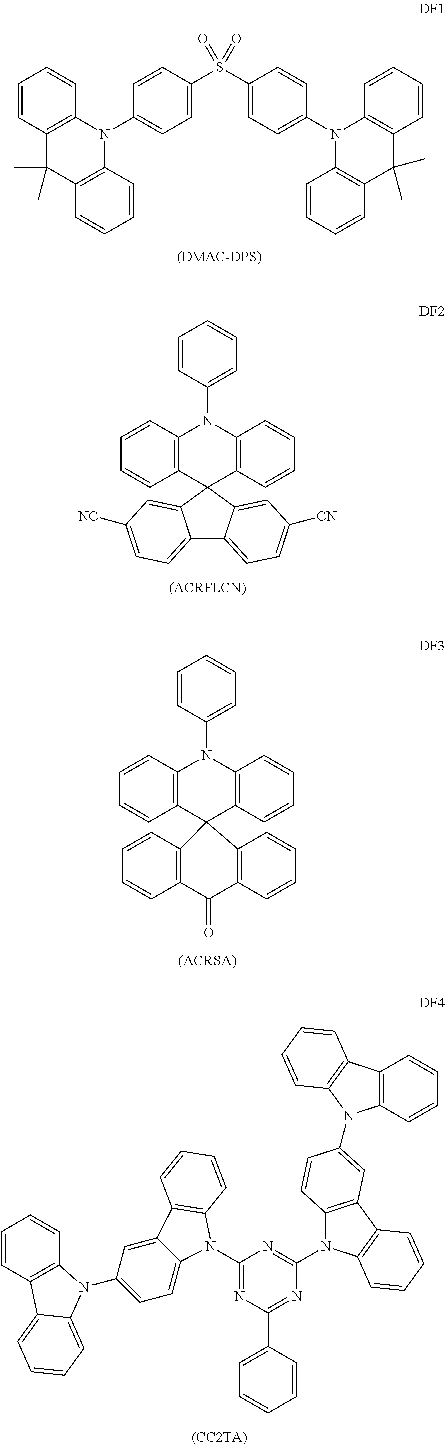

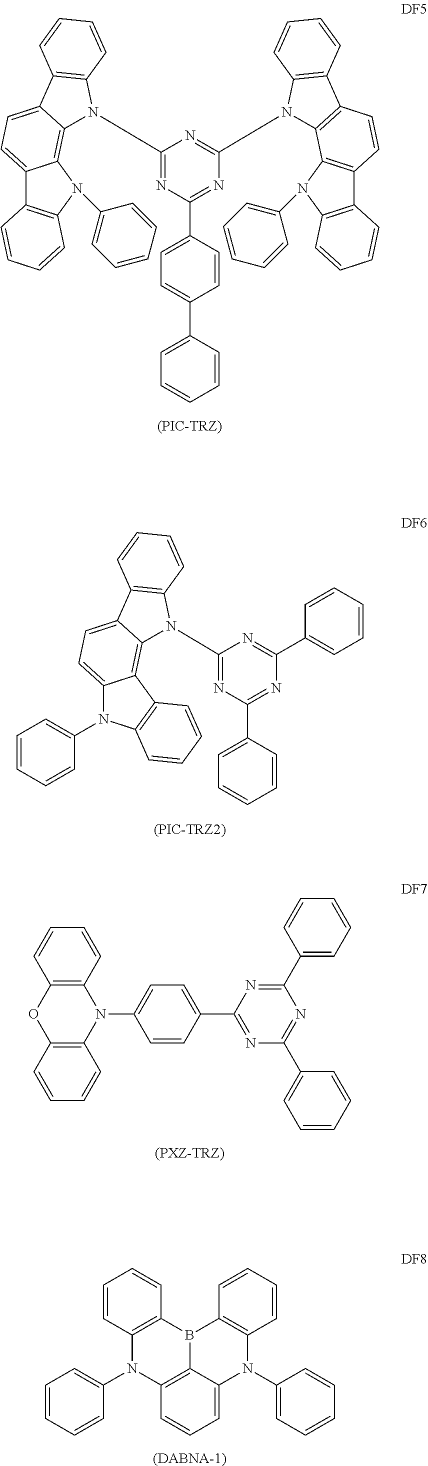

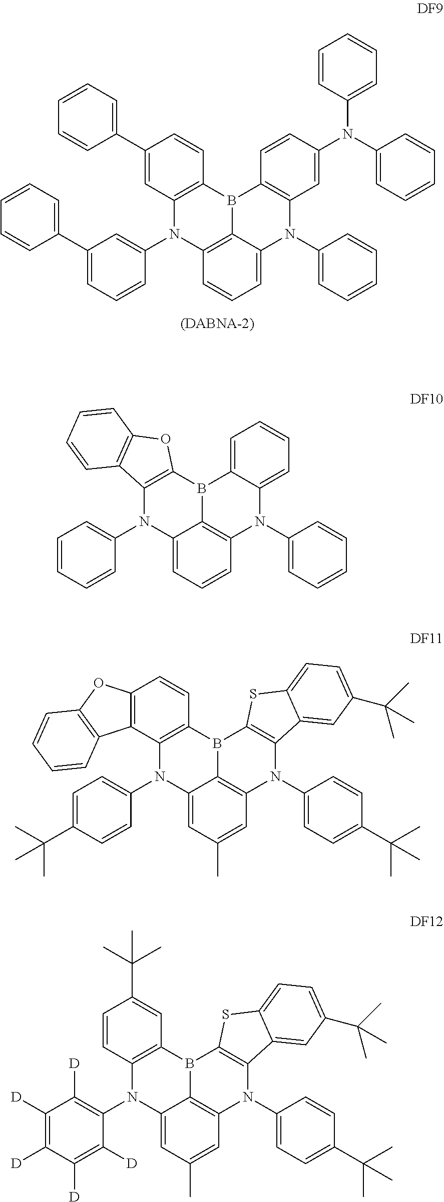

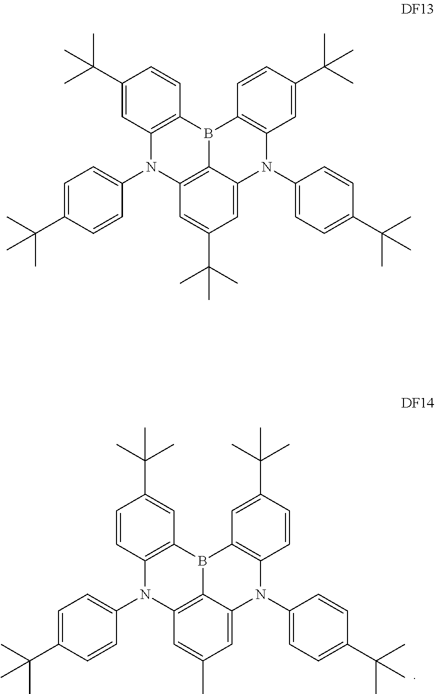

### Quantum Dot

The emission layer 130 may include a quantum dot.

The term “quantum dot” as utilized herein refers to a crystal of a semiconductor compound, and may include any material capable of emitting light of one or more suitable emission wavelengths according to the size of the crystal.

A diameter of the quantum dot may be, for example, in a range of about 1 nanometer (nm) to about 10 nm. Unless otherwise defined, in the present disclosure, the term “particle diameter” or “quantum dot size” refers to an average diameter if (e.g., when) particles or dots are spherical and refers to an average major axis length if (e.g., when) particles or dots are non-spherical. A particle diameter or dot size may be measured by utilizing a particle size analyzer (PSA) or from a transmission electron microscope (TEM) image or a scanning electron microscope (SEM) image. A “particle diameter” or “dot size” is, for example, an average particle diameter or average dot size. An “average particle diameter” or “average dot size” refers to, for example, a median particle diameter or dot size (D50), which refers to the diameter of particles or dots having a cumulative volume of 50 vol % in particle size or crystallite size distribution. As another method, a dynamic light-scattering measurement device may be utilized to perform measurement and data analysis, the number of particles or dots may be counted for each particle size or dot size range, and then the average particle diameter or average dot diameter (D50) may be obtained through calculation therefrom. In some embodiments, the average particle diameter or average dot diameter (D50) may be measured by utilizing a laser diffraction method. If (e.g., when) measurement is performed by a laser diffraction method, for example, particles or dots to be measured may be dispersed in a dispersion medium, and then may be irradiated with ultrasonic waves of about 28 kHz at an output of 60 W by utilizing a commercially available laser diffraction particle or dot size measurement device (e.g., Microtrac MT 3000), and then the average or dot diameter (D50) on the basis of 50% of the particle or dot diameter distribution in the measurement device may be calculated.

The quantum dot may be synthesized by a wet chemical process, a metal organic chemical vapor deposition process, a molecular beam epitaxy process, or any process similar thereto.

The wet chemical process is a method including mixing a precursor material with an organic solvent and then growing quantum dot particle crystals. When the crystal grows, the organic solvent naturally acts as a dispersant coordinated on the surface of the quantum dot crystal and controls the growth of the crystal so that the growth of quantum dot particles can be controlled or selected through a process which costs lower, and is easier than vapor deposition methods, such as metal organic chemical vapor deposition (MOCVD) or molecular beam epitaxy (MBE).

The quantum dot may include: a Group II-VI semiconductor compound; a Group III-V semiconductor compound; a Group III-VI semiconductor compound; a Group 1-Ill-VI semiconductor compound; a Group IV-VI semiconductor compound; a Group IV element or compound; or any combination thereof.

Examples of the Group II-VI semiconductor compound are: a binary compound, such as CdS, CdSe, CdTe, ZnS, ZnSe, ZnTe, ZnO, HgS, HgSe, HgTe, MgSe, MgS, and/or the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or the like; a quaternary compound, such as CdZnSeS, CdZnSeTe, CdZnSTe, CdHgSeS, CdHgSeTe, CdHgSTe, HgZnSeS, HgZnSeTe, HgZnSTe, and/or the like; or any combination thereof.

Examples of the Group III-V semiconductor compound are: a binary compound, such as GaN, GaP, GaAs, GaSb, AlN, AlP, AlAs, AlSb, InN, InP, InAs, InSb, and/or the like; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, and/or the like; a quaternary compound, such as GaAlNP, GaAlNAs, GaAlNSb, GaAlPAs, GaAlPSb, GaInNP, GaInNAs, GaInNSb, GaInPAs, GaInPSb, InAINP, InAINAs, InAINSb, InAlPAs, InAlPSb, and/or the like; or any combination thereof. In one or more embodiments, the Group Ill-V semiconductor compound may further include a Group II element. Examples of the Group III-V semiconductor compound further including the Group II element are InZnP, InGaZnP, InAIZnP, and/or the like.

Examples of the Group III-VI semiconductor compound are: a binary compound, such as GaS, GaSe, Ga₂Se₃, GaTe, InS, InSe, In₂S₃, In₂Se₃, InTe, and/or the like; a ternary compound, such as InGaS₃, InGaSe₃, and/or the like; or any combination thereof.

Examples of the Group I-III-VI semiconductor compound are: a ternary compound, such as AgInS, AgInS₂, CuInS, CuInS₂, CuGaO₂, AgGaO₂, AgAlO₂, and/or the like; a quaternary compound, such as AgInGaS, AgInGaS₂, and/or the like; or any combination thereof.

Examples of the Group IV-VI semiconductor compound are: a binary compound, such as SnS, SnSe, SnTe, PbS, PbSe, PbTe, and/or the like; a ternary compound, such as SnSeS, SnSeTe, SnSTe, PbSeS, PbSeTe, PbSTe, SnPbS, SnPbSe, SnPbTe, and/or the like; a quaternary compound, such as SnPbSSe, SnPbSeTe, SnPbSTe, and/or the like; or any combination thereof.

Examples of the Group IV element or compound are: a single element, such as Si, Ge, and/or the like; a binary compound, such as SiC, SiGe, and/or the like; or any combination thereof.

Each element included in a multi-element compound, such as the binary compound, the ternary compound, and the quaternary compound, may be present at a substantially uniform concentration or non-substantially uniform concentration in a particle.

In one or more embodiments, the quantum dot may have a single structure in which the concentration of each element in the quantum dot is substantially uniform, or may have a core-shell dual structure. For example, a material included in the core and a material included in the shell may be different from each other.

The shell of the quantum dot may act as a protective layer which prevents chemical denaturation of the core to maintain semiconductor characteristics, and/or as a charging layer which imparts electrophoretic characteristics to the quantum dot. The shell may be single-layered or multi-layered. The interface between the core and the shell may have a concentration gradient in which the concentration of an element existing in the shell decreases toward the center of the core.

Examples of the shell of the quantum dot are an oxide of metal, metalloid, or non-metal, a semiconductor compound, or a combination thereof. Examples of the oxide of metal, metalloid, or non-metal are: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or the like; a ternary compound, such as MgAl₂O₄, CoFe₂O₄, NiFe₂O₄, CoMn₂O₄, and/or the like; or any combination thereof. Examples of the semiconductor compound are: as described herein, a Group II-VI semiconductor compound; a Group Ill-V semiconductor compound; a Group Ill-VI semiconductor compound; a Group 1-Ill-VI semiconductor compound; a Group IV-VI semiconductor compound; or any combination thereof. For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

The quantum dot may have a full width at half maximum (FWHM) of an emission wavelength spectrum of about 45 nm or less, for example, about 40 nm or less, or for example, about 30 nm or less. When the FWHM of the quantum dot is within these ranges, the quantum dot may have improved color purity or improved color reproducibility. In some embodiments, because light emitted through the quantum dot is emitted in all directions, the wide viewing angle may be improved.

In some embodiments, the quantum dot may be in the form of spherical, pyramidal, multi-arm, or cubic nanoparticles, nanotubes, nanowires, nanofibers, or nanoplate particles.

Because the energy band gap may be adjusted by controlling the size of the quantum dot, light having one or more suitable wavelength bands may be obtained from the quantum dot emission layer. Accordingly, by utilizing quantum dots of different sizes, a light-emitting device that emits light of one or more suitable wavelengths may be implemented. In detail, the size of the quantum dot may be selected to emit red light, green light, and/or blue light. In some embodiments, the size of the quantum dot may be configured to emit white light by combination of light of one or more suitable colors.

### Optical Activation Layer 135

The optical activation layer 135 may be to absorb incident light to generate excitons. The excitons may generate holes and electrons. The holes generated by the optical activation layer 135 may move to the first electrode 110 through the hole transport region 120. The electrons generated by the optical activation layer 135 may move to the second electrode 150 through the electron transport region 140. For example, the optical activation layer 135 may be to absorb light to generate an electrical signal. In more detail, each of the first compound and the second compound included in the optical activation layer 135 may act as a donor for supplying electrons, and may be referred to as a p-type or kind compound. In some embodiments, the third compound included in the optical activation layer 135 may act as an acceptor for receiving electrons, and may be referred to as an n-type or kind compound. Accordingly, the optoelectronic device 30 including the optical activation layer 135 may serve as an optical sensor.

In one or more embodiments, the optical activation layer 135 may not include (e.g., may exclude) (e.g., each of) a subphthalocyanine-based compound and a fullerene-based compound. For example, the optical activation layer 135 may not include (e.g., may exclude) SubPC, SubNC, fullerene 60, and/or fullerene 70:

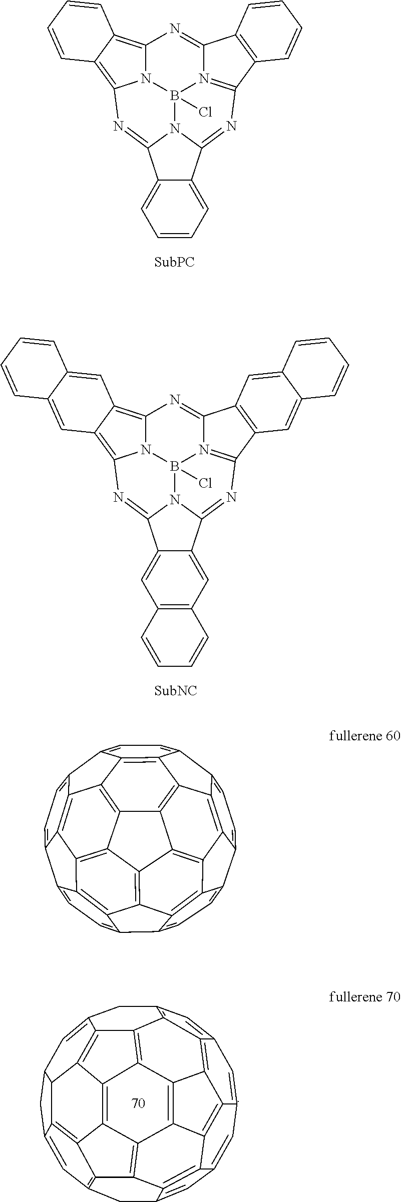

For example, the first to third compounds may not be SubPC, SubNC, fullerene 60, and/or fullerene 70.

The optoelectronic device 30 may include one optical activation layer 135 or a plurality of optical activation layers 135, and the optical activation layer 135 may have a single-layer structure or a multi-layer structure. In this regard, a description of the optoelectronic device 30 including the optical activation layer 135 will be provided.

### Electron Transport Region 140

The electron transport region 140 may have i) a single-layer structure including (e.g., consisting of) a single layer including (e.g., consisting of) a single material, ii) a single-layer structure including (e.g., consisting of) a single layer including multiple materials that are different from each other, or iii) a multi-layer structure including multiple layers including multiple materials that are different from each other.

The electron transport region 140 may include a buffer layer, a hole blocking layer, an electron control layer, an electron transport layer, an electron injection layer, or any combination thereof.

For example, the electron transport region 140 may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein constituent layers of each structure are stacked sequentially from the emission layer 130.

The electron transport region 140 (e.g., the buffer layer, the hole blocking layer, the electron control layer, or the electron transport layer in the electron transport region 140) may include a metal-free compound including at least one π electron-deficient nitrogen-containing C₁-C₆₀ cyclic group.

For example, the electron transport region 140 may include a compound represented by Formula 601:

[Ar₆₀₁]ₓₑ₁₁-[(L₆₀₁)ₓₑ₁-R₆₀₁]ₓₑ₂₁ Formula 601
wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each be as described in connection with Q₁,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

In one or more embodiments, when xe11 in Formula 601 is 2 or more, two or more of Ar₆₀₁ may be linked to each other via a single bond.

In one or more embodiments, Ar₆₀₁ in Formula 601 may be an anthracene group unsubstituted or substituted with at least one R₁₀ₐ.

In one or more embodiments, the electron transport region 140 may include a compound represented by Formula 601-1:

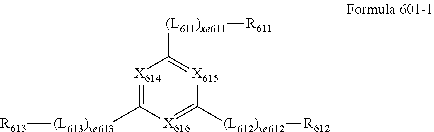

wherein, in Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,
L₆₁₁ to L₆₁₃ are each the same as described in connection with L₆₀₁,
xe611 to xe613 may each be as described in connection with xe1,
R₆₁₁ to R₆₁₃ may each be as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, xe1 and xe611 to xe613 in Formulae 601 and 601-1 may each independently be 0, 1, or 2.

The electron transport region 140 may include: at least one of (e.g., selected from among) Compounds ET1 to ET45; 2,9-dimethyl-4,7-diphenyl-1,10-phenanthroline (BCP); 4,7-diphenyl-1,10-phenanthroline (Bphen); Alq₃; BAlq; TAZ; NTAZ; and/or any combination thereof:

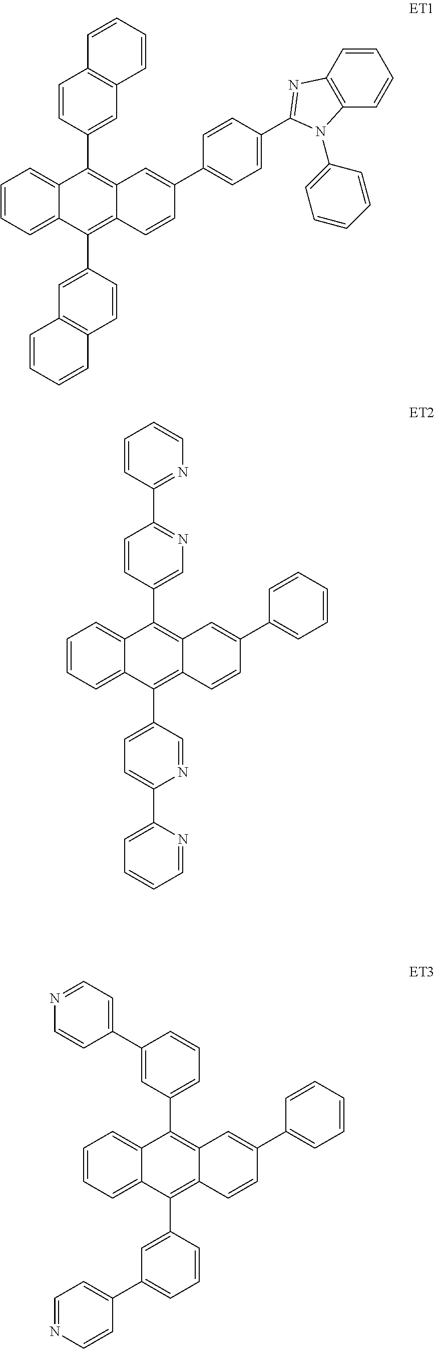 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

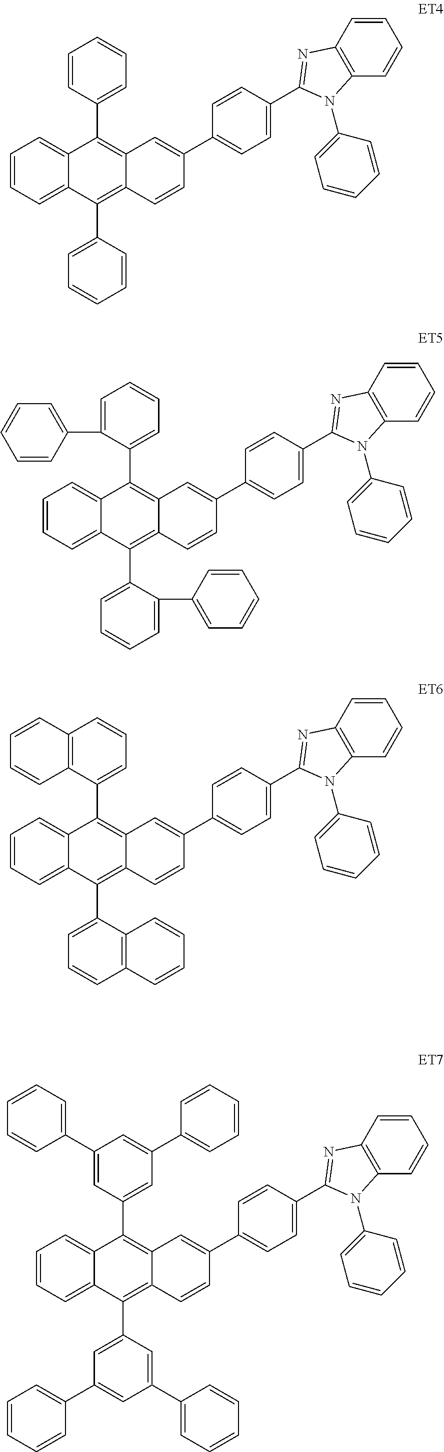 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

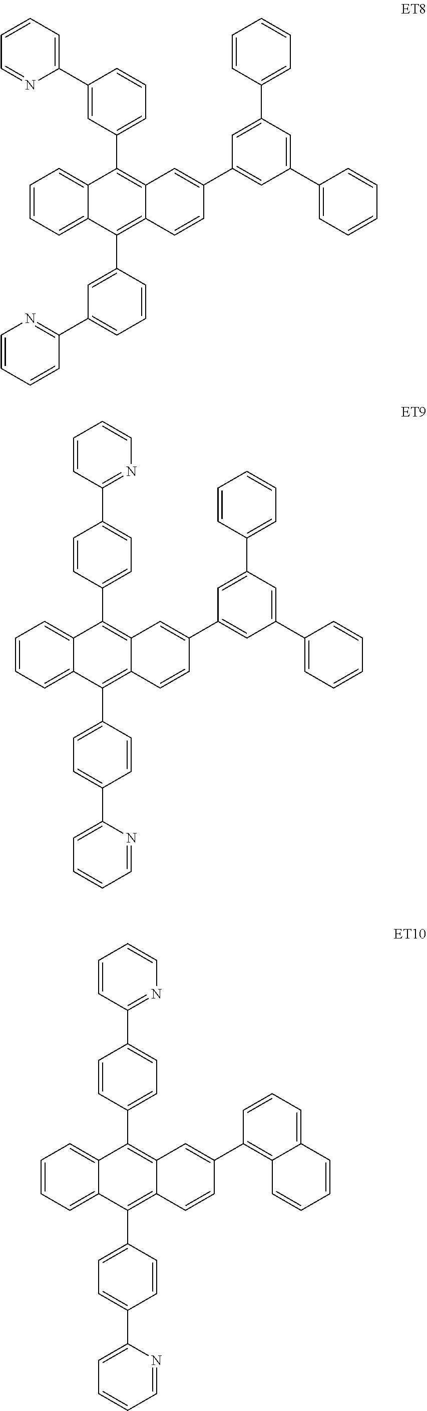 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

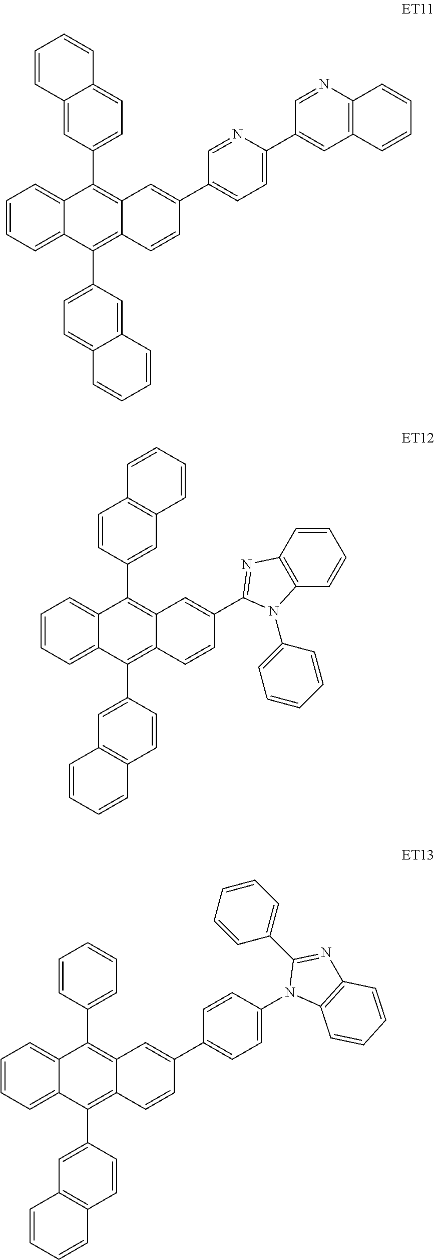 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

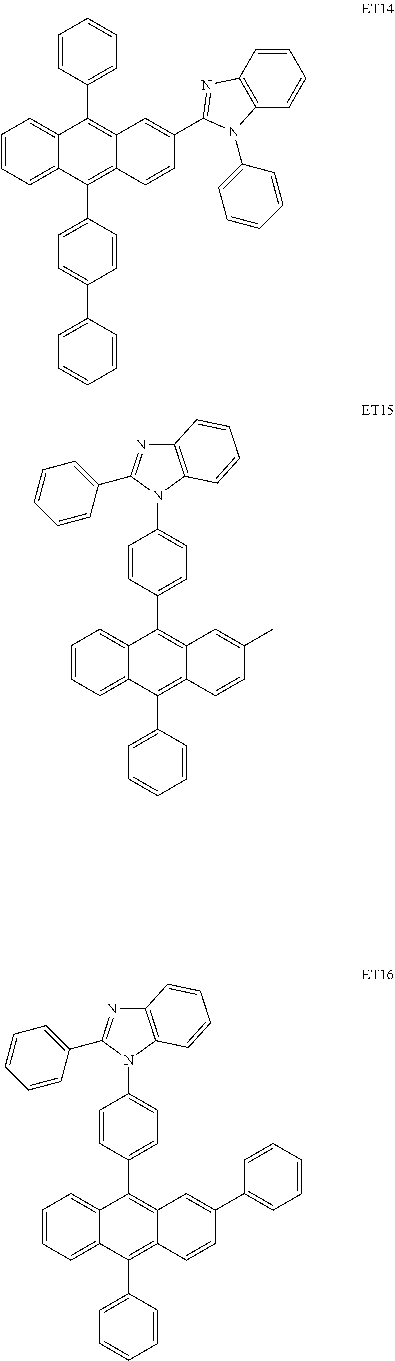 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

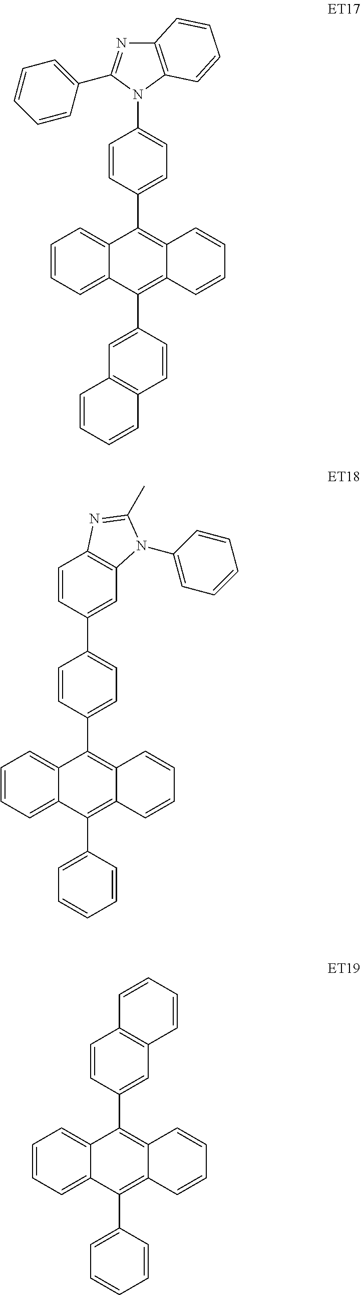

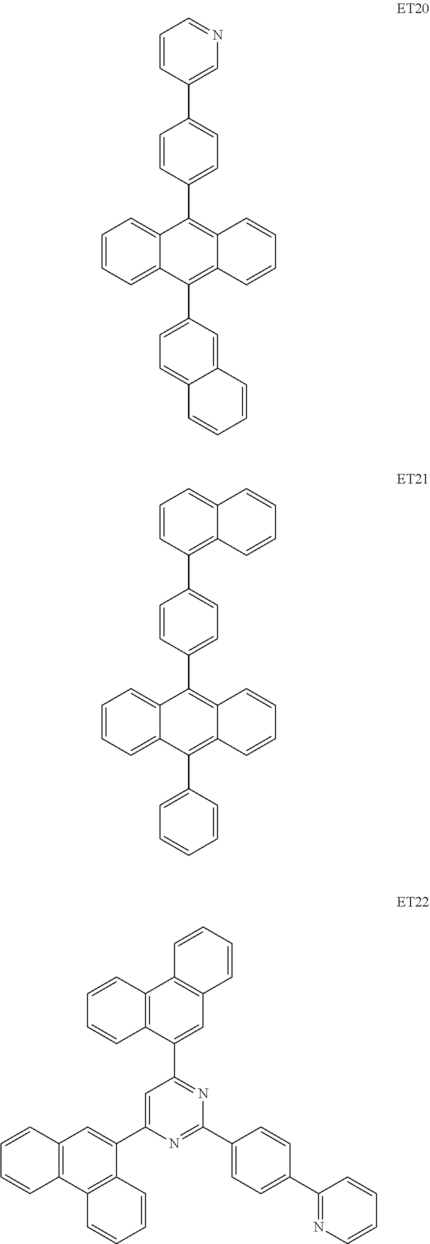

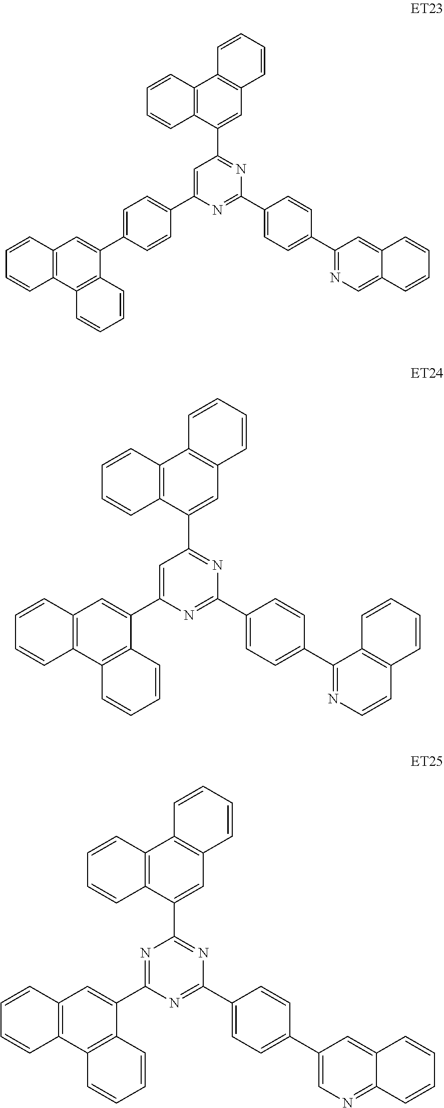 [SMILES: c1ccc2cc(-c3ccc(-c4nc(-c5ccc(-c6cc7ccccc7c7ccccc67)cc5)cc(-c5cc6ccccc6c6ccccc56)n4)cc3)ncc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

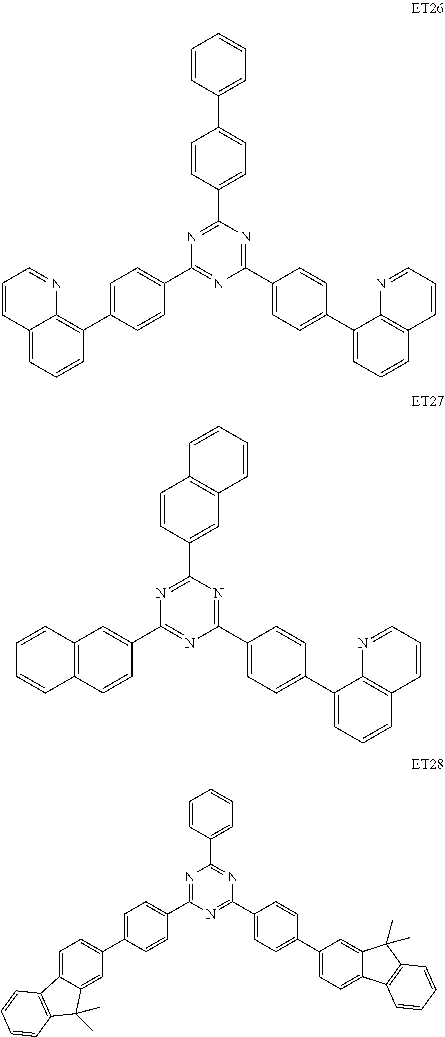 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

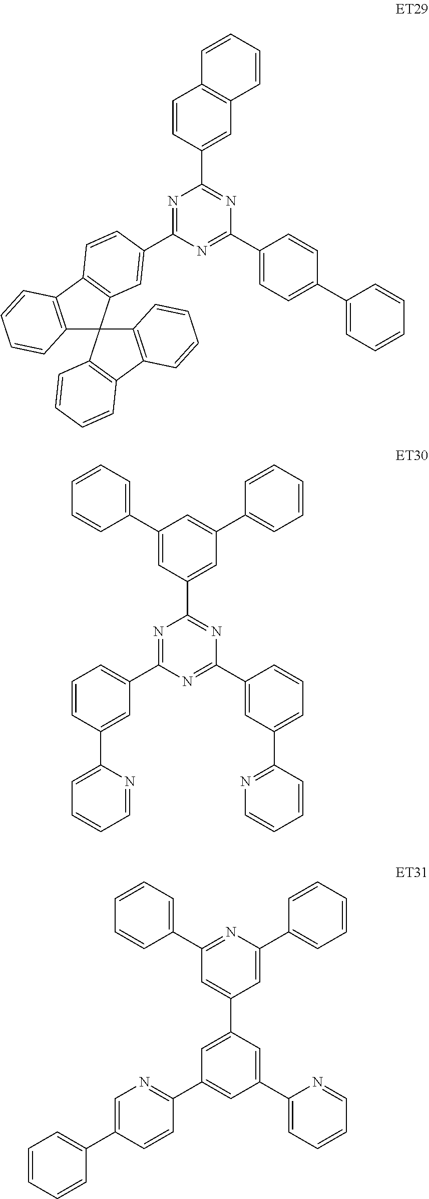

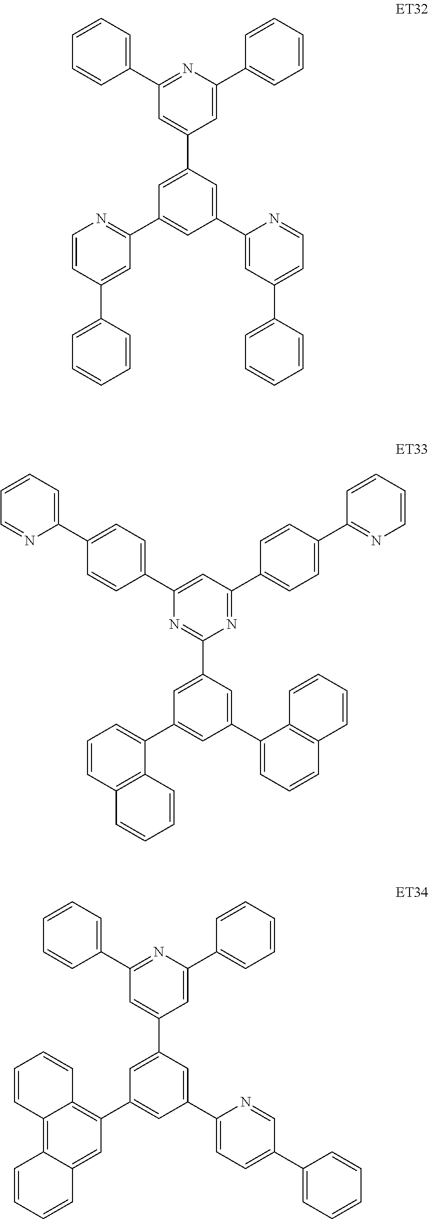 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

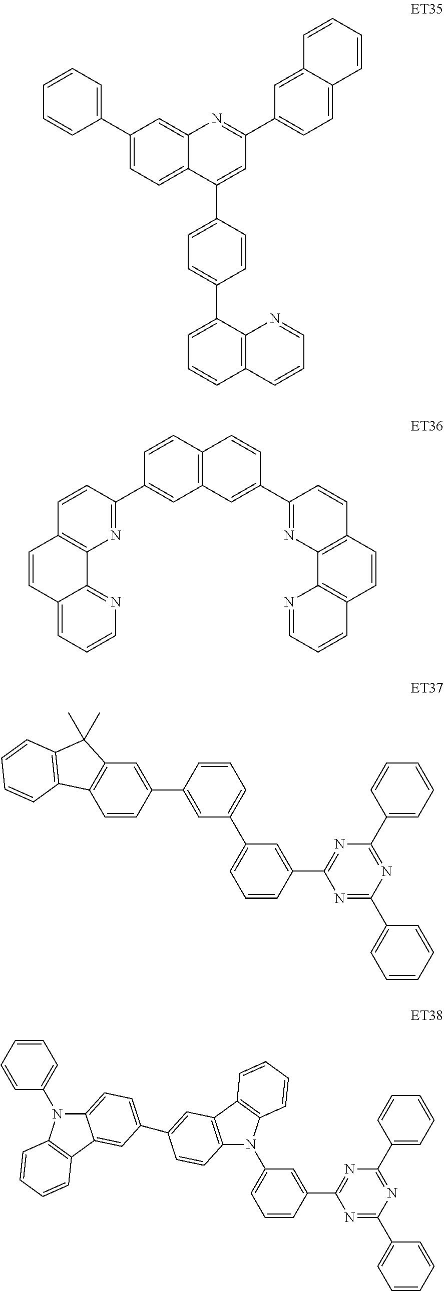 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

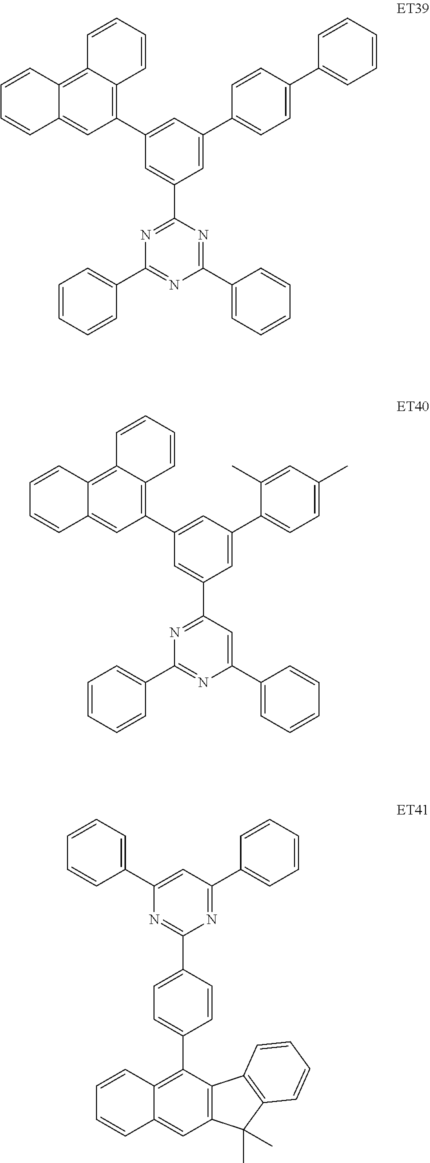 [SMILES: c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1]

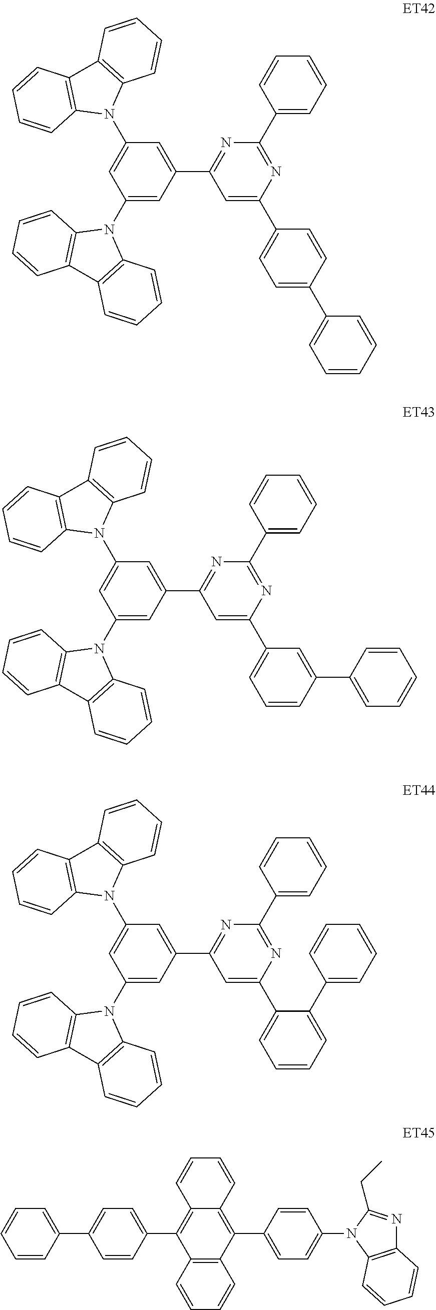 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

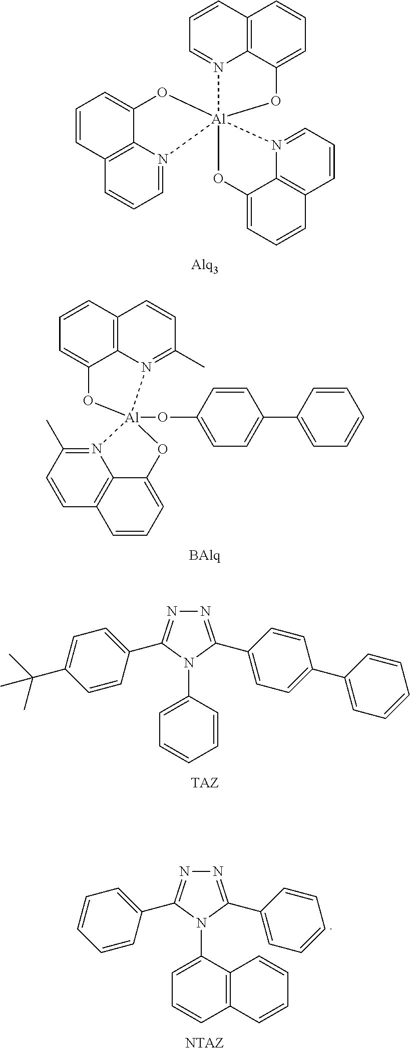

A thickness of the electron transport region 140 may be in a range of about 100 Å to about 5,000 Å, for example, about 160 Å to about 4,000 Å. When the electron transport region 140 includes a buffer layer, a hole blocking layer, an electron control layer, an electron transport layer, or any combination thereof, a thickness of the buffer layer, the hole blocking layer, or the electron control layer may be in a range of about 20 Å to about 1,000 Å, for example, about 30 Å to about 300 Å, and a thickness of the electron transport layer may be in a range of about 100 Å to about 1,000 Å, for example, about 150 Å to about 500 Å. When the thicknesses of the buffer layer, the hole blocking layer, the electron control layer, the electron transport layer, and/or the electron transport region 140 are within the ranges described, satisfactory electron transporting characteristics may be obtained without a substantial increase in driving voltage.

The electron transport region 140 (e.g., the electron transport layer in the electron transport region 140) may further include, in addition to the materials described herein, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the alkaline earth-metal complex may include hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, phenanthroline, cyclopentadiene, or any combination thereof.

For example, the metal-containing material may include a L₁ complex. The Li complex may include, for example, Compound ET-D1 (LiQ) or ET-D2:

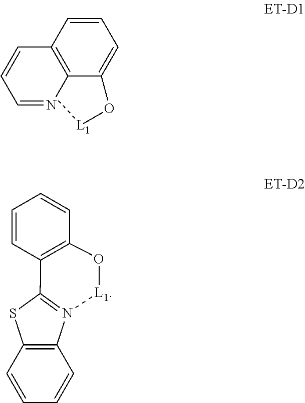

The electron transport region 140 may include an electron injection layer that facilitates the injection of electrons from the second electrode 150. The electron injection layer may directly contact the second electrode 150, but embodiments are not limited thereto.

The electron injection layer may have i) a single-layer structure including (e.g., consisting of) a single layer including (e.g., consisting of) a single material, ii) a single-layer structure including (e.g., consisting of) a single layer including multiple materials that are different from each other, or iii) a multi-layer structure including multiple layers including multiple materials that are different from each other.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may be oxides, halides (e.g., fluorides, chlorides, bromides, iodides, and/or the like), or tellurides of the alkali metal, the alkaline earth metal, and the rare earth metal, or any combination thereof.

The alkali metal-containing compound may include: an alkali metal oxide, such as Li₂O, Cs₂O, K₂O, and/or the like; alkali metal halides, such as LiF, NaF, CsF, KF, LiI, NaI, CsI, KI, and/or the like; or any combination thereof. The alkaline earth metal-containing compound may include an alkaline earth metal compound, such as BaO, SrO, CaO, BaₓSr₁₋ₓO (wherein x is a real number satisfying 0<x<1), BaₓCa₁₋ₓO (wherein x is a real number satisfying 0<x<1), and/or the like. The rare earth metal-containing compound may include YbF₃, ScF₃, Sc₂O₃, Y₂O₃, Ce₂₀₃, GdF₃, TbF₃, YbI₃, ScI₃, TbI₃, or any combination thereof. In one or more embodiments, the rare earth metal-containing compound may include lanthanide metal telluride. Examples of the lanthanide metal telluride are LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and/or the like.

The alkali metal complex, the alkaline earth-metal complex, and the rare earth metal complex may include i) at least one selected from among ions of the alkali metal, the alkaline earth metal, and the rare earth metal and ii) a ligand bonded to the metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

In one or more embodiments, the electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described herein. In one or more embodiments, the electron injection layer may further include an organic material (e.g., a compound represented by Formula 601).

In one or more embodiments, the electron injection layer may include (e.g., consist of) i) an alkali metal-containing compound (e.g., alkali metal halide); or ii) a) an alkali metal-containing compound (e.g., alkali metal halide), and b) an alkali metal, an alkaline earth metal, a rare earth metal, or any combination thereof. For example, the electron injection layer may be a KI:Yb co-deposited layer, an RbI:Yb co-deposited layer, a LiF:Yb co-deposited layer, and/or the like.

When the electron injection layer further includes an organic material, then an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof may be uniformly or non-uniformly dispersed in a matrix including the organic material.

A thickness of the electron injection layer may be in a range of about 1 Å to about 100 Å, and, for example, about 3 Å to about 90 Å. When the thickness of the electron injection layer is within the ranges described, satisfactory electron injection characteristics may be obtained without a substantial increase in driving voltage.

### Second Electrode 150

The second electrode 150 may be arranged on the electron transport region 140. The second electrode 150 may be a cathode, which is an electron injection electrode, and as a material for forming the second electrode 150, a metal, an alloy, an electrically conductive compound, or any combination thereof, each having a low-work function, may be utilized.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layer structure or a multi-layer structure including multiple layers.

### Optoelectronic Devices 30, 31, 32, 33, 34, and 35

An aspect of the present disclosure provides an optoelectronic device 30 including:
a first electrode 110;
a second electrode 150 facing the first electrode 110; and
an optical activation layer 135 between the first electrode 110 and the second electrode 150,
wherein the optical activation layer 135 includes the first compound represented by Formula 1, the second compound represented by Formula 2, and the third compound represented by Formula 3.

In one or more embodiments, the optical activation layer 135 may be formed by vacuum-depositing the herein-described composition including the first compound represented by Formula 1, the second compound represented by Formula 2, and the third compound represented by Formula 3, but embodiments are not limited thereto. For example, the optical activation layer 135 may be easily manufactured in one chamber process.

In one or more embodiments, the optoelectronic device 30 may further include a hole transport region 120 between the first electrode 110 and the optical activation layer 135, and an electron transport region 140 between the optical activation layer 135 and the second electrode 150. The hole transport region 120 may include a hole injection layer, a hole transport layer, an emission auxiliary layer, an electron blocking layer, or any combination thereof. The electron transport region 140 may include a buffer layer, a hole blocking layer, an electron control layer, an electron transport layer, an electron injection layer, or any combination thereof.

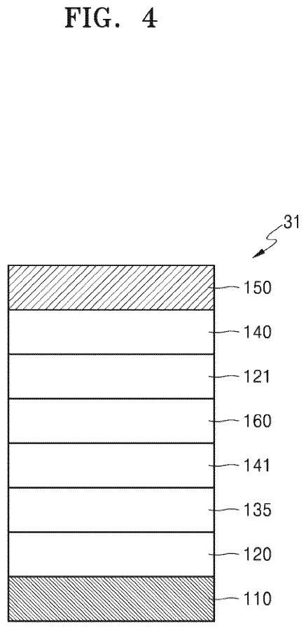

FIG. 4 is a diagram illustrating an optoelectronic device 31 according to another embodiment.

Referring to FIG. 4, the optoelectronic device 31 may further include a charge generation layer 160 between the first electrode 110 and the second electrode 150. The charge generation layer 160 may extend as one body to be included in the light-emitting device 10 (e.g., as described in FIGS. 1 and 2).

The optoelectronic device 31 may further include an electron transport layer 141 between the hole transport region 120 and the charge generation layer 160, and the optoelectronic device 31 may further include a hole transport layer 121 between the charge generation layer 160 and the electron transport region 140, but embodiments are not limited thereto. The electron transport layer 141 may have the characteristics (material, thickness, and/or the like) of the electron transport layer described herein in the description of the electron transport region 140. The hole transport layer 121 may have the characteristics (material, thickness, and/or the like) of the hole transport layer described herein in the description of the hole transport region 120. Each of the electron transport layer 141 and the hole transport layer 121 may extend as one body to be included in the light-emitting device 10 (e.g., as described in FIGS. 1 and 2).

For example, the optoelectronic device 31 may have a stacked structure in which the first electrode 110, the hole transport region 120, the optical activation layer 135, the electron transport layer 141, the charge generation layer 160, the hole transport layer 121, the electron transport region 140, and the second electrode 150 are arranged in the stated order.

The optical activation layer 135 may be a single layer including all of the first compound, the second compound, and the third compound.

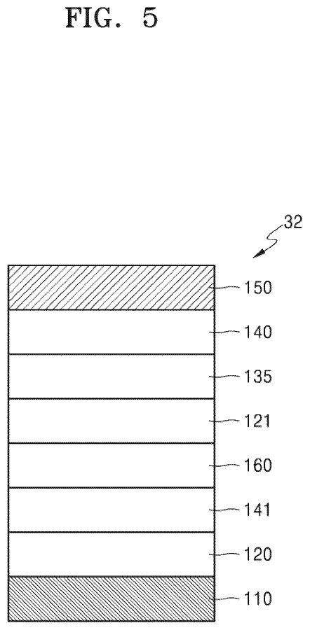

FIG. 5 is a diagram illustrating an optoelectronic device 32 according to another embodiment.

The optoelectronic device 32 of FIG. 5 is substantially the same as the optoelectronic device 31 of FIG. 4 except for the position of the optical activation layer 135, and thus, descriptions of the other components will not be provided.

Referring to FIG. 5, the optoelectronic device 32 may have a stacked structure in which the first electrode 110, the hole transport region 120, the electron transport layer 141, the charge generation layer 160, the hole transport layer 121, the optical activation layer 135, the electron transport region 140, and the second electrode 150 are arranged in the stated order.

The optical activation layer 135 may be a single layer including all (e.g., each) of the first compound, the second compound, and the third compound.

Referring to FIGS. 3 to 5, the optical activation layer 135 may be a single layer, and may include a mixture of the first to third compounds. For example, the first compound, the second compound, and the third compound may be present in the optical activation layer 135 as a mixture.

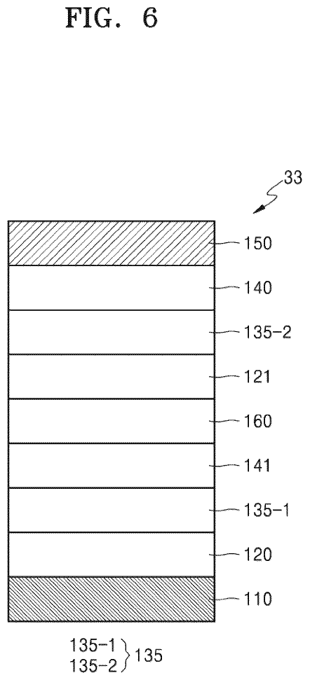

FIG. 6 is a diagram illustrating an optoelectronic device 33 according to another embodiment.

The optoelectronic device 33 of FIG. 6 is substantially the same as the optoelectronic device 31 of FIG. 4 except for the number of optical activation layers 135, and thus, descriptions of the other components will not be provided.

Referring to FIG. 6, the optical activation layer 135 may include a first optical activation layer 135-1 between the first electrode 110 and the charge generation layer 160, and a second optical activation layer 135-2 between the charge generation layer 160 and the second electrode 150. For example, the optoelectronic device 33 may include two or more optical activation layers.

For example, the optoelectronic device 33 may have a stacked structure in which the first electrode 110, the hole transport region 120, the first optical activation layer 135-1, the electron transport layer 141, the charge generation layer 160, the hole transport layer 121, the second optical activation layer 135-2, the electron transport region 140, and the second electrode 150 are arranged in the stated order.

In one or more embodiments, each of the first optical activation layer 135-1 and the second optical activation layer 135-2 may include at least two of (e.g., at least two selected from among) the first to third compounds. Each of the first optical activation layer 135-1 and the second optical activation layer 135-2 may include the third compound.

In one or more embodiments, the first optical activation layer 135-1 may include the first compound and the third compound, and the second optical activation layer 135-2 may include the second compound and the third compound. For example, the first optical activation layer 135-1 may not include (e.g., may exclude) the second compound and may include (e.g., consist of) the first compound and the third compound, and the second optical activation layer 135-2 may not include (e.g., may exclude) the first compound and may include (e.g., consist of) the second compound and the third compound.

In one or more embodiments, the first optical activation layer 135-1 may include the second compound and the third compound, and the second optical activation layer 135-2 may include the first compound and the third compound. For example, the first optical activation layer 135-1 may not include (e.g., may exclude) the first compound and may include (e.g., consist of) the second compound and the third compound, and the second optical activation layer 135-2 may not include (e.g., may exclude) the second compound and may include (e.g., consist of) the first compound and the third compound.

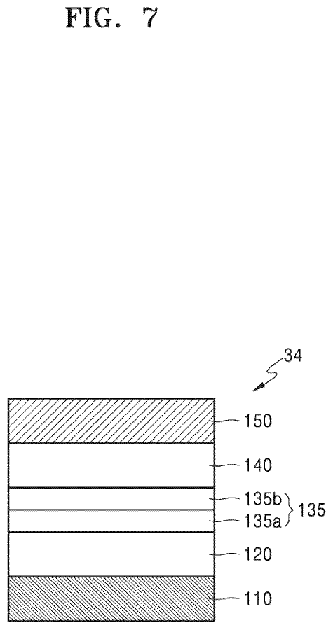

FIG. 7 is a diagram illustrating an optoelectronic device 34 according to another embodiment.

The optoelectronic device 34 of FIG. 7 is substantially the same as the optoelectronic device 30 of FIG. 3 except for the structure of the optical activation layer 135, and thus, descriptions of the other components will not be provided.

Referring to FIG. 7, the optical activation layer 135 may include a first layer 135a adjacent to the hole transport region 120 and a second layer 135b adjacent to the electron transport region 140. For example, the optical activation layer 135 may have a multi-layer structure divided into the first layer 135a and the second layer 135b.

In one or more embodiments, the first layer 135a may be an optical activation layer that includes the first compound and the third compound and absorbs green light, and the second layer 135b may be an optical activation layer that includes the second compound and the third compound and absorbs red light, but embodiments are not limited thereto. For example, the first layer 135a may not include (e.g., may exclude) the second compound and may include (e.g., consist of) the first compound and the third compound, and the second layer 135b may not include (e.g., may exclude) the first compound and may include (e.g., consist of) the second compound and the third compound.

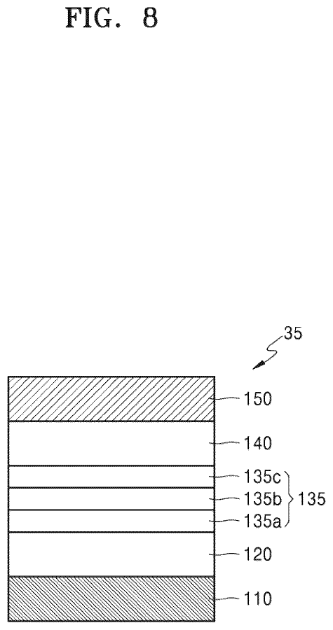

FIG. 8 is a diagram illustrating an optoelectronic device 35 according to another embodiment.

The optoelectronic device 35 of FIG. 8 is substantially the same as the optoelectronic device 34 of FIG. 7 except for the structure of the optical activation layer 135, and thus, descriptions of the other components will not be provided.

Referring to FIG. 8, the optical activation layer 135 may include a first layer 135a adjacent to the hole transport region 120, a third layer 135c adjacent to the electron transport region 140, and a second layer 135b between the first layer 135a and the third layer 135c. For example, the optical activation layer 135 may have a multi-layer structure divided into the first layer 135a, the second layer 135b, and the third layer 135c.

In one or more embodiments, the first layer 135a may include the first compound, the second layer 135b may include the second compound, and the third layer 135c may include the third compound, but embodiments are not limited thereto. For example, the first layer 135a may not include (e.g., may exclude) the second compound and the third compound, and may be a single layer including (e.g., consisting of) the first compound. The second layer 135b may not include (e.g., may exclude) the first compound and the third compound, and may be a single layer including (e.g., consisting of) the second compound. The third layer 135c may not include (e.g., may exclude) the first compound and the second compound, and may be a single layer including (e.g., consisting of) the third compound.

Referring to FIGS. 3 to 8, the optical activation layer 135 may include all (e.g., each) of the first compound, the second compound, and the third compound. As a result, the optical activation layer 135 may have excellent or suitable external quantum efficiency for green light, and may concurrently (e.g., simultaneously) have excellent or suitable external quantum efficiency for red light. Because the optical activation layer 135 has excellent or suitable external quantum efficiency for green light, the optoelectronic device 30, 31, 32, 33, 34, or 35 may easily and accurately recognize fingerprints of a user of an electronic apparatus. Red light has a longer wavelength than green light, and thus may penetrate deeper into the skin of a user and accurately recognize blood vessels. For example, because the optical activation layer 135 has excellent or suitable external quantum efficiency for red light, the optoelectronic device 30, 31, 32, 33, 34, or 35 may easily and accurately recognize the blood pressure of a user of an electronic apparatus.

### Electronic Equipment

The optoelectronic device 30, 31, 32, 33, 34, or 35 may be included in one or more suitable electronic equipment(s).

For example, the electronic equipment including the optoelectronic device 30, 31, 32, 33, 34, or 35 may be at least one selected from among a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, a signboard, a vehicle sensor, a household sensor, and a solar cell, and/or one or more combinations thereof.

Because the optoelectronic device 30, 31, 32, 33, 34, or 35 has excellent or suitable optoelectronic characteristics for green light and red light, the electronic equipment may function as an optical sensor, such as a fingerprint recognition sensor, a blood pressure recognition sensor, and/or the like.

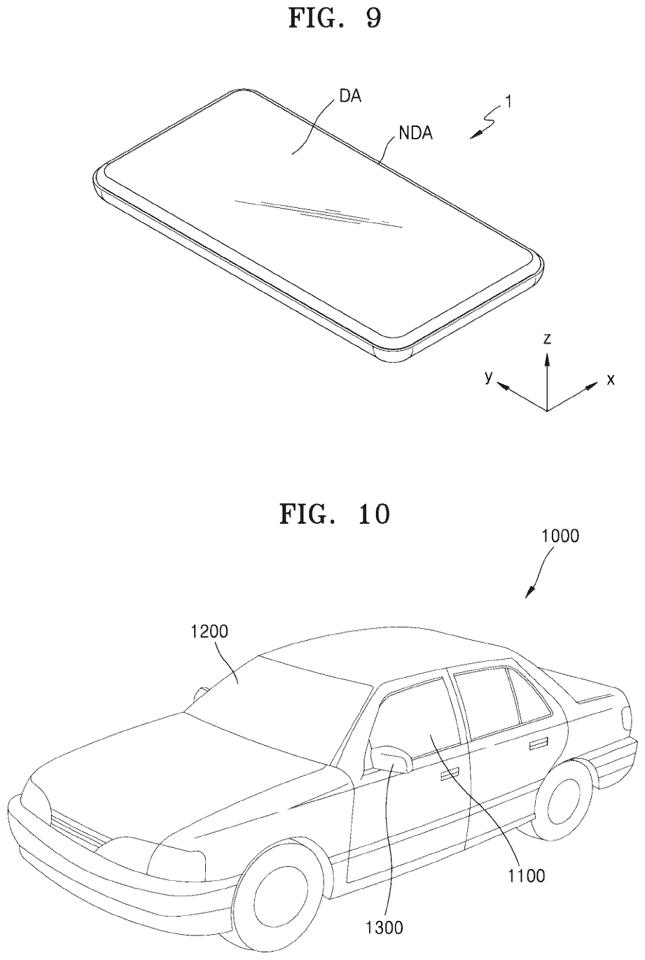

### Description of FIG. 9

FIG. 9 is a perspective view schematically illustrating electronic equipment 1 including an optoelectronic device according to one or more embodiments. The electronic equipment 1 may be, as a device that displays a moving image or still image, a portable electronic equipment, such as a mobile phone, a smart phone, a tablet personal computer (PC), a mobile communication terminal, an electronic notebook, an electronic book, a portable multimedia player (PMP), a navigation, or a ultra-mobile PC (UMPC), as well as one or more suitable products, such as a television, a laptop, a monitor, a billboard, or an Internet of things (IoT). The electronic equipment 1 may be such a product described herein or a part thereof. In some embodiments, the electronic equipment 1 may be a wearable device, such as a smart watch, a watch phone, a glasses-type or kind display, or a head mounted display (HMD), or a part of the wearable device. However, embodiments are not limited thereto. For example, the electronic equipment 1 may include a dashboard of a vehicle, a center fascia of a vehicle, a center information display (CID) arranged on a dashboard of a vehicle, a room mirror display replacing a side mirror of a vehicle, an entertainment display for a rear seat of a vehicle or a display arranged on the back of a front seat, a head up display (HUD) installed in the front of a vehicle or projected on a front window glass, or a computer generated hologram augmented reality head up display (CGH AR HUD). FIG. 9 illustrates a case in which the electronic equipment 1 is a smart phone for convenience of explanation.

The electronic equipment 1 may include a display area DA and a non-display area NDA outside the display area DA. A display device may implement an image through an array of a plurality of pixels that are two-dimensionally arranged in the display area DA.

The non-display area NDA is an area that does not display an image, and may be around (e.g., entirely surround) the display area DA. On the non-display area NDA, a driver for providing electrical signals or power to display devices arranged on the display area DA may be arranged. On the non-display area NDA, a pad, which is an area to which an electronic element or a printed circuit board may be electrically connected, may be arranged.

In the electronic equipment 1, a length in the x-axis direction and a length in the y-axis direction may be different from each other. In one or more embodiments, as shown in FIG. 9, the length in the x-axis direction may be shorter than the length in the y-axis direction. In one or more embodiments, the length in the x-axis direction may be the same as the length in the y-axis direction. In one or more embodiments, the length in the x-axis direction may be longer than the length in the y-axis direction.

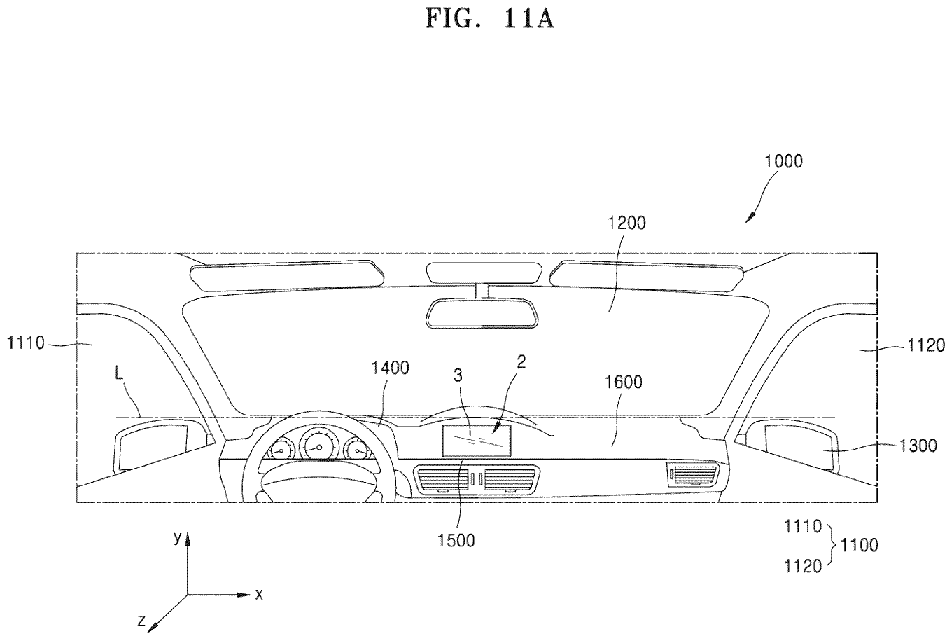

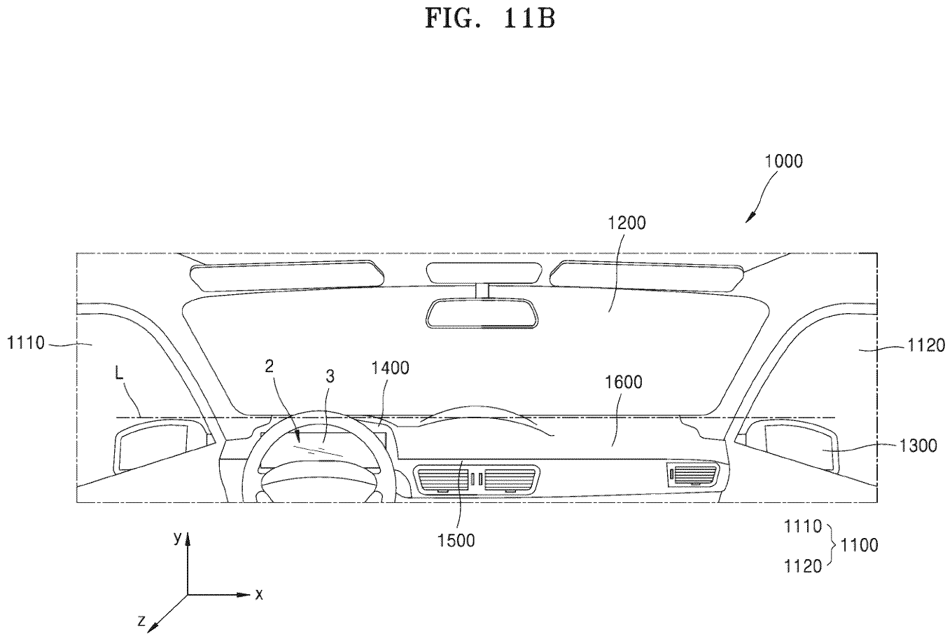

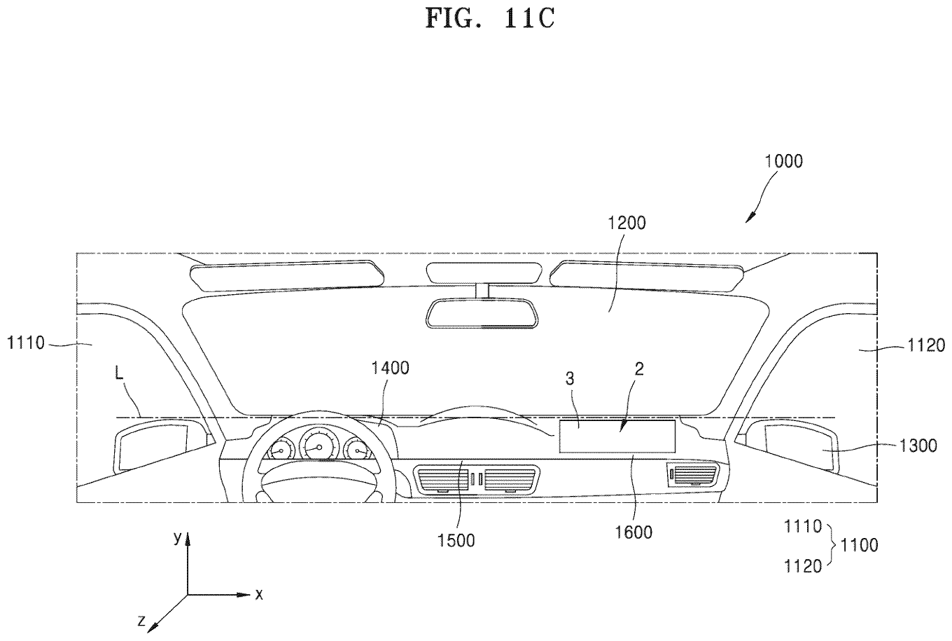

### Descriptions of FIGS. 10 and 11A to 11C

FIG. 10 is a diagram schematically illustrating the exterior of a vehicle 1000 as electronic equipment including an optoelectronic device according to one or more embodiments. FIGS. 11A to 11C are each a diagram schematically illustrating the interior of the vehicle 1000 according to one or more embodiments.

Referring to FIGS. 10, 11A, 11B, and 11C, the vehicle 1000 may refer to one or more suitable apparatuses for moving a subject to be transported, such as a human, an object, or an animal, from a departure point to a destination point. The vehicle 1000 may include a vehicle traveling on a road or a track, a vessel moving over the sea or river, an airplane flying in the sky utilizing the action of air, and/or the like.

The vehicle 1000 may travel on a road or a track. The vehicle 1000 may move in a set or predetermined direction according to rotation of at least one wheel. For example, the vehicle 1000 may include a three-wheeled or four-wheeled vehicle, a construction machine, a two-wheeled vehicle, a prime mover device, a bicycle, and a train running on a track.

The vehicle 1000 may include a body having an interior and an exterior, and a chassis in which mechanical apparatuses necessary for driving are installed as other parts except for the body. The exterior of the body may include a front panel, a bonnet, a roof panel, a rear panel, a trunk, a pillar provided at a boundary between doors, and/or the like. The chassis of the vehicle 1000 may include a power generating device, a power transmitting device, a driving device, a steering device, a braking device, a suspension device, a transmission device, a fuel device, front and rear wheels, left and right wheels, and/or the like.

The vehicle 1000 may include a side window glass 1100, a front window glass 1200, a side mirror 1300, a cluster 1400, a center fascia 1500, a passenger seat dashboard 1600, and a display device 2.

The side window glass 1100 and the front window glass 1200 may be partitioned by a pillar arranged between the side window glass 1100 and the front window glass 1200.

The side window glass 1100 may be installed on the side of the vehicle 1000. In one or more embodiments, the side window glass 1100 may be installed on a door of the vehicle 1000. A plurality of side window glasses 1100 may be provided and may face each other. In one or more embodiments, the side window glass 1100 may include a first side window glass 1110 and a second side window glass 1120. In one or more embodiments, the first side window glass 1110 may be arranged adjacent to the cluster 1400. The second side window glass 1120 may be arranged adjacent to the passenger seat dashboard 1600.

In one or more embodiments, the side window glasses 1100 may be spaced and/or apart from each other in the x-direction or the −x-direction. For example, the first side window glass 1110 and the second side window glass 1120 may be spaced and/or apart from each other in the x-direction or the −x-direction. In other words, an imaginary straight line L connecting the side window glasses 1100 may extend in the x-direction or the −x-direction. For example, the imaginary straight line L connecting the first side window glass 1110 and the second side window glass 1120 to each other may extend in the x-direction or the −x-direction.

The front window glass 1200 may be installed in the front of the vehicle 1000. The front window glass 1200 may be arranged between the side window glasses 1100 facing each other.

The side mirror 1300 may provide a rear view of the vehicle 1000. The side mirror 1300 may be installed on the exterior of the vehicle body. In one or more embodiments, a plurality of side mirrors 1300 may be provided. Any one of the plurality of side mirrors 1300 may be arranged outside the first side window glass 1110. The other one of the plurality of side mirrors 1300 may be arranged outside the second side window glass 1120.

The cluster 1400 may be arranged in front of the steering wheel. The cluster 1400 may include a tachometer, a speedometer, a coolant thermometer, a fuel gauge turn indicator, a high beam indicator, a warning lamp, a seat belt warning lamp, an odometer, a tachograph, an automatic shift selector indicator lamp, a door open warning lamp, an engine oil warning lamp, and/or a low fuel warning light.

The center fascia 1500 may include a control panel on which a plurality of buttons for adjusting an audio device, an air conditioning device, and a heater of a seat are arranged. The center fascia 1500 may be arranged on one side of the cluster 1400.

The passenger seat dashboard 1600 may be spaced and/or apart from the cluster 1400 with the center fascia 1500 arranged therebetween. In one or more embodiments, the cluster 1400 may be arranged to correspond to a driver seat, and the passenger seat dashboard 1600 may be arranged to correspond to a passenger seat. In one or more embodiments, the cluster 1400 may be adjacent to the first side window glass 1110, and the passenger seat dashboard 1600 may be adjacent to the second side window glass 1120.

In one or more embodiments, the display device 2 may include a display panel 3, and the display panel 3 may display an image. The display device 2 may be arranged inside the vehicle 1000. In one or more embodiments, the display device 2 may be arranged between the side window glasses 1100 facing each other. The display device 2 may be arranged on at least one of the cluster 1400, the center fascia 1500, and the passenger seat dashboard 1600.

The display device 2 may include an organic light-emitting display device, an inorganic light-emitting display device, a quantum dot display device, and/or the like. Hereinafter, as the display device 2 according to one or more embodiments of the disclosure, an organic light-emitting display device including the light-emitting device according to the disclosure will be described as an example, but one or more suitable types (kinds) of display devices as described herein may be utilized in embodiments of the disclosure.

Referring to FIG. 11A, the display device 2 may be arranged on the center fascia 1500. In one or more embodiments, the display device 2 may display navigation information. In one or more embodiments, the display device 2 may display audio, video, or information regarding vehicle settings.

Referring to FIG. 11B, the display device 2 may be arranged on the cluster 1400. When the display device 2 is arranged on the cluster 1400, the cluster 1400 may display driving information and/or the like through the display device 2. For example, the cluster 1400 may be implemented digitally. The digital cluster 1400 may display vehicle information and driving information as images. For example, a needle and a gauge of a tachometer and one or more suitable warning light icons may be displayed by a digital signal.

Referring to FIG. 11C, the display device 2 may be arranged on the passenger seat dashboard 1600. The display device 2 may be embedded in the passenger seat dashboard 1600 or arranged on the passenger seat dashboard 1600. In one or more embodiments, the display device 2 arranged on the passenger seat dashboard 1600 may display an image related to information displayed on the cluster 1400 and/or information displayed on the center fascia 1500. In one or more embodiments, the display device 2 arranged on the passenger seat dashboard 1600 may display information different from information displayed on the cluster 1400 and/or information displayed on the center fascia 1500.

### Manufacturing Method

The layers constituting the hole transport region, the emission layer, the optical activation layer (the first layer, the second layer, the third layer, the first optical activation layer, and the second optical activation layer) and/or the layers constituting the electron transport region may be formed in a certain region by utilizing one or more suitable methods such as vacuum deposition, spin coating, casting, Langmuir-Blodgett (LB) deposition, ink-jet printing, laser-printing, laser-induced thermal imaging (LITI), and/or the like.

When the layers constituting the hole transport region, the emission layer, the optical activation layer (the first layer, the second layer, the third layer, the first optical activation layer, and the second optical activation layer) and/or the layers constituting the electron transport region are formed by vacuum deposition, the deposition may be performed at a deposition temperature in a range of about 100° C. to about 500° C., at a vacuum degree in a range of about 10⁻⁸ torr to about 10⁻³ torr, and at a deposition speed in a range of about 0.01 angstrom per second (Å/sec) to about 100 Å/sec, depending on a material to be included in a layer to be formed and the structure of a layer to be formed.

### Definition of Terms

The term “C₃-C₆₀ carbocyclic group” as utilized herein refers to a cyclic group consisting of carbon only as a ring-forming atom and having 3 to 60 carbon atoms. The term “C₁-C₆₀ heterocyclic group” as utilized herein refers to a cyclic group that has 1 to 60 carbon atoms and further has, in addition to carbon, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. For example, the number of ring-forming atoms of the C₁-C₆₀ heterocyclic group may be from 3 to 61.

The “cyclic group” as utilized herein may include both (e.g., simultaneously) the C₃-C₆₀ carbocyclic group and the C₁-C₆₀ heterocyclic group.

The term “π electron-rich C₃-C₆₀ cyclic group” as utilized herein refers to a cyclic group that has 3 to 60 carbon atoms and does not include *—N═*′ as a ring-forming moiety.

The term “π electron-deficient nitrogen-containing C₁-C₆₀ cyclic group” as utilized herein refers to a heterocyclic group that has 1 to 60 carbon atoms and includes *—N═*′ as a ring-forming moiety.

For example,
the C₃-C₆₀ carbocyclic group may be i) Group T1 or ii) a condensed cyclic group in which two or more of Group T1 are condensed with each other (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) Group T2, ii) a condensed cyclic group in which two or more of Group T2 are condensed with each other, or iii) a condensed cyclic group in which at least one Group T2 and at least one Group T1 are condensed with each other (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
the π electron-rich C₃-C₆₀ cyclic group may be i) Group T1, ii) a condensed cyclic group in which two or more of Group T1 are condensed with each other, iii) Group T3, iv) a condensed cyclic group in which two or more of Group T3 are condensed with each other, or v) a condensed cyclic group in which at least one Group T3 and at least one Group T1 are condensed with each other (e.g., the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like), and
the π electron-deficient nitrogen-containing C₁-C₆₀ cyclic group may be i) Group T4, ii) a condensed cyclic group in which two or more of Group T4 are condensed with each other, iii) a condensed cyclic group in which at least one Group T4 and at least one Group T1 are condensed with each other, iv) a condensed cyclic group in which at least one Group T4 and at least one Group T3 are condensed with each other, or v) a condensed cyclic group in which at least one Group T4, at least one Group T1, and at least one Group T3 are condensed with one another (e.g., a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like).

Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group.

Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group.

Group T3 may be a furan group, a thiophene group, a 1H-pyrrole group, a silole group, or a borole group.

Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group, the C₃-C₆₀ carbocyclic group, the C₁-C₆₀ heterocyclic group, the π electron-rich C₃-C₆₀ cyclic group, or the π electron-deficient nitrogen-containing C₁-C₆₀ cyclic group” as utilized herein refer to a group condensed to any cyclic group, a monovalent group, or a polyvalent group (e.g., a divalent group, a trivalent group, a tetravalent group, and/or the like) according to the structure of a formula for which the corresponding term is utilized.

For example, the “benzene group” may be a benzo group, a phenyl group, a phenylene group, and/or the like, which may be easily understood by one of ordinary skill in the art according to the structure of a formula including the “benzene group.”

Depending on context, a divalent group may refer or be a polyvalent group (e.g., trivalent, tetravalent, etc., and not just divalent) per, e.g., the structure of a formula in connection with which of the terms are utilized.

Examples of the monovalent C₃-C₆₀ carbocyclic group and monovalent C₁-C₆₀ heterocyclic group are a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

Examples of the divalent C₃-C₆₀ carbocyclic group and the divalent C₁-C₆₀ heterocyclic group are a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as utilized herein refers to a linear or branched aliphatic hydrocarbon monovalent group that has 1 to 60 carbon atoms, and examples thereof are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and/or the like.

The term “C₁-C₆₀ alkylene group” as utilized herein refers to a divalent group having the same structure as the C₁-C₆₀ alkyl group.

The term “C₂-C₆₀ alkenyl group” as utilized herein refers to a monovalent hydrocarbon group having at least one carbon-carbon double bond in the middle or at the terminus of the C₂-C₆₀ alkyl group, and examples thereof are an ethenyl group, a propenyl group, a butenyl group, and/or the like.

The term “C₂-C₆₀ alkenylene group” as utilized herein refers to a divalent group having the same structure as the C₂-C₆₀ alkenyl group.

The term “C₂-C₆₀ alkynyl group” as utilized herein refers to a monovalent hydrocarbon group having at least one carbon-carbon triple bond in the middle or at the terminus of the C₂-C₆₀ alkyl group, and examples thereof are an ethynyl group, a propynyl group, and/or the like.

The term “C₂-C₆₀ alkynylene group” as utilized herein refers to a divalent group having the same structure as the C₂-C₆₀ alkynyl group.

The term “C₁-C₆₀ alkoxy group” as utilized herein refers to a monovalent group represented by —OA₁₀₁ (wherein A₁₀₁ is the C₁-C₆₀ alkyl group), and examples thereof are a methoxy group, an ethoxy group, an isopropyloxy group, and/or the like.

The term “C₃-C₁₀ cycloalkyl group” as utilized herein refers to a monovalent saturated hydrocarbon cyclic group having 3 to 10 carbon atoms, and examples thereof are a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and/or the like.

The term “C₃-C₁₀ cycloalkylene group” as utilized herein refers to a divalent group having the same structure as the C₃-C₁₀ cycloalkyl group.

The term “C₁-C₁₀ heterocycloalkyl group” as utilized herein refers to a monovalent cyclic group of 1 to 10 carbon atoms, further including, in addition to carbon atoms, at least one heteroatom, as ring-forming atoms, and examples thereof are a 1,2,3,4-oxatriazolidinyl group, a tetrahydrofuranyl group, a tetrahydrothiophenyl group, and/or the like.

The term “C₁-C₁₀ heterocycloalkylene group” as utilized herein refers to a divalent group having the same structure as the C₁-C₁₀ heterocycloalkyl group.

The term “C₃-C₁₀ cycloalkenyl group” as utilized herein refers to a monovalent cyclic group that has 3 to 10 carbon atoms and at least one carbon-carbon double bond in the ring thereof and no aromaticity, and examples thereof are a cyclopentenyl group, a cyclohexenyl group, a cycloheptenyl group, and/or the like.

The term “C₃-C₁₀ cycloalkenylene group” as utilized herein refers to a divalent group having the same structure as the C₃-C₁₀ cycloalkenyl group.

The term “C₁-C₁₀ heterocycloalkenyl group” as utilized herein refers to a monovalent cyclic group of 1 to 10 carbon atoms, further including, in addition to carbon atoms, at least one heteroatom, as ring-forming atoms, and having at least one carbon-carbon double bond in the cyclic structure thereof. Examples of the C₁-C₁₀ heterocycloalkenyl group are a 4,5-dihydro-1,2,3,4-oxatriazolyl group, a 2,3-dihydrofuranyl group, a 2,3-dihydrothiophenyl group, and/or the like.

The term “C₁-C₁₀ heterocycloalkenylene group” as utilized herein refers to a divalent group having the same structure as the C₁-C₁₀ heterocycloalkenyl group.

The term “C₆-C₆₀ aryl group” as utilized herein refers to a monovalent group having a carbocyclic aromatic system of 6 to 60 carbon atoms.

The term “C₆-C₆₀ arylene group” as utilized herein refers to a divalent group having a carbocyclic aromatic system of 6 to 60 carbon atoms.

Examples of the C₆-C₆₀ aryl group are a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and/or the like.

When the C₆-C₆₀ aryl group and the C₆-C₆₀ arylene group each include two or more rings, the rings may be condensed with each other.

The term “C₁-C₆₀ heteroaryl group” as utilized herein refers to a monovalent group having a heterocyclic aromatic system of 1 to 60 carbon atoms, further including, in addition to carbon atoms, at least one heteroatom, as ring-forming atoms.

The term “C₁-C₆₀ heteroarylene group” as utilized herein refers to a divalent group having a heterocyclic aromatic system of 1 to 60 carbon atoms, further including, in addition to carbon atoms, at least one heteroatom, as ring-forming atoms.

Examples of the C₁-C₆₀ heteroaryl group are a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and/or the like.

When the C₁-C₆₀ heteroaryl group and the C₁-C₆₀ heteroarylene group each include two or more rings, the rings may be condensed with each other.

The term “monovalent non-aromatic condensed polycyclic group” as utilized herein refers to a monovalent group (e.g., having 8 to 60 carbon atoms) having two or more rings condensed to each other, only carbon atoms as ring-forming atoms, and no aromaticity in its entire molecular structure. Examples of the monovalent non-aromatic condensed polycyclic group are an indenyl group, a fluorenyl group, a spiro-bifluorenyl group, a benzofluorenyl group, an indenophenanthrenyl group, an indeno anthracenyl group, and/or the like.

The term “divalent non-aromatic condensed polycyclic group” as utilized herein refers to a divalent group having the same structure as the monovalent non-aromatic condensed polycyclic group.

The term “monovalent non-aromatic condensed heteropolycyclic group” as utilized herein refers to a monovalent group (e.g., having 1 to 60 carbon atoms) having two or more rings condensed to each other, further including, in addition to carbon atoms, at least one heteroatom, as ring-forming atoms, and having non-aromaticity in its entire molecular structure. Examples of the monovalent non-aromatic condensed heteropolycyclic group are a pyrrolyl group, a thiophenyl group, a furanyl group, an indolyl group, a benzoindolyl group, a naphtho indolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and/or the like.

The term “divalent non-aromatic condensed heteropolycyclic group” as utilized herein refers to a divalent group having the same structure as the monovalent non-aromatic condensed heteropolycyclic group.

The term “C₆-C₆₀ aryloxy group” as utilized herein refers to —OA₁₀₂ (wherein A₁₀₂ is the C₆-C₆₀ aryl group).

The term “C₆-C₆₀ arylthio group” as utilized herein refers to —SA₁₀₃ (wherein A₁₀₃ is the C₇-C₆₀ aryl group).

The term “C₇-C₆₀ arylalkyl group” as utilized herein refers to —A₁₀₄A₁₀₅ (wherein A₁₀₄ is a C₁-C₅₄ alkylene group, and A₁₀₅ is a C₆-C₅₉ aryl group).

The term “C₂-C₆₀ heteroarylalkyl group” as utilized herein refers to —A₁₀₆A₁₀₇ (wherein A₁₀₆ is a C₁-C₅₉ alkylene group, and A₁₀₇ is a C₁-C₅₉ heteroaryl group).

The term “R₁₀ₐ” as utilized herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).
Q₁ to Q₃, Q₁₁ to Q₁₃, Q₂₁ to Q₂₃, and Q₃₁ to Q₃₃ utilized herein may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group.

The term “heteroatom” as utilized herein refers to any atom other than a carbon atom. Examples of the heteroatom are O, S, N, P, Si, B, Ge, Se, and any combination thereof.

The term “third-row transition metal” as utilized herein includes Hf, Ta, W, Re, Os, Ir, Pt, Au, and/or the like.

As utilized herein, “D” refers to deuterium, “Ph” refers to a phenyl group, “Me” refers to a methyl group, “Et” refers to an ethyl group, “tert-Bu” or “Bu^{t}” refers to a tert-butyl group, and “OMe” refers to a methoxy group.

The term “biphenyl group” as utilized herein refers to “a phenyl group substituted with a phenyl group.” In other words, the “biphenyl group” may be a substituted phenyl group having a C₆-C₆₀ aryl group as a substituent.

The term “terphenyl group” as utilized herein refers to “a phenyl group substituted with a biphenyl group.” In other words, the “terphenyl group” may be a substituted phenyl group having, as a substituent, a C₆-C₆₀ aryl group substituted with a C₆-C₆₀ aryl group.

* and *′ as utilized herein, unless defined otherwise, each refer to a binding site to a neighboring atom in a corresponding formula or moiety.

As utilized herein, the x-axis, y-axis, and z-axis are not limited to three axes in an orthogonal coordinate system, and may be interpreted in a broad sense including these axes. For example, the x-axis, y-axis, and z-axis may refer to those orthogonal to each other, or may refer to those in different directions that are not orthogonal to each other.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The optoelectronic device, the electronic apparatus, the light emitting device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the optoelectronic device and/or the electronic apparatus, may be formed on one integrated circuit (IC) chip or on separate IC chips. Further, the various components of the optoelectronic device and/or the electronic apparatus may be implemented on a flexible printed circuit film, a tape carrier package (TCP), a printed circuit board (PCB), or formed on one substrate. Further, the various components of the device and/or apparatus may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Hereinafter, compounds according to embodiments and optoelectronic devices according to embodiments will be described in more detail with reference to Synthesis Examples and Examples. The wording “B was utilized instead of A” utilized in describing Synthesis Examples refers to that an identical molar equivalent of B was utilized in place of A.

### EXAMPLES

### Example 1

As an anode, a glass substrate (product of Corning Inc.) with a 15 ohm per square centimeter (Ω/cm²) (1,200 angstrom (A)) ITO formed thereon was cut to a size of 50 millimeter (mm)×50 mm×0.7 mm, sonicated by utilizing isopropyl alcohol and pure water each for 5 minutes, washed by irradiation of ultraviolet rays and exposure of ozone thereto for 30 minutes, and then mounted on a vacuum deposition apparatus.

2-TNATA was vacuum-deposited on the anode to form a hole injection layer having a thickness of 600 Å. 4,4′-bis[N-(1-naphthyl)-N-phenylamino]biphenyl (hereinafter, referred to as NPB) was vacuum-deposited on the hole injection layer to form a hole transport layer having a thickness of 300 Å.

Compound A1 was deposited on the hole transport layer to form a first layer having a thickness of 100 Å, Compound B1 was deposited thereon to form a second layer having a thickness of 100 Å, and Compound C₁₀ was deposited thereon to form a third layer having a thickness of 340 Å, thereby forming an optical activation layer having a total thickness of 540 Å.

2,2′,2″-(1,3,5-Benzinetriyl)-tris(1-phenyl-1-H-benzimidazole) (TPBi) was vacuum-deposited on the optical activation layer to form a buffer layer having a thickness of 50 Å. Alq₃ was vacuum-deposited on the buffer layer to form an electron transport layer having a thickness of 300 Å. LiF was vacuum-deposited on the electron transport layer to form an electron injection layer having a thickness of 10 Å. A1 was deposited on the electron injection layer to form a cathode having a thickness of a 3,000 Å, thereby completing the manufacture of an optoelectronic device.

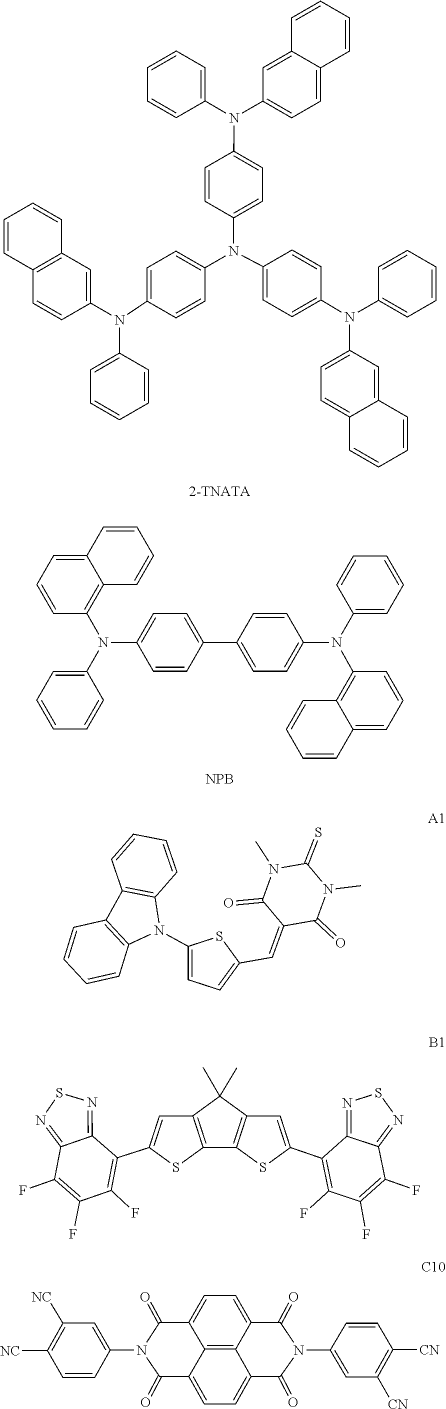 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1 ; "NPB" ; CN1C(=O)C(=Cc2ccc(-n3c4ccccc4c4ccccc43)s2)C(=O)N(C)C1=S ; CC1(C)c2cc(-c3c(F)c(F)c(F)c4nsnc34)sc2-c2sc(-c3c(F)c(F)c(F)c4nsnc34)cc21 ; N#Cc1ccc(N2C(=O)c3ccc4c5c(ccc(c35)C2=O)C(=O)N(c2ccc(C#N)c(C#N)c2)C4=O)cc1C#N]

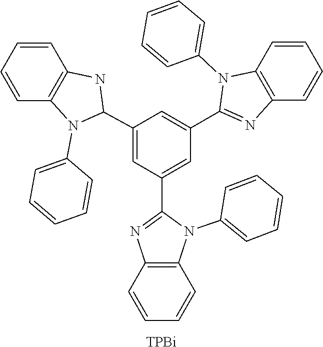

### Examples 2 to 13 and Comparative Examples 1 to 4

Optoelectronic devices were manufactured in substantially the same manner as in Example 1, except that, in forming an optical activation layer, the type or kind of each of a first compound, a second compound, and a third compound and the thickness of each of a first layer, a second layer, and a third layer were changed as shown in Table 1.

### Example 14

An optoelectronic device was manufactured in substantially the same manner as in Example 1, except that, in forming an optical activation layer, Compound A1, Compound B1, and Compound C₁₀ were mixed to form a single layer having a thickness of 540 Å.

### Evaluation Example 1

To evaluate the characteristics of the optoelectronic devices manufactured in Examples 1 to 14 and Comparative Examples 1 to 4, external quantum efficiency (EQE) was measured, and results thereof are shown in Table 1. The EQE refers to the ratio of electrical energy generated from irradiated optical energy.

Light (530 nm) irradiated to an optoelectronic device was measured by utilizing an EQE measurement device (K3100, McScience, Korea). A current generated during the light irradiation was measured by utilizing a current meter (Keithley, Tektronix, USA). The EQE was calculated by utilizing the irradiated light and the measured current.

TABLE 1

| | First | Second | Third | | |
|---|---|---|---|---|---|
| | compound | compound | compound | | |
| | (thickness | (thickness | (thickness | EQE (%) | EQE (%) |
| | of first | of second | of third | for green | for |
| | layer) | layer) | layer) | light | red light |
| Example 1 | A1 | B1 | C10 | 14.6 | 12.2 |
| | (100 Å) | (100 Å) | (340 Å) | | |
| Example 2 | A1 | B1 | C10 | 10.4 | 14 |
| | (48 Å) | (112 Å) | (340 Å) | | |
| Example 3 | A7 | B1 | C10 | 9.2 | 13.1 |
| | (100 Å) | (100 Å) | (340 Å) | | |
| Example 4 | A8 | B1 | C10 | 8.7 | 11.1 |
| | (100 Å) | (100 Å) | (340 Å) | | |
| Example 5 | A9 | B1 | C10 | 5.6 | 8.1 |
| | (100 Å) | (100 Å) | (340 Å) | | |
| Example 6 | A55 | B1 | C10 | 8.5 | 9.6 |
| | (100 Å) | (100 Å) | (340 Å) | | |
| Example 7 | A65 | B1 | C10 | 10.2 | 10.7 |
| | (100 Å) | (100 Å) | (340 Å) | | |
| Example 8 | A1 | B22 | C10 | 7.2 | 6.5 |
| | (100 Å) | (100 Å) | (340 Å) | | |
| Example 9 | A1 | B39 | C10 | 6 | 4.9 |
| | (100 Å) | (100 Å) | (340 Å) | | |
| Example 10 | A1 | B40 | C10 | 7.7 | 8.1 |
| | (100 Å) | (100 Å) | (340 Å) | | |
| Example 11 | A1 | B41 | C10 | 6.4 | 8.8 |
| | (100 Å) | (100 Å) | (340 Å) | | |
| Example 12 | A1 | B1 | C1 | 10.2 | 11.2 |
| | (100 Å) | (100 Å) | (340 Å) | | |
| Example 13 | A1 | B1 | C13 | 9.6 | 10.4 |
| | (100 Å) | (100 Å) | (340 Å) | | |
| Comparative | A1 | — | C10 | 16.8 | — |
| Example 1 | (100 Å) | | (340 Å) | | |
| Comparative | — | B1 | C10 | — | 17.8 |
| Example 2 | | (120 Å) | (340 Å) | | |
| Comparative | A1 | B1 | — | 0.1 | 0.1 |
| Example 3 | (100 Å) | (100 Å) | | | |
| Comparative | A1 | B1 | — | 0.1 | 0.1 |
| Example 4 | (48 Å) | (112 Å) | | | |

TABLE 2

| | Optical activation layer | | | | |
|---|---|---|---|---|---|
| | (single layer) | | | EQE | EQE (%) |
| | First | Second | Third | (%) for | for |
| | compound | compound | compound | green light | red light |
| Example 14 | A1 | B1 | C10 | 16.8 | 17.8 |

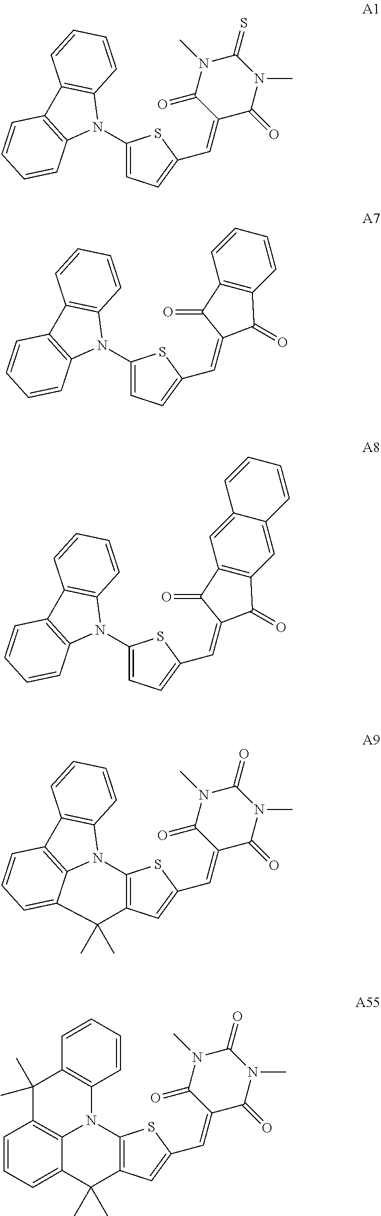

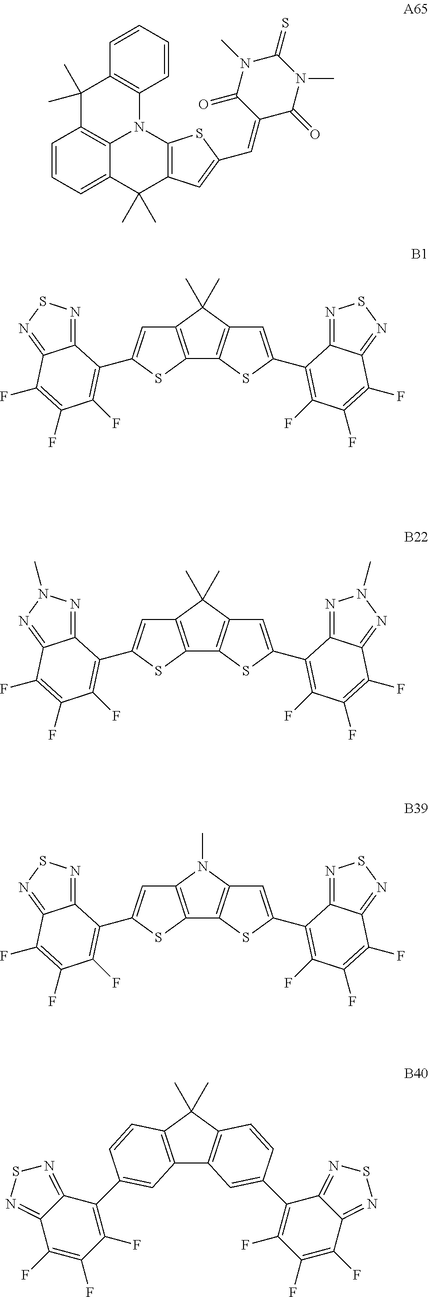

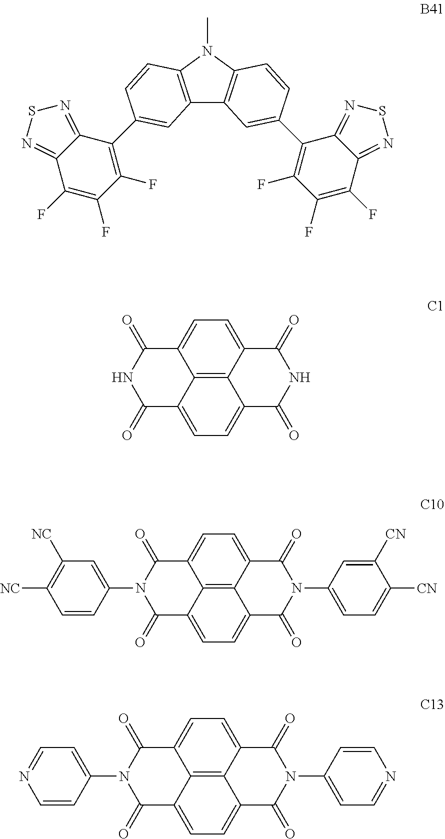 [SMILES: Cn1c2ccc(-c3c(F)c(F)c(F)c4nsnc34)cc2c2cc(-c3c(F)c(F)c(F)c4nsnc34)ccc21 ; O=C1NC(=O)c2ccc3c4c(ccc1c24)C(=O)NC3=O ; N#Cc1ccc(N2C(=O)c3ccc4c5c(ccc(c35)C2=O)C(=O)N(c2ccc(C#N)c(C#N)c2)C4=O)cc1C#N ; O=C1c2ccc3c4c(ccc(c24)C(=O)N1c1ccncc1)C(=O)N(c1ccncc1)C3=O]

From Tables 1 and 2, it was confirmed that the optoelectronic device including all of the first compound, the second compound, and the third compound, according to one or more embodiments, concurrently (e.g., simultaneously) had EQE for green light which was sufficient for fingerprint sensing and EQE for red light which was sufficient for blood pressure sensing.

According to the one or more embodiments, by utilizing first to third compounds each having a relatively low deposition temperature, processability may be ensured, and thus, an optoelectronic device may be more easily manufactured. When the optoelectronic device included in a portable electronic apparatus includes each (e.g., all) of the first to third compounds, the optoelectronic device may have excellent or suitable EQE for both (e.g., simultaneously) green light and red light. As a result, a user of the electronic apparatus may easily and accurately recognize information, such as fingerprints and blood pressure of an individual, through the electronic apparatus having excellent or suitable portability.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A composition comprising:
a first compound represented by Formula 1;
a second compound represented by Formula 2; and
a third compound represented by Formula 3: 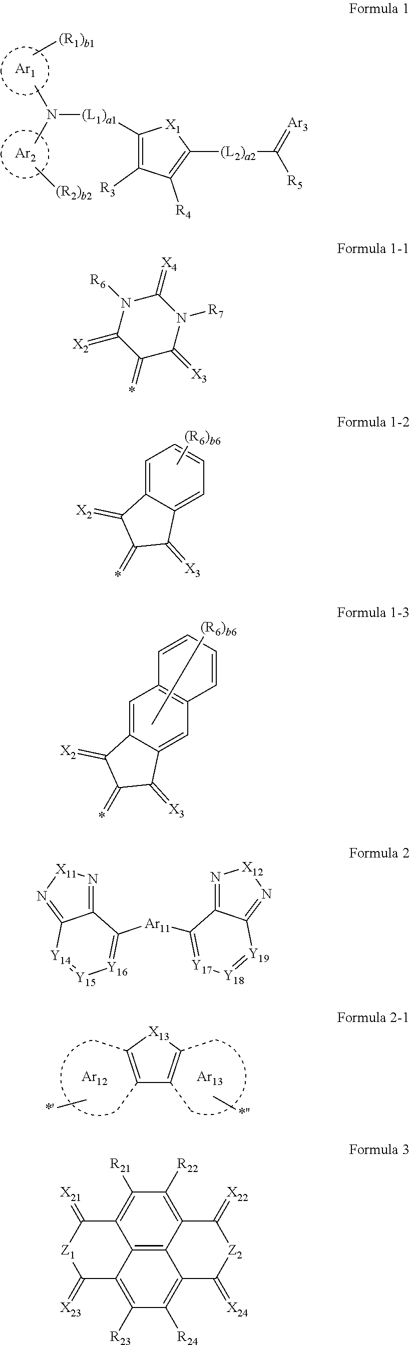
in Formula 1, Formula 1-1 to Formula 1-3, Formula 2, Formula 2-1, and Formula 3,
Ar₁, Ar₂, Ar₁₂, and Ar₁₃ are each independently a C₃-C₆₀ carbocyclic group unsubstituted or substituted with at least one R₁₀ₐ or a C₁-C₆₀ heterocyclic group unsubstituted or substituted with at least one R₁₀ₐ,
Ar₁ and Ar₂ are not connected or are connected via a single bond, *—O—*′, *—S—*′, *—C(T₁)(T₂)-*′, *—Si(T₁)(T₂)-*′, or *—N(T₁)-*′,
Ar₂ is not connected to an X₁-containing 5-membered ring, or is connected to the X₁-containing 5-membered ring via a single bond, *—O—*′, *—S—*′, *—C(T₃)(T₄)-*′, *—Si(T₃)(T₄)-*′, or *—N(T₃)-*′,
T₁ to T₄ are each independently hydrogen, deuterium, —F, —Cl, a cyano group, a C₁-C₆₀ alkyl group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
Ar₃ is a group represented by one selected from among Formula 1-1 to Formula 1-3,
Ar₁₁ is a group represented by Formula 2-1,
X₁ is O, S, Se, Te, SO, SO₂, C(R₁ₐ)(R_{1b}), Si(R₁ₐ)(R_{1b}), or N(R₁ₐ),
X₂ is O, S, Se, Te, SO, SO₂, C(R_{1c})(R₁ₐ), Si(R_{1c})(R₁ₐ), or N(R_{1c}),
X₃ is O, S, Se, Te, SO, SO₂, C(R₁ₑ)(R_{1f}), Si(R₁ₑ)(R_{1f}), or N(R₁ₑ),
X₄ is O, S, Se, Te, SO, SO₂, C(R_{1g})(R₁ₕ), Si(R_{1g})(R₁ₕ), or N(R_{1g}),
X₁₁ is N(R₁₁), O, S, or Se,
X₁₂ is N(R₁₂), O, S, or Se,
X₁₃ is C(R₁₃ₐ)(R_{13b}), N(R₁₃), O, S, or Se,
Y₁₄ is N or C(R₁₄),
Y₁₅ is N or C(R₁₅),
Y₁₆ is N or C(R₁₆),
Y₁₇ is N or C(R₁₇),
Y₁₈ is N or C(R₁₈),
Y₁₉ is N or C(R₁₉),
X₂₁ to X₂₄ are each independently O, S, or Se,
Z₁ is O or N(R₂₅),
Z₂ is O or N(R₂₆),
L₁ and L₂ are each independently a single bond, a C₁-C₂₀ alkylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
each of a1 and a2 is an integer from 1 to 3,
each of b1 and b2 is an integer from 1 to 10,
b6 is an integer from 1 to 6,
R₁ₐ to R₁ₕ, R₁ to R₇, R₁₃ₐ, R_{13b}, R₁₁ to R₁₉, and R₂₁ to R₂₆ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ are each independently:
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or
a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, cyano group, a C₁-C₆₀ alkyl group, a C₁-C₆₀ alkoxy group, a phenyl group, a biphenyl group, or any combination thereof, and
*, and *′, and *″ each indicate a binding site to a neighboring atom.

2. An optoelectronic device comprising:
a first electrode;
a second electrode facing the first electrode; and
an optical activation layer between the first electrode and the second electrode,
wherein the optical activation layer comprises a first compound represented by Formula 1, a second compound represented by Formula 2, and a third compound represented by Formula 3: 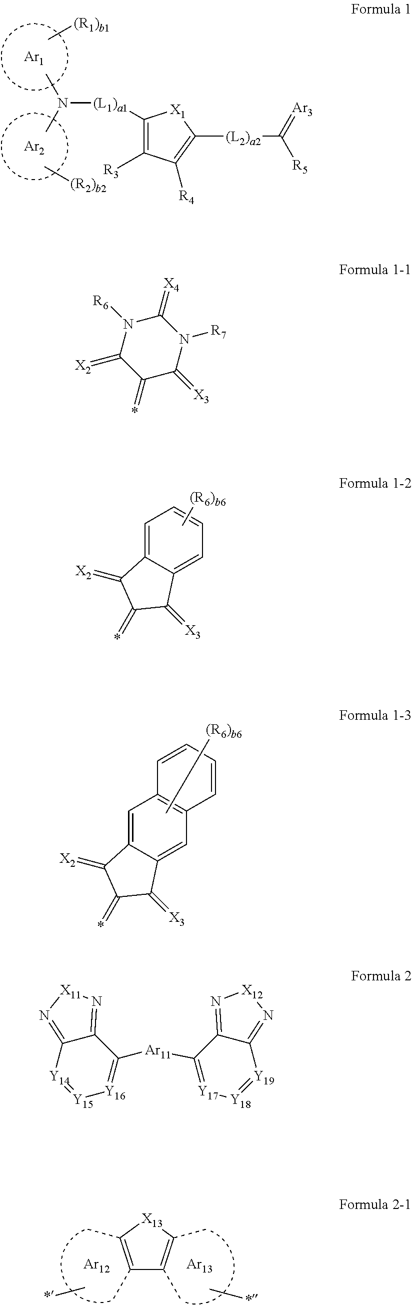 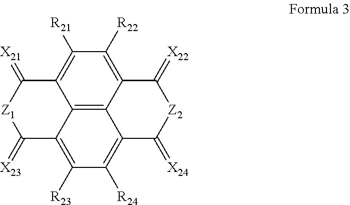
wherein, in Formula 1, Formula 1-1 to Formula 1-3, Formula 2, Formula 2-1, and Formula 3,
Ar₁, Ar₂, Ar₁₂, and Ar₁₃ are each independently a C₃-C₆₀ carbocyclic group unsubstituted or substituted with at least one R₁₀ₐ or a C₁-C₆₀ heterocyclic group unsubstituted or substituted with at least one R₁₀ₐ,
Ar₁ and Ar₂ are not connected or are connected via a single bond, *—O—*′, *—S—*′, *—C(T₁)(T₂)-*′, *—Si(T₁)(T₂)-*′, or *—N(T₁)-*′,
Ar₂ is not connected to an X₁-containing 5-membered ring, or is connected to the X₁-containing 5-membered ring via a single bond, *—O—*′, *—S—*′, *—C(T₃)(T₄)-*′, *—Si(T₃)(T₄)-*′, or *—N(T₃)-*′,
T₁ to T₄ are each independently hydrogen, deuterium, —F, —Cl, a cyano group, a C₁-C₆₀ alkyl group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
Ar₃ is a group represented by one selected from among Formula 1-1 to Formula 1-3,
Ar₁₁ is a group represented by Formula 2-1,
X₁ is O, S, Se, Te, SO, SO₂, C(R₁ₐ)(R_{1b}), Si(R₁ₐ)(R_{1b}), or N(R₁ₐ),
X₂ is O, S, Se, Te, SO, SO₂, C(R_{1c})(R₁ₐ), Si(R_{1c})(R₁ₐ), or N(R_{1c}),
X₃ is O, S, Se, Te, SO, SO₂, C(R₁ₑ)(R_{1f}), Si(R₁ₑ)(R_{1f}), or N(R₁ₑ),
X₄ is O, S, Se, Te, SO, SO₂, C(R_{1g})(R₁ₕ), Si(R_{1g})(R₁ₕ), or N(R_{1g}),
X₁₁ is N(R₁₁), O, S, or Se,
X₁₂ is N(R₁₂), O, S, or Se,
X₁₃ is C(R₁₃ₐ)(R_{13b}), N(R₁₃), O, S, or Se,
Y₁₄ is N or C(R₁₄),
Y₁₅ is N or C(R₁₅),
Y₁₆ is N or C(R₁₆),
Y₁₇ is N or C(R₁₇),
Y₁₈ is N or C(R₁₈),
Y₁₉ is N or C(R₁₉),
X₂₁ to X₂₄ are each independently O, S, or Se,
Z₁ is O or N(R₂₅),
Z₂ is O or N(R₂₆),
L₁ and L₂ are each independently a single bond, a C₁-C₂₀ alkylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
each of a1 and a2 is an integer from 1 to 3,
each of b1 and b2 is an integer from 1 to 10,
b6 is an integer from 1 to 6,
R₁ₐ to R₁ₕ, R₁ to R₇, R₁₃ₐ, R_{13b}, R₁₁ to R₁₉, and R₂₁ to R₂₆ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ are each independently:
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or
a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, cyano group, a C₁-C₆₀ alkyl group, a C₁-C₆₀ alkoxy group, a phenyl group, a biphenyl group, or any combination thereof, and
*, *′, and *″ each indicate a binding site to a neighboring atom.

3. The optoelectronic device of claim 2, wherein the optical activation layer is a single layer.

4. The optoelectronic device of claim 2, wherein the optical activation layer comprises:
a first layer comprising the first compound; and
a second layer comprising the second compound.

5. The optoelectronic device of claim 4, wherein each of the first layer and the second layer comprises the third compound.

6. The optoelectronic device of claim 4, wherein the second layer is between the first layer and the second electrode, the optical activation layer further comprises a third layer between the second layer and the second electrode, and
the third layer comprises the third compound.

7. The optoelectronic device of claim 2, further comprising a charge generation layer between the first electrode and the second electrode, wherein the optical activation layer comprises: a first optical activation layer between the first electrode and the charge generation layer; and a second optical activation layer between the charge generation layer and the second electrode.

8. The optoelectronic device of claim 7, wherein the first optical activation layer comprises the first compound and the third compound, and
the second optical activation layer comprises the second compound and the third compound.

9. The optoelectronic device of claim 2, wherein an absolute value of a highest occupied molecular orbital (HOMO) energy level of the first compound is about 5.0 electron volt (eV) to about 5.5 eV.

10. The optoelectronic device of claim 2, wherein an absolute value of a highest occupied molecular orbital (HOMO) energy level of the second compound is about 5.0 eV to about 6.5 eV.

11. The optoelectronic device of claim 2, wherein an absolute value of a lowest unoccupied molecular orbital (LUMO) energy level of the third compound is 3.5 eV or less.

12. The optoelectronic device of claim 2, wherein the optical activation layer does not comprise each of a fullerene-based compound and a subphthalocyanine-based compound.

13. The optoelectronic device of claim 2, wherein, in Formula 1, at least one selected from among L₁ and L₂ is a single bond.

14. The optoelectronic device of claim 2, wherein, in Formula 1, a moiety represented by 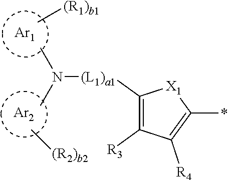
is a moiety represented by one selected from among Formulae 1A to 1E: 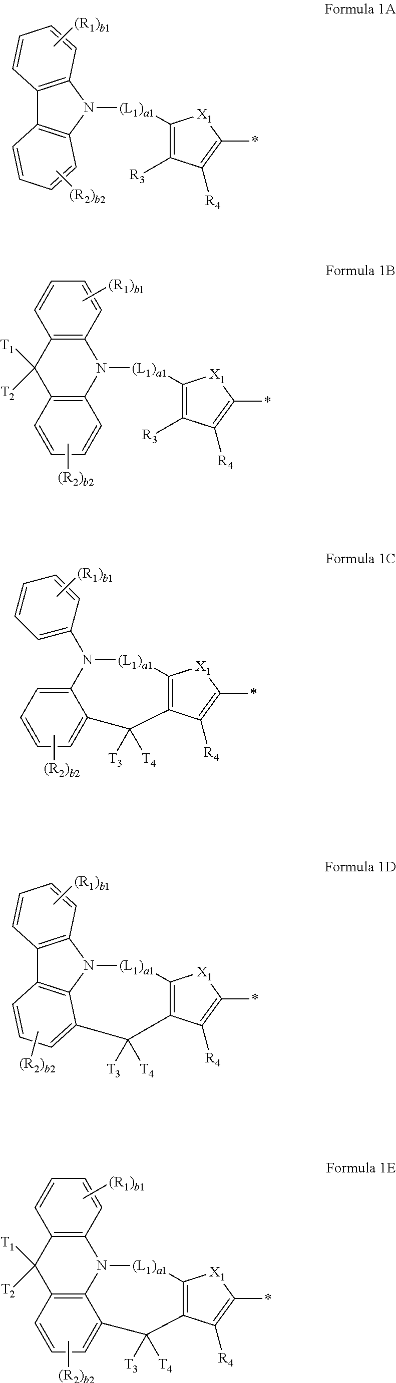
in Formulae 1A to 1E,
X₁, L₁, a1, T₁ to T₄, and R₁ to R₄ are each as defined for Formula 1,
b1 is an integer from 1 to 5,
b2 is an integer from 1 to 4, and
* indicates a binding site to (L₂)ₐ₂ in Formula 1.

15. The optoelectronic device of claim 2, wherein, in Formula 2,
at least two selected from among Y₁₄ to Y₁₆ are each N, and
at least two selected from among Y₁₇ to Y₁₉ are each N.

16. The optoelectronic device of claim 2, wherein, in Formula 2-1, Ar₁₂ and Ar₁₃ are each independently a cyclopentadiene group unsubstituted or substituted with at least one R₁₀ₐ, a benzene group unsubstituted or substituted with at least one R₁₀ₐ, a pyrimidine group unsubstituted or substituted with at least one R₁₀ₐ, a thiophene group unsubstituted or substituted with at least one R₁₀ₐ, a pyrrole group unsubstituted or substituted with at least one R₁₀ₐ, or a furan group unsubstituted or substituted with at least one R₁₀ₐ.

17. The optoelectronic device of claim 2, wherein, in Formula 3,
Z₁ is N(R₂₅),
Z₂ is N(R₂₆), and
R₂₅ and R₂₆ are each independently selected from among:
hydrogen;
deuterium;
—F;
—Cl;
a cyano group;
a C₁-C₁ alkyl group unsubstituted or substituted with deuterium, —F, —Cl, a cyano group, or any combination thereof;
a C₆-C₁₀ aryl group unsubstituted or substituted with deuterium, —F, —Cl, a cyano group, —CF₃, or any combination thereof; and
a C₆-C₁₀ heteroaryl group unsubstituted or substituted with deuterium, —F, —Cl, a cyano group, —CF₃, or any combination thereof.

18. The optoelectronic device of claim 2, wherein the optical activation layer is a vacuum deposited optical activation layer.

19. An electronic apparatus comprising:
a first electrode;
a second electrode facing the first electrode;
an optical activation layer between the first electrode and the second electrode; and
an emission layer not overlapping the optical activation layer and between the first electrode and the second electrode,
wherein the optical activation layer comprises a first compound represented by Formula 1, a second compound represented by Formula 2, and a third compound represented by Formula 3: 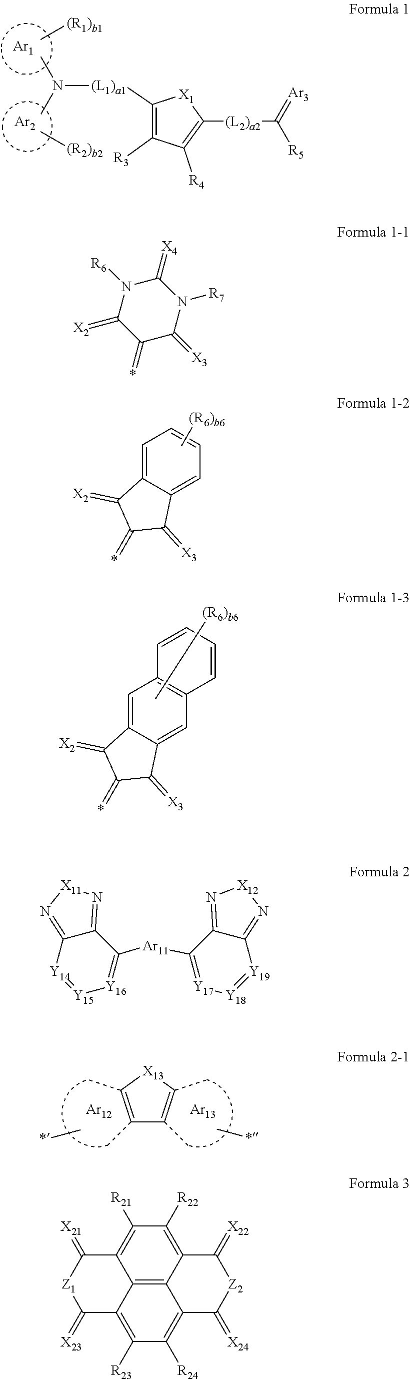
wherein, in Formula 1, Formula 1-1 to Formula 1-3, Formula 2, Formula 2-1, and Formula 3,
Ar₁, Ar₂, Ar₁₂, and Ar₁₃ are each independently a C₃-C₆₀ carbocyclic group unsubstituted or substituted with at least one R₁₀ₐ or a C₁-C₆₀ heterocyclic group unsubstituted or substituted with at least one R₁₀ₐ,
Ar₁ and Ar₂ are not connected or are connected via a single bond, *—O—*′, *—S—*′, *—C(T₁)(T₂)-*′, *—Si(T₁)(T₂)-*′, or *—N(T₁)-*′,
Ar₂ is not connected to an X₁-containing 5-membered ring, or is connected to the X₁-containing 5-membered ring via a single bond, *—O—*′, *—S—*′, *—C(T₃)(T₄)-*′, *—Si(T₃)(T₄)-*′, or *—N(T₃)-*′,
T₁ to T₄ are each independently hydrogen, deuterium, —F, —Cl, a cyano group, a C₁-C₆₀ alkyl group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
Ar₃ is a group represented by one selected from among Formula 1-1 to Formula 1-3,
Ar₁₁ is a group represented by Formula 2-1,
X₁ is O, S, Se, Te, SO, SO₂, C(R₁ₐ)(R_{1b}), Si(R₁ₐ)(R_{1b}), or N(R₁ₐ),
X₂ is O, S, Se, Te, SO, SO₂, C(R_{1c})(R₁ₐ), Si(R_{1c})(R₁ₐ), or N(R_{1c}),
X₃ is O, S, Se, Te, SO, SO₂, C(R₁ₑ)(R_{1f}), Si(R₁ₑ)(R_{1f}), or N(R₁ₑ),
X₄ is O, S, Se, Te, SO, SO₂, C(R_{1g})(R₁ₕ), Si(R_{1g})(R₁ₕ), or N(R_{1g}),
X₁₁ is N(R₁₁), O, S, or Se,
X₁₂ is N(R₁₂), O, S, or Se,
X₁₃ is C(R₁₃ₐ)(R_{13b}), N(R₁₃), O, S, or Se,
Y₁₄ is N or C(R₁₄),
Y₁₅ is N or C(R₁₅),
Y₁₆ is N or C(R₁₆),
Y₁₇ is N or C(R₁₇),
Y₁₈ is N or C(R₁₈),
Y₁₉ is N or C(R₁₉),
X₂₁ to X₂₄ are each independently O, S, or Se,
Z₁ is O or N(R₂₅),
Z₂ is O or N(R₂₆),
L₁ and L₂ are each independently a single bond, a C₁-C₂₀ alkylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
each of a1 and a2 is an integer from 1 to 3,
each of b1 and b2 is an integer from 1 to 10,
b6 is an integer from 1 to 6,
R₁ₐ to R₁ₕ, R₁ to R₇, R₁₃ₐ, R_{13b}, R₁₁ to R₁₉, and R₂₁ to R₂₆ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ are each independently:
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or
a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, cyano group, a C₁-C₆₀ alkyl group, a C₁-C₆₀ alkoxy group, a phenyl group, a biphenyl group, or any combination thereof, and
*, *, and *″ each indicate a binding site to a neighboring atom.

20. An electronic equipment comprising the electronic apparatus of claim 19, wherein the electronic equipment is at least one selected from the group consisting of a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, a signboard, and combinations thereof.
